(19) United States
(12) Patent Application Publication
(10) Pub. No.: US 2023/0039147 A1
(43) Pub. Date: Feb. 9, 2023

(54) DRILLING OPERATIONS FRICTION FRAMEWORK

(71) Applicant: Schlumberger Technology Corporation, Sugar Land, TX (US)

(72) Inventors: Pavel Gutarov, Montpellier (FR); Laurent Vallet, Montpellier (FR)

(21) Appl. No.: 17/817,697

(22) Filed: Aug. 5, 2022

Related U.S. Application Data
(60) Provisional application No. 63/230,272, filed on Aug. 6, 2021.

(51) Int. Cl. G06F 30/13; E21B 47/00

(52) U.S. Cl. CPC G06F 30/13; E21B 47/00; E21B 2200/20

(57) ABSTRACT

A method can include acquiring data during rig operations for a specified drillstring for drilling a specified borehole in a geologic environment, where the data include downhole survey data; determining a drillstring load based on at least a portion of the data; comparing the drillstring load to a plurality of modeled loads, where the plurality of modeled loads depend on the specified drillstring, the specified borehole, and at least a portion of the survey data and correspond to a plurality of different friction factor values; and, based on the comparing, estimating a friction factor value that corresponds to the drillstring load.

### RELATED APPLICATIONS

This application claims priority to and the benefit of a U.S. Provisional Application having Ser. No. 63/230,272, filed 6 Aug. 2021, which is incorporated by reference herein.

### BACKGROUND

A resource field can be an accumulation, pool or group of pools of one or more resources (e.g., oil, gas, oil and gas) in a subsurface environment. A resource field can include at least one reservoir. A reservoir may be shaped in a manner that can trap hydrocarbons and may be covered by an impermeable or sealing rock. A bore can be drilled into an environment where the bore may be utilized to form a well that can be utilized in producing hydrocarbons from a reservoir.

A rig can be a system of components that can be operated to form a bore in an environment, to transport equipment into and out of a bore in an environment, etc. As an example, a rig can include a system that can be used to drill a bore and to acquire information about an environment, about drilling, etc. A resource field may be an onshore field, an offshore field or an on- and offshore field. A rig can include components for performing operations onshore and/or offshore. A rig may be, for example, vessel-based, offshore platform-based, onshore, etc.

Field planning can occur over one or more phases, which can include an exploration phase that aims to identify and assess an environment (e.g., a prospect, a play, etc.), which may include drilling of one or more bores (e.g., one or more exploratory wells, etc.). Other phases can include appraisal, development and production phases.

### SUMMARY

A method can include acquiring data during rig operations for a specified drillstring for drilling a specified borehole in a geologic environment, where the data include downhole survey data; determining a drillstring load based on at least a portion of the data; comparing the drillstring load to a plurality of modeled loads, wherein the plurality of modeled loads depend on the specified drillstring, the specified borehole, and at least a portion of the survey data and correspond to a plurality of different friction factor values; and, based on the comparing, estimating a friction factor value that corresponds to the drillstring load. A system can include a processor; memory accessible by the processor; processor-executable instructions stored in the memory and executable to instruct the system to: acquire data during rig operations for a specified drillstring for drilling a specified borehole in a geologic environment, where the data include downhole survey data; determine a drillstring load based on at least a portion of the data; perform a comparison of the drillstring load and a plurality of modeled loads, where the plurality of modeled loads depend on the specified drillstring, the specified borehole, and at least a portion of the survey data and correspond to a plurality of different friction factor values; and, based on the comparison, estimate a friction factor value that corresponds to the drillstring load. One or more computer-readable storage media can include processor-executable instructions to instruct a computing system to: acquire data during rig operations for a specified drillstring for drilling a specified borehole in a geologic environment, where the data include downhole survey data; determine a drillstring load based on at least a portion of the data; perform a comparison of the drillstring load and a plurality of modeled loads, where the plurality of modeled loads depend on the specified drillstring, the specified borehole, and at least a portion of the survey data and correspond to a plurality of different friction factor values; and, based on the comparison, estimate a friction factor value that corresponds to the drillstring load. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Features and advantages of the described implementations can be more readily understood by reference to the following description taken in conjunction with the accompanying drawings.

FIG. 1 illustrates examples of equipment in a geologic environment;

FIG. 2 illustrates examples of equipment and examples of hole types;

FIG. 3 illustrates an example of a system;

FIG. 4 illustrates an example of a system;

FIG. 5 illustrates an example of a graphical user interface;

FIG. 6 illustrates an example of a graphical user interface;

FIG. 7 illustrates an example of a system;

FIG. 8 illustrates an example of a method and an example of a graphic;

FIG. 9 illustrates an example of a graphic with reference to the graphic of FIG. 8;

FIG. 10 illustrates an example of a graphic that includes various tracks of time series data and other information;

FIG. 11 illustrates an example of a graphic with respect to time series data;

FIG. 12 illustrates an example of a graphic with respect to time series data;

FIG. 13 illustrates an example of a graphic with respect to time series data;

FIG. 14 illustrates an example of a method and an example of a system;

FIG. 15 illustrates an example of a method;

FIG. 16 illustrates an example of a system;

FIG. 17 illustrates an example of a graphical user interface;

FIG. 18 illustrates an example of a graphical user interface;

FIG. 19 illustrates an example of a graphical user interface;

FIG. 20 illustrates an example of a graphical user interface;

FIG. 21 illustrates an example of a graphical user interface of an enlarged portion of the graphical user interface of FIG. 20;

FIG. 22 illustrates an example of a graphical user interface;

FIG. 23 illustrates an example of a graphical user interface that includes a portion of the graphical user interface of FIG. 22;

FIG. 24 illustrates an example of a portion of a graphical user interface;

FIG. 25 illustrates an example of another portion of the graphical user interface of FIG. 24;

FIG. 26 illustrates an example of a graphical user interface for an example of computational framework components;

FIG. 27 illustrates an example of a method;

FIG. 28 illustrates an example of a method;

FIG. 29 illustrates an example of a method and an example of a system;

FIG. 30 illustrates an example of a well construction ecosystem that includes one or more friction factor frameworks;

FIG. 31 illustrates an example of computing system; and

FIG. 32 illustrates example components of a system and a networked system.

### DETAILED DESCRIPTION

The following description includes the best mode presently contemplated for practicing the described implementations. This description is not to be taken in a limiting sense, but rather is made merely for the purpose of describing the general principles of the implementations. The scope of the described implementations should be ascertained with reference to the issued claims.

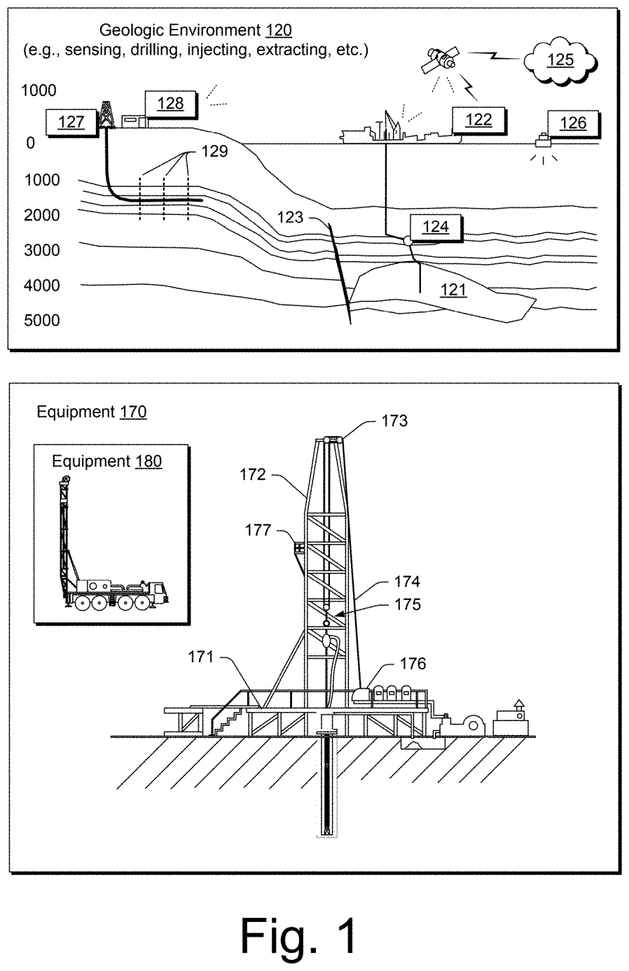

FIG. 1 shows an example of a geologic environment 120. In FIG. 1, the geologic environment 120 may be a sedimentary basin that includes layers (e.g., stratification) that include a reservoir 121 and that may be, for example, intersected by a fault 123 (e.g., or faults). As an example, the geologic environment 120 may be outfitted with a variety of sensors, detectors, actuators, etc. For example, equipment 122 may include communication circuitry to receive and to transmit information with respect to one or more networks 125. Such information may include information associated with downhole equipment 124, which may be equipment to acquire information, to assist with resource recovery, etc. Other equipment 126 may be located remote from a well site and include sensing, detecting, emitting or other circuitry. Such equipment may include storage and communication circuitry to store and to communicate data, instructions, etc. As an example, one or more pieces of equipment may provide for measurement, collection, communication, storage, analysis, etc. of data (e.g., for one or more produced resources, etc.). As an example, one or more satellites may be provided for purposes of communications, data acquisition, etc. For example, FIG. 1 shows a satellite in communication with the network 125 that may be configured for communications, noting that the satellite may additionally or alternatively include circuitry for imagery (e.g., spatial, spectral, temporal, radiometric, etc.).

FIG. 1 also shows the geologic environment 120 as optionally including equipment 127 and 128 associated with a well that includes a substantially horizontal portion that may intersect with one or more fractures 129. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop the reservoir (e.g., via fracturing, injecting, extracting, etc.). As an example, the equipment 127 and/or 128 may include components, a system, systems, etc. for fracturing, seismic sensing, analysis of seismic data, assessment of one or more fractures, injection, production, etc. As an example, the equipment 127 and/or 128 may provide for measurement, collection, communication, storage, analysis, etc. of data such as, for example, production data (e.g., for one or more produced resources). As an example, one or more satellites may be provided for purposes of communications, data acquisition, etc.

FIG. 1 also shows an example of equipment 170 and an example of equipment 180. Such equipment, which may be systems of components, may be suitable for use in the geologic environment 120. While the equipment 170 and 180 are illustrated as land-based, various components may be suitable for use in an offshore system.

The equipment 170 includes a platform 171, a derrick 172, a crown block 173, a line 174, a traveling block assembly 175, drawworks 176 and a landing 177 (e.g., a monkeyboard). As an example, the line 174 may be controlled at least in part via the drawworks 176 such that the traveling block assembly 175 travels in a vertical direction with respect to the platform 171. For example, by drawing the line 174 in, the drawworks 176 may cause the line 174 to run through the crown block 173 and lift the traveling block assembly 175 skyward away from the platform 171; whereas, by allowing the line 174 out, the drawworks 176 may cause the line 174 to run through the crown block 173 and lower the traveling block assembly 175 toward the platform 171. Where the traveling block assembly 175 carries pipe (e.g., casing, etc.), tracking of movement of the traveling block 175 may provide an indication as to how much pipe has been deployed.

A derrick can be a structure used to support a crown block and a traveling block operatively coupled to the crown block at least in part via line. A derrick may be pyramidal in shape and offer a suitable strength-to-weight ratio. A derrick may be movable as a unit or in a piece by piece manner (e.g., to be assembled and disassembled).

As an example, drawworks may include a spool, brakes, a power source and assorted auxiliary devices. Drawworks may controllably reel out and reel in line. Line may be reeled over a crown block and coupled to a traveling block to gain mechanical advantage in a “block and tackle” or “pulley” fashion. Reeling out and in of line can cause a traveling block (e.g., and whatever may be hanging underneath it), to be lowered into or raised out of a bore. Reeling out of line may be powered by gravity and reeling in by a motor, an engine, etc. (e.g., an electric motor, a diesel engine, etc.).

As an example, a crown block can include a set of pulleys (e.g., sheaves) that can be located at or near a top of a derrick or a mast, over which line is threaded. A traveling block can include a set of sheaves that can be moved up and down in a derrick or a mast via line threaded in the set of sheaves of the traveling block and in the set of sheaves of a crown block. A crown block, a traveling block and a line can form a pulley system of a derrick or a mast, which may enable handling of heavy loads (e.g., drillstring, pipe, casing, liners, etc.) to be lifted out of or lowered into a bore. As an example, line may be about a centimeter to about five centimeters in diameter as, for example, steel cable. Through use of a set of sheaves, such line may carry loads heavier than the line could support as a single strand.

As an example, a derrickman may be a rig crew member that works on a platform attached to a derrick or a mast. A derrick can include a landing on which a derrickman may stand. As an example, such a landing may be about 10 meters or more above a rig floor. In an operation referred to as trip out of the hole (TOH), a derrickman may wear a safety harness that enables leaning out from the work landing (e.g., monkeyboard) to reach pipe in located at or near the center of a derrick or a mast and to throw a line around the pipe and pull it back into its storage location (e.g., fingerboards), for example, until it a time at which it may be desirable to run the pipe back into the bore. As an example, a rig may include automated pipe-handling equipment such that the derrickman controls the machinery rather than physically handling the pipe.

As an example, a trip may refer to the act of pulling equipment from a bore and/or placing equipment in a bore. As an example, equipment may include a drillstring that can be pulled out of a hole and/or placed or replaced in a hole. As an example, a pipe trip may be performed where a drill bit has dulled or has otherwise ceased to drill efficiently and is to be replaced.

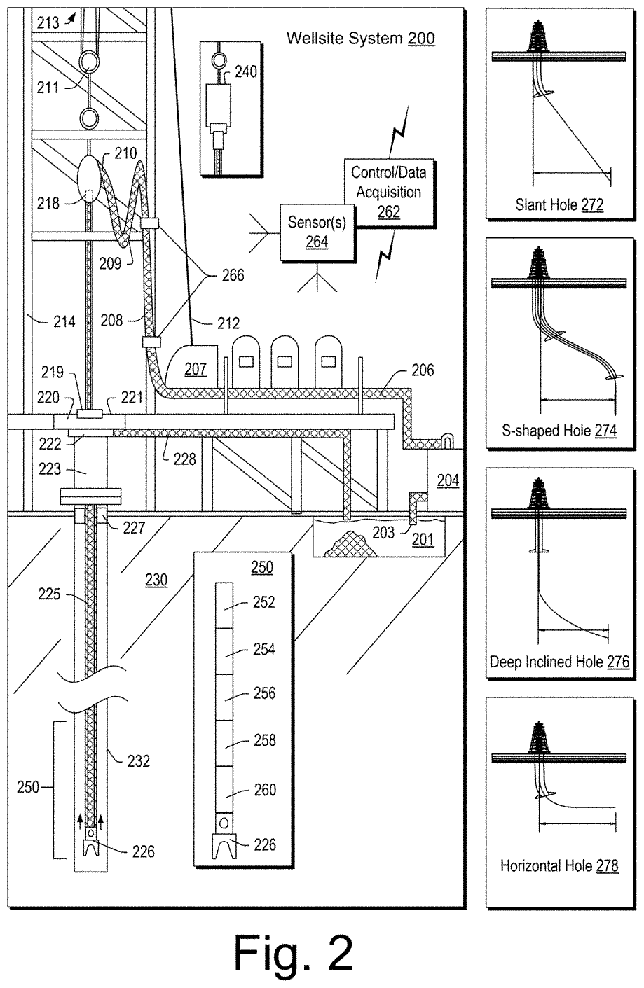

FIG. 2 shows an example of a wellsite system 200 (e.g., at a wellsite that may be onshore or offshore). As shown, the wellsite system 200 can include a mud tank 201 for holding mud and other material (e.g., where mud can be a drilling fluid), a suction line 203 that serves as an inlet to a mud pump 204 for pumping mud from the mud tank 201 such that mud flows to a vibrating hose 206, a drawworks 207 for winching drill line or drill lines 212, a standpipe 208 that receives mud from the vibrating hose 206, a kelly hose 209 that receives mud from the standpipe 208, a gooseneck or goosenecks 210, a traveling block 211, a crown block 213 for carrying the traveling block 211 via the drill line or drill lines 212 (see, e.g., the crown block 173 of FIG. 1), a derrick 214 (see, e.g., the derrick 172 of FIG. 1), a kelly 218 or a top drive 240, a kelly drive bushing 219, a rotary table 220, a drill floor 221, a bell nipple 222, one or more blowout preventors (BOPs) 223, a drillstring 225, a drill bit 226, a casing head 227 and a flow pipe 228 that carries mud and other material to, for example, the mud tank 201.

In the example system of FIG. 2, a borehole 232 is formed in subsurface formations 230 by rotary drilling; noting that various example embodiments may also use directional drilling.

As shown in the example of FIG. 2, the drillstring 225 is suspended within the borehole 232 and has a drillstring assembly 250 that includes the drill bit 226 at its lower end. As an example, the drillstring assembly 250 may be a bottom hole assembly (BHA).

The wellsite system 200 can provide for operation of the drillstring 225 and other operations. As shown, the wellsite system 200 includes the platform 211 and the derrick 214 positioned over the borehole 232. As mentioned, the wellsite system 200 can include the rotary table 220 where the drillstring 225 pass through an opening in the rotary table 220.

As shown in the example of FIG. 2, the wellsite system 200 can include the kelly 218 and associated components, etc., or a top drive 240 and associated components. As to a kelly example, the kelly 218 may be a square or hexagonal metal/alloy bar with a hole drilled therein that serves as a mud flow path. The kelly 218 can be used to transmit rotary motion from the rotary table 220 via the kelly drive bushing 219 to the drillstring 225, while allowing the drillstring 225 to be lowered or raised during rotation. The kelly 218 can pass through the kelly drive bushing 219, which can be driven by the rotary table 220. As an example, the rotary table 220 can include a master bushing that operatively couples to the kelly drive bushing 219 such that rotation of the rotary table 220 can turn the kelly drive bushing 219 and hence the kelly 218. The kelly drive bushing 219 can include an inside profile matching an outside profile (e.g., square, hexagonal, etc.) of the kelly 218; however, with slightly larger dimensions so that the kelly 218 can freely move up and down inside the kelly drive bushing 219.

As to a top drive example, the top drive 240 can provide functions performed by a kelly and a rotary table. The top drive 240 can turn the drillstring 225. As an example, the top drive 240 can include one or more motors (e.g., electric and/or hydraulic) connected with appropriate gearing to a short section of pipe called a quill, that in turn may be screwed into a saver sub or the drillstring 225 itself. The top drive 240 can be suspended from the traveling block 211, so the rotary mechanism is free to travel up and down the derrick 214. As an example, a top drive 240 may allow for drilling to be performed with more joint stands than a kelly/rotary table approach.

In the example of FIG. 2, the mud tank 201 can hold mud, which can be one or more types of drilling fluids. As an example, a wellbore may be drilled to produce fluid, inject fluid or both (e.g., hydrocarbons, minerals, water, etc.).

In the example of FIG. 2, the drillstring 225 (e.g., including one or more downhole tools) may be composed of a series of pipes threadably connected together to form a long tube with the drill bit 226 at the lower end thereof. As the drillstring 225 is advanced into a wellbore for drilling, at some point in time prior to or coincident with drilling, the mud may be pumped by the pump 204 from the mud tank 201 (e.g., or other source) via a the lines 206, 208 and 209 to a port of the kelly 218 or, for example, to a port of the top drive 240. The mud can then flow via a passage (e.g., or passages) in the drillstring 225 and out of ports located on the drill bit 226 (see, e.g., a directional arrow). As the mud exits the drillstring 225 via ports in the drill bit 226, it can then circulate upwardly through an annular region between an outer surface(s) of the drillstring 225 and surrounding wall(s) (e.g., open borehole, casing, etc.), as indicated by directional arrows. In such a manner, the mud lubricates the drill bit 226 and carries heat energy (e.g., frictional or other energy) and formation cuttings to the surface where the mud (e.g., and cuttings) may be returned to the mud tank 201, for example, for recirculation (e.g., with processing to remove cuttings, etc.).

The mud pumped by the pump 204 into the drillstring 225 may, after exiting the drillstring 225, form a mudcake that lines the wellbore which, among other functions, may reduce friction between the drillstring 225 and surrounding wall(s) (e.g., borehole, casing, etc.). A reduction in friction may facilitate advancing or retracting the drillstring 225. During a drilling operation, the entire drillstring 225 may be pulled from a wellbore and optionally replaced, for example, with a new or sharpened drill bit, a smaller diameter drillstring, etc. As mentioned, the act of pulling a drillstring out of a hole or replacing it in a hole is referred to as tripping. A trip may be referred to as an upward trip or an outward trip or as a downward trip or an inward trip depending on trip direction.

As an example, consider a downward trip where upon arrival of the drill bit 226 of the drillstring 225 at a bottom of a wellbore, pumping of the mud commences to lubricate the drill bit 226 for purposes of drilling to enlarge the wellbore. As mentioned, the mud can be pumped by the pump 204 into a passage of the drillstring 225 and, upon filling of the passage, the mud may be used as a transmission medium to transmit energy, for example, energy that may encode information as in mud-pulse telemetry.

As an example, mud-pulse telemetry equipment may include a downhole device configured to effect changes in pressure in the mud to create an acoustic wave or waves upon which information may modulated. In such an example, information from downhole equipment (e.g., one or more modules of the drillstring 225) may be transmitted uphole to an uphole device, which may relay such information to other equipment for processing, control, etc.

As an example, telemetry equipment may operate via transmission of energy via the drillstring 225 itself. For example, consider a signal generator that imparts coded energy signals to the drillstring 225 and repeaters that may receive such energy and repeat it to further transmit the coded energy signals (e.g., information, etc.).

As an example, the drillstring 225 may be fitted with telemetry equipment 252 that includes a rotatable drive shaft, a turbine impeller mechanically coupled to the drive shaft such that the mud can cause the turbine impeller to rotate, a modulator rotor mechanically coupled to the drive shaft such that rotation of the turbine impeller causes said modulator rotor to rotate, a modulator stator mounted adjacent to or proximate to the modulator rotor such that rotation of the modulator rotor relative to the modulator stator creates pressure pulses in the mud, and a controllable brake for selectively braking rotation of the modulator rotor to modulate pressure pulses. In such example, an alternator may be coupled to the aforementioned drive shaft where the alternator includes at least one stator winding electrically coupled to a control circuit to selectively short the at least one stator winding to electromagnetically brake the alternator and thereby selectively brake rotation of the modulator rotor to modulate the pressure pulses in the mud.

In the example of FIG. 2, an uphole control and/or data acquisition system 262 may include circuitry to sense pressure pulses generated by telemetry equipment 252 and, for example, communicate sensed pressure pulses or information derived therefrom for process, control, etc.

The assembly 250 of the illustrated example includes a logging-while-drilling (LWD) module 254, a measuring-while-drilling (MWD) module 256, an optional module 258, a roto-steerable system (RSS) and/or motor 260, and the drill bit 226. Such components or modules may be referred to as tools where a drillstring can include a plurality of tools.

As to a RSS, it involves technology utilized for directional drilling. Directional drilling involves drilling into the Earth to form a deviated bore such that the trajectory of the bore is not vertical; rather, the trajectory deviates from vertical along one or more portions of the bore. As an example, consider a target that is located at a lateral distance from a surface location where a rig may be stationed. In such an example, drilling can commence with a vertical portion and then deviate from vertical such that the bore is aimed at the target and, eventually, reaches the target. Directional drilling may be implemented where a target may be inaccessible from a vertical location at the surface of the Earth, where material exists in the Earth that may impede drilling or otherwise be detrimental (e.g., consider a salt dome, etc.), where a formation is laterally extensive (e.g., consider a relatively thin yet laterally extensive reservoir), where multiple bores are to be drilled from a single surface bore, where a relief well is desired, etc.

One approach to directional drilling involves a mud motor; however, a mud motor can present some challenges depending on factors such as rate of penetration (ROP), transferring weight to a bit (e.g., weight on bit, WOB) due to friction, etc. A mud motor can be a positive displacement motor (PDM) that operates to drive a bit (e.g., during directional drilling, etc.). A PDM operates as drilling fluid is pumped through it where the PDM converts hydraulic power of the drilling fluid into mechanical power to cause the bit to rotate.

As an example, a PDM may operate in a combined rotating mode where surface equipment is utilized to rotate a bit of a drillstring (e.g., a rotary table, a top drive, etc.) by rotating the entire drillstring and where drilling fluid is utilized to rotate the bit of the drillstring. In such an example, a surface RPM (SRPM) may be determined by use of the surface equipment and a downhole RPM of the mud motor may be determined using various factors related to flow of drilling fluid, mud motor type, etc. As an example, in the combined rotating mode, bit RPM can be determined or estimated as a sum of the SRPM and the mud motor RPM, assuming the SRPM and the mud motor RPM are in the same direction.

As an example, a PDM mud motor can operate in a so-called sliding mode, when the drillstring is not rotated from the surface. In such an example, a bit RPM can be determined or estimated based on the RPM of the mud motor.

A RSS can drill directionally where there is continuous rotation from surface equipment, which can alleviate the sliding of a steerable motor (e.g., a PDM). A RSS may be deployed when drilling directionally (e.g., deviated, horizontal, or extended-reach wells). A RSS can aim to minimize interaction with a borehole wall, which can help to preserve borehole quality. A RSS can aim to exert a relatively consistent side force akin to stabilizers that rotate with the drillstring or orient the bit in the desired direction while continuously rotating at the same number of rotations per minute as the drillstring.

The LWD module 254 may be housed in a suitable type of drill collar and can contain one or a plurality of selected types of logging tools. It will also be understood that more than one LWD and/or MWD module can be employed, for example, as represented at by the module 256 of the drillstring assembly 250. Where the position of an LWD module is mentioned, as an example, it may refer to a module at the position of the LWD module 254, the module 256, etc. An LWD module can include capabilities for measuring, processing, and storing information, as well as for communicating with the surface equipment. In the illustrated example, the LWD module 254 may include a seismic measuring device.

The MWD module 256 may be housed in a suitable type of drill collar and can contain one or more devices for measuring characteristics of the drillstring 225 and the drill bit 226. As an example, the MWD tool 254 may include equipment for generating electrical power, for example, to power various components of the drillstring 225. As an example, the MWD tool 254 may include the telemetry equipment 252, for example, where the turbine impeller can generate power by flow of the mud; it being understood that other power and/or battery systems may be employed for purposes of powering various components. As an example, the MWD module 256 may include one or more of the following types of measuring devices: a weight-on-bit measuring device, a torque measuring device, a vibration measuring device, a shock measuring device, a stick slip measuring device, a direction measuring device, and an inclination measuring device.

FIG. 2 also shows some examples of types of holes that may be drilled. For example, consider a slant hole 272, an S-shaped hole 274, a deep inclined hole 276 and a horizontal hole 278.

As an example, a drilling operation can include directional drilling where, for example, at least a portion of a well includes a curved axis. For example, consider a radius that defines curvature where an inclination with regard to the vertical may vary until reaching an angle between about 30 degrees and about 60 degrees or, for example, an angle to about 90 degrees or possibly greater than about 90 degrees.

As an example, a directional well can include several shapes where each of the shapes may aim to meet particular operational demands. As an example, a drilling process may be performed on the basis of information as and when it is relayed to a drilling engineer. As an example, inclination and/or direction may be modified based on information received during a drilling process.

As an example, deviation of a bore may be accomplished in part by use of one or more of a RSS, a downhole motor and/or a turbine. As to a motor, for example, a drillstring can include a positive displacement motor (PDM).

As an example, a system may be a steerable system and include equipment to perform a method such as geosteering. As an example, a steerable system can include a PDM or a turbine on a lower part of a drillstring which, just above a drill bit, a bent sub can be mounted. As an example, above a PDM, MWD equipment that provides real time or near real time data of interest (e.g., inclination, direction, pressure, temperature, real weight on the drill bit, torque stress, etc.) and/or LWD equipment may be installed. As to the latter, LWD equipment can make it possible to send to the surface various types of data of interest, including for example, geological data (e.g., gamma ray log, resistivity, density and sonic logs, etc.).

The coupling of sensors providing information on the course of a well trajectory, in real time or near real time, with, for example, one or more logs characterizing the formations from a geological viewpoint, can allow for implementing a geosteering method. Such a method can include navigating a subsurface environment, for example, to follow a desired route to reach a desired target or targets.

As an example, a drillstring can include an azimuthal density neutron (ADN) tool for measuring density and porosity; a MWD tool for measuring inclination, azimuth and shocks; a compensated dual resistivity (CDR) tool for measuring resistivity and gamma ray related phenomena; one or more variable gauge stabilizers; one or more bend joints; and a geosteering tool, which may include a motor and optionally equipment for measuring and/or responding to one or more of inclination, resistivity and gamma ray related phenomena.

As an example, geosteering can include intentional directional control of a wellbore based on results of downhole geological logging measurements in a manner that aims to keep a directional wellbore within a desired region, zone (e.g., a pay zone), etc. As an example, geosteering may include directing a wellbore to keep the wellbore in a particular section of a reservoir, for example, to minimize gas and/or water breakthrough and, for example, to maximize economic production from a well that includes the wellbore.

Referring again to FIG. 2, the wellsite system 200 can include one or more sensors 264 that are operatively coupled to the control and/or data acquisition system 262. As an example, a sensor or sensors may be at surface locations. As an example, a sensor or sensors may be at downhole locations. As an example, a sensor or sensors may be at one or more remote locations that are not within a distance of the order of about one hundred meters from the wellsite system 200. As an example, a sensor or sensor may be at an offset wellsite where the wellsite system 200 and the offset wellsite are in a common field (e.g., oil and/or gas field).

As an example, one or more of the sensors 264 can be provided for tracking pipe, tracking movement of at least a portion of a drillstring, etc.

As an example, the system 200 can include one or more sensors 266 that can sense and/or transmit signals to a fluid conduit such as a drilling fluid conduit (e.g., a drilling mud conduit). For example, in the system 200, the one or more sensors 266 can be operatively coupled to portions of the standpipe 208 through which mud flows. As an example, a downhole tool can generate pulses that can travel through the mud and be sensed by one or more of the one or more sensors 266. In such an example, the downhole tool can include associated circuitry such as, for example, encoding circuitry that can encode signals, for example, to reduce demands as to transmission. As an example, circuitry at the surface may include decoding circuitry to decode encoded information transmitted at least in part via mud-pulse telemetry. As an example, circuitry at the surface may include encoder circuitry and/or decoder circuitry and circuitry downhole may include encoder circuitry and/or decoder circuitry. As an example, the system 200 can include a transmitter that can generate signals that can be transmitted downhole via mud (e.g., drilling fluid) as a transmission medium.

As an example, one or more portions of a drillstring may become stuck. The term stuck can refer to one or more of varying degrees of inability to move or remove a drillstring from a bore. As an example, in a stuck condition, it might be possible to rotate pipe or lower it back into a bore or, for example, in a stuck condition, there may be an inability to move the drillstring axially in the bore, though some amount of rotation may be possible. As an example, in a stuck condition, there may be an inability to move at least a portion of the drillstring axially and rotationally.

As to the term “stuck pipe”, this can refer to a portion of a drillstring that cannot be rotated or moved axially. As an example, a condition referred to as “differential sticking” can be a condition whereby the drillstring cannot be moved (e.g., rotated or reciprocated) along the axis of the bore. Differential sticking may occur when high-contact forces caused by low reservoir pressures, high wellbore pressures, or both, are exerted over a sufficiently large area of the drillstring. Differential sticking can have time and financial cost.

As an example, a sticking force can be a product of the differential pressure between the wellbore and the reservoir and the area that the differential pressure is acting upon. This means that a relatively low differential pressure (delta p) applied over a large working area can be just as effective in sticking pipe as can a high differential pressure applied over a small area.

As an example, a condition referred to as “mechanical sticking” can be a condition where limiting or prevention of motion of the drillstring by a mechanism other than differential pressure sticking occurs. Mechanical sticking can be caused, for example, by one or more of junk in the hole, wellbore geometry anomalies, cement, keyseats or a buildup of cuttings in the annulus.

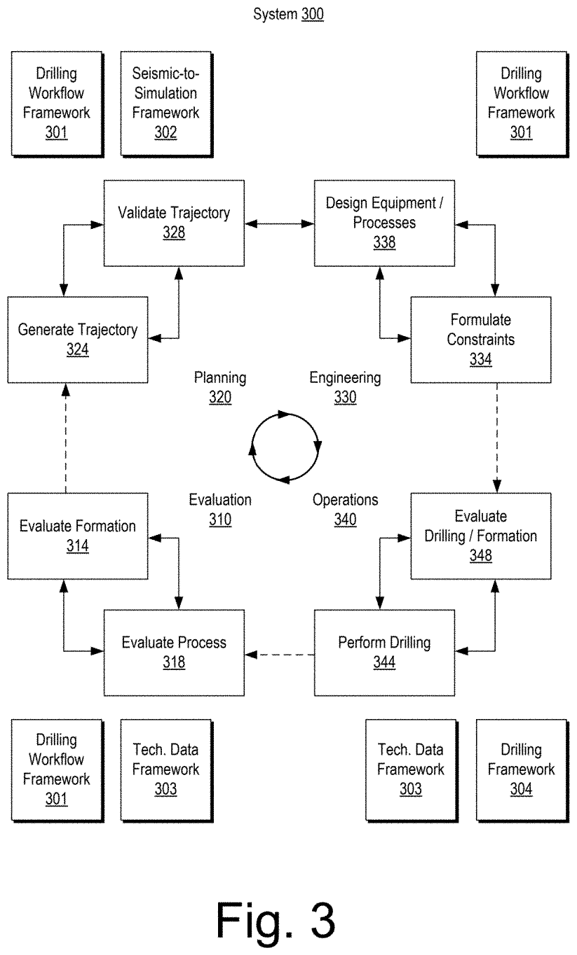

FIG. 3 shows an example of a system 300 that includes various equipment for evaluation 310, planning 320, engineering 330 and operations 340. For example, a drilling workflow framework 301, a seismic-to-simulation framework 302, a technical data framework 303 and a drilling framework 304 may be implemented to perform one or more processes such as a evaluating a formation 314, evaluating a process 318, generating a trajectory 324, validating a trajectory 328, formulating constraints 334, designing equipment and/or processes based at least in part on constraints 338, performing drilling 344 and evaluating drilling and/or formation 348.

In the example of FIG. 3, the seismic-to-simulation framework 302 can be, for example, the PETREL framework (Schlumberger Limited, Houston, Tex.) and the technical data framework 303 can be, for example, the TECHLOG framework (Schlumberger Limited, Houston, Tex.).

As an example, a framework can include entities that may include earth entities, geological objects or other objects such as wells, surfaces, reservoirs, etc. Entities can include virtual representations of actual physical entities that are reconstructed for purposes of one or more of evaluation, planning, engineering, operations, etc.

Entities may include entities based on data acquired via sensing, observation, etc. (e.g., seismic data and/or other information). An entity may be characterized by one or more properties (e.g., a geometrical pillar grid entity of an earth model may be characterized by a porosity property). Such properties may represent one or more measurements (e.g., acquired data), calculations, etc.

A framework may be an object-based framework. In such a framework, entities may include entities based on pre-defined classes, for example, to facilitate modeling, analysis, simulation, etc. An example of an object-based framework is the MICROSOFT .NET framework (Redmond, Wash.), which provides a set of extensible object classes. In the .NET framework, an object class encapsulates a module of reusable code and associated data structures. Object classes can be used to instantiate object instances for use in by a program, script, etc. For example, borehole classes may define objects for representing boreholes based on well data.

As an example, a framework can include an analysis component that may allow for interaction with a model or model-based results (e.g., simulation results, etc.). As to simulation, a framework may operatively link to or include a simulator such as the ECLIPSE reservoir simulator (Schlumberger Limited, Houston Tex.), the INTERSECT reservoir simulator (Schlumberger Limited, Houston Tex.), etc.

The aforementioned PETREL framework provides components that allow for optimization of exploration and development operations. The PETREL framework includes seismic to simulation software components that can output information for use in increasing reservoir performance, for example, by improving asset team productivity. Through use of such a framework, various professionals (e.g., geophysicists, geologists, well engineers, reservoir engineers, etc.) can develop collaborative workflows and integrate operations to streamline processes. Such a framework may be considered an application and may be considered a data-driven application (e.g., where data is input for purposes of modeling, simulating, etc.).

As an example, one or more frameworks may be interoperative and/or run upon one or another. As an example, consider the framework environment marketed as the OCEAN framework environment (Schlumberger Limited, Houston, Tex.), which allows for integration of add-ons (or plug-ins) into a PETREL framework workflow. The OCEAN framework environment leverages .NET tools (Microsoft Corporation, Redmond, Wash.) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

As an example, a framework can include a model simulation layer along with a framework services layer, a framework core layer and a modules layer. The framework may include the OCEAN framework where the model simulation layer can include or operatively link to the PETREL model-centric software package that hosts OCEAN framework applications. In an example embodiment, the PETREL software may be considered a data-driven application. The PETREL software can include a framework for model building and visualization. Such a model may include one or more grids.

As an example, the model simulation layer may provide domain objects, act as a data source, provide for rendering and provide for various user interfaces. Rendering may provide a graphical environment in which applications can display their data while the user interfaces may provide a common look and feel for application user interface components.

As an example, domain objects can include entity objects, property objects and optionally other objects. Entity objects may be used to geometrically represent wells, surfaces, reservoirs, etc., while property objects may be used to provide property values as well as data versions and display parameters. For example, an entity object may represent a well where a property object provides log information as well as version information and display information (e.g., to display the well as part of a model).

As an example, data may be stored in one or more data sources (or data stores, generally physical data storage devices), which may be at the same or different physical sites and accessible via one or more networks. As an example, a model simulation layer may be configured to model projects. As such, a particular project may be stored where stored project information may include inputs, models, results and cases. Thus, upon completion of a modeling session, a user may store a project. At a later time, the project can be accessed and restored using the model simulation layer, which can recreate instances of the relevant domain objects.

As an example, the system 300 may be used to perform one or more workflows. A workflow may be a process that includes a number of worksteps. A workstep may operate on data, for example, to create new data, to update existing data, etc. As an example, a workflow may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable at least in part in the PETREL software, for example, that operates on seismic data, seismic attribute(s), etc.

As an example, seismic data can be data acquired via a seismic survey where sources and receivers are positioned in a geologic environment to emit and receive seismic energy where at least a portion of such energy can reflect off subsurface structures. As an example, a seismic data analysis framework or frameworks (e.g., consider the OMEGA framework, marketed by Schlumberger Limited, Houston, Tex.) may be utilized to determine depth, extent, properties, etc. of subsurface structures. As an example, seismic data analysis can include forward modeling and/or inversion, for example, to iteratively build a model of a subsurface region of a geologic environment. As an example, a seismic data analysis framework may be part of or operatively coupled to a seismic-to-simulation framework (e.g., the PETREL framework, etc.).

As an example, a workflow may be a process implementable at least in part in the OCEAN framework. As an example, a workflow may include one or more worksteps that access a module such as a plug-in (e.g., external executable code, etc.).

As an example, a framework may provide for modeling petroleum systems. For example, the modeling framework marketed as the PETROMOD framework (Schlumberger Limited, Houston, Tex.) includes features for input of various types of information (e.g., seismic, well, geological, etc.) to model evolution of a sedimentary basin. The PETROMOD framework provides for petroleum systems modeling via input of various data such as seismic data, well data and other geological data, for example, to model evolution of a sedimentary basin. The PETROMOD framework may predict if, and how, a reservoir has been charged with hydrocarbons, including, for example, the source and timing of hydrocarbon generation, migration routes, quantities, pore pressure and hydrocarbon type in the subsurface or at surface conditions. In combination with a framework such as the PETREL framework, workflows may be constructed to provide basin-to-prospect scale exploration solutions. Data exchange between frameworks can facilitate construction of models, analysis of data (e.g., PETROMOD framework data analyzed using PETREL framework capabilities), and coupling of workflows.

As mentioned, a drillstring can include various tools that may make measurements. As an example, a wireline tool or another type of tool may be utilized to make measurements. As an example, a tool may be configured to acquire electrical borehole images. As an example, the fullbore Formation Microlmager (FMI) tool (Schlumberger Limited, Houston, Tex.) can acquire borehole image data. A data acquisition sequence for such a tool can include running the tool into a borehole with acquisition pads closed, opening and pressing the pads against a wall of the borehole, delivering electrical current into the material defining the borehole while translating the tool in the borehole, and sensing current remotely, which is altered by interactions with the material.

Analysis of formation information may reveal features such as, for example, vugs, dissolution planes (e.g., dissolution along bedding planes), stress-related features, dip events, etc. As an example, a tool may acquire information that may help to characterize a reservoir, optionally a fractured reservoir where fractures may be natural and/or artificial (e.g., hydraulic fractures). As an example, information acquired by a tool or tools may be analyzed using a framework such as the TECHLOG framework. As an example, the TECHLOG framework can be interoperable with one or more other frameworks such as, for example, the PETREL framework.

As an example, various aspects of a workflow may be completed automatically, may be partially automated, or may be completed manually, as by a human user interfacing with a software application. As an example, a workflow may be cyclic, and may include, as an example, four stages such as, for example, an evaluation stage (see, e.g., the evaluation equipment 310), a planning stage (see, e.g., the planning equipment 320), an engineering stage (see, e.g., the engineering equipment 330) and an execution stage (see, e.g., the operations equipment 340). As an example, a workflow may commence at one or more stages, which may progress to one or more other stages (e.g., in a serial manner, in a parallel manner, in a cyclical manner, etc.).

As an example, a workflow can commence with an evaluation stage, which may include a geological service provider evaluating a formation (see, e.g., the evaluation block 314). As an example, a geological service provider may undertake the formation evaluation using a computing system executing a software package tailored to such activity; or, for example, one or more other suitable geology platforms may be employed (e.g., alternatively or additionally). As an example, the geological service provider may evaluate the formation, for example, using earth models, geophysical models, basin models, petrotechnical models, combinations thereof, and/or the like. Such models may take into consideration a variety of different inputs, including offset well data, seismic data, pilot well data, other geologic data, etc. The models and/or the input may be stored in the database maintained by the server and accessed by the geological service provider.

As an example, a workflow may progress to a geology and geophysics (“G&G”) service provider, which may generate a well trajectory (see, e.g., the generation block 324), which may involve execution of one or more G&G software packages. Examples of such software packages include the PETREL framework. As an example, a G&G service provider may determine a well trajectory or a section thereof, based on, for example, one or more model(s) provided by a formation evaluation (e.g., per the evaluation block 314), and/or other data, e.g., as accessed from one or more databases (e.g., maintained by one or more servers, etc.). As an example, a well trajectory may take into consideration various “basis of design” (BOD) constraints, such as general surface location, target (e.g., reservoir) location, and the like. As an example, a trajectory may incorporate information about tools, bottom-hole assemblies, casing sizes, etc., that may be used in drilling the well. A well trajectory determination may take into consideration a variety of other parameters, including risk tolerances, fluid weights and/or plans, bottom-hole pressures, drilling time, etc.

As an example, a workflow may progress to a first engineering service provider (e.g., one or more processing machines associated therewith), which may validate a well trajectory and, for example, relief well design (see, e.g., the validation block 328). Such a validation process may include evaluating physical properties, calculations, risk tolerances, integration with other aspects of a workflow, etc. As an example, one or more parameters for such determinations may be maintained by a server and/or by the first engineering service provider; noting that one or more model(s), well trajectory(ies), etc. may be maintained by a server and accessed by the first engineering service provider. For example, the first engineering service provider may include one or more computing systems executing one or more software packages. As an example, where the first engineering service provider rejects or otherwise suggests an adjustment to a well trajectory, the well trajectory may be adjusted or a message or other notification sent to the G&G service provider requesting such modification.

As an example, one or more engineering service providers (e.g., first, second, etc.) may provide a casing design, bottom-hole assembly (BHA) design, fluid design, and/or the like, to implement a well trajectory (see, e.g., the design block 338). In some embodiments, a second engineering service provider may perform such design using one of more software applications. Such designs may be stored in one or more databases maintained by one or more servers, which may, for example, employ STUDIO framework tools, and may be accessed by one or more of the other service providers in a workflow.

As an example, a second engineering service provider may seek approval from a third engineering service provider for one or more designs established along with a well trajectory. In such an example, the third engineering service provider may consider various factors as to whether the well engineering plan is acceptable, such as economic variables (e.g., oil production forecasts, costs per barrel, risk, drill time, etc.), and may request authorization for expenditure, such as from the operating company's representative, well-owner's representative, or the like (see, e.g., the formulation block 334). As an example, at least some of the data upon which such determinations are based may be stored in one or more database maintained by one or more servers. As an example, a first, a second, and/or a third engineering service provider may be provided by a single team of engineers or even a single engineer, and thus may or may not be separate entities.

As an example, where economics may be unacceptable or subject to authorization being withheld, an engineering service provider may suggest changes to casing, a bottom-hole assembly, and/or fluid design, or otherwise notify and/or return control to a different engineering service provider, so that adjustments may be made to casing, a bottom-hole assembly, and/or fluid design. Where modifying one or more of such designs is impracticable within well constraints, trajectory, etc., the engineering service provider may suggest an adjustment to the well trajectory and/or a workflow may return to or otherwise notify an initial engineering service provider and/or a G&G service provider such that either or both may modify the well trajectory.

As an example, a workflow can include considering a well trajectory, including an accepted well engineering plan, and a formation evaluation. Such a workflow may then pass control to a drilling service provider, which may implement the well engineering plan, establishing safe and efficient drilling, maintaining well integrity, and reporting progress as well as operating parameters (see, e.g., the blocks 344 and 348). As an example, operating parameters, formation encountered, data collected while drilling (e.g., using logging-while-drilling or measuring-while-drilling technology), may be returned to a geological service provider for evaluation. As an example, the geological service provider may then re-evaluate the well trajectory, or one or more other aspects of the well engineering plan, and may, in some cases, and potentially within predetermined constraints, adjust the well engineering plan according to the real-life drilling parameters (e.g., based on acquired data in the field, etc.).

Whether the well is entirely drilled, or a section thereof is completed, depending on the specific embodiment, a workflow may proceed to a post review (see, e.g., the evaluation block 318). As an example, a post review may include reviewing drilling performance. As an example, a post review may further include reporting the drilling performance (e.g., to one or more relevant engineering, geological, or G&G service providers).

Various activities of a workflow may be performed consecutively and/or may be performed out of order (e.g., based partially on information from templates, nearby wells, etc. to fill in gaps in information that is to be provided by another service provider). As an example, undertaking one activity may affect the results or basis for another activity, and thus may, either manually or automatically, call for a variation in one or more workflow activities, work products, etc. As an example, a server may allow for storing information on a central database accessible to various service providers where variations may be sought by communication with an appropriate service provider, may be made automatically, or may otherwise appear as suggestions to the relevant service provider. Such an approach may be considered to be a holistic approach to a well workflow, in comparison to a sequential, piecemeal approach.

As an example, various actions of a workflow may be repeated multiple times during drilling of a wellbore. For example, in one or more automated systems, feedback from a drilling service provider may be provided at or near real-time, and the data acquired during drilling may be fed to one or more other service providers, which may adjust its piece of the workflow accordingly. As there may be dependencies in other areas of the workflow, such adjustments may permeate through the workflow, e.g., in an automated fashion. In some embodiments, a cyclic process may additionally or instead proceed after a certain drilling goal is reached, such as the completion of a section of the wellbore, and/or after the drilling of the entire wellbore, or on a per-day, week, month, etc. basis.

Well planning can include determining a path of a well that can extend to a reservoir, for example, to economically produce fluids such as hydrocarbons therefrom. Well planning can include selecting a drilling and/or completion assembly which may be used to implement a well plan. As an example, various constraints can be imposed as part of well planning that can impact design of a well. As an example, such constraints may be imposed based at least in part on information as to known geology of a subterranean domain, presence of one or more other wells (e.g., actual and/or planned, etc.) in an area (e.g., consider collision avoidance), etc. As an example, one or more constraints may be imposed based at least in part on characteristics of one or more tools, components, etc. As an example, one or more constraints may be based at least in part on factors associated with drilling time and/or risk tolerance.

As an example, a system can allow for a reduction in waste, for example, as may be defined according to LEAN. In the context of LEAN, consider one or more of the following types of waste: transport (e.g., moving items unnecessarily, whether physical or data); inventory (e.g., components, whether physical or informational, as work in process, and finished product not being processed); motion (e.g., people or equipment moving or walking unnecessarily to perform desired processing); waiting (e.g., waiting for information, interruptions of production during shift change, etc.); overproduction (e.g., production of material, information, equipment, etc. ahead of demand); over Processing (e.g., resulting from poor tool or product design creating activity); and defects (e.g., effort involved in inspecting for and fixing defects whether in a plan, data, equipment, etc.). As an example, a system that allows for actions (e.g., methods, workflows, etc.) to be performed in a collaborative manner can help to reduce one or more types of waste.

As an example, a system can be utilized to implement a method for facilitating distributed well engineering, planning, and/or drilling system design across multiple computation devices where collaboration can occur among various different users (e.g., some being local, some being remote, some being mobile, etc.). In such a system, the various users via appropriate devices may be operatively coupled via one or more networks (e.g., local and/or wide area networks, public and/or private networks, land-based, marine-based and/or areal networks, etc.).

As an example, a system may allow well engineering, planning, and/or drilling system design to take place via a subsystems approach where a wellsite system is composed of various subsystem, which can include equipment subsystems and/or operational subsystems (e.g., control subsystems, etc.). As an example, computations may be performed using various computational platforms/devices that are operatively coupled via communication links (e.g., network links, etc.). As an example, one or more links may be operatively coupled to a common database (e.g., a server site, etc.). As an example, a particular server or servers may manage receipt of notifications from one or more devices and/or issuance of notifications to one or more devices. As an example, a system may be implemented for a project where the system can output a well plan, for example, as a digital well plan, a paper well plan, a digital and paper well plan, etc. Such a well plan can be a complete well engineering plan or design for the particular project.

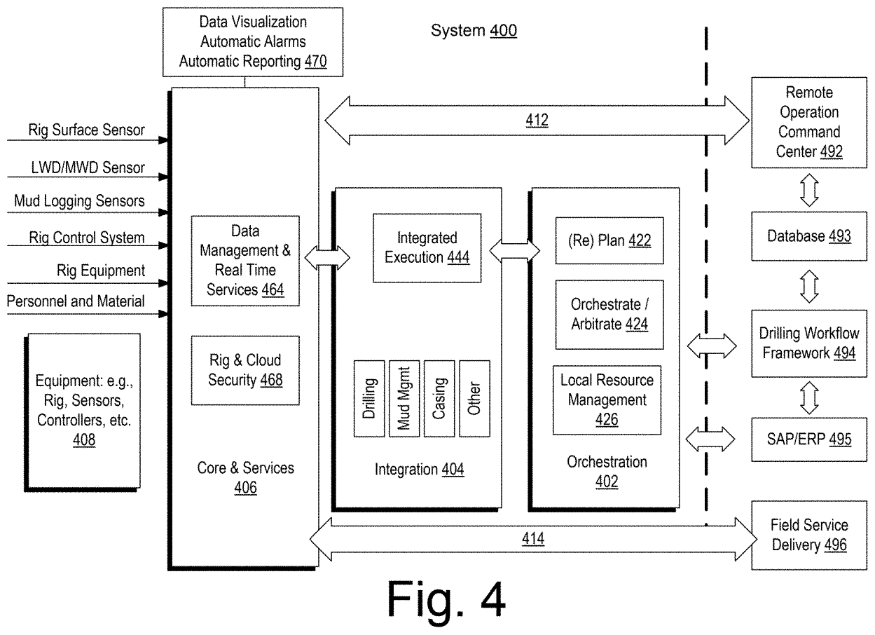

FIG. 4 shows an example of a system 400 that includes various components that can be local to a wellsite and includes various components that can be remote from a wellsite. As shown, the system 400 includes an orchestration block 402, an integration block 404, a core and services block 406 and an equipment block 408. These blocks can be labeled in one or more manners other than as shown in the example of FIG. 4. In the example of FIG. 4, the blocks 402, 404, 406 and 408 can be defined by one or more of operational features, functions, relationships in an architecture, etc.

As an example, the blocks 402, 404, 406 and 408 may be described in a pyramidal architecture where, from peak to base, a pyramid includes the orchestration block 402, the integration block 404, the core and services block 406 and the equipment block 408.

As an example, the orchestration block 402 can be associated with a well management level (e.g., well planning and/or orchestration) and can be associated with a rig management level (e.g., rig dynamic planning and/or orchestration). As an example, the integration block 404 can be associated with a process management level (e.g., rig integrated execution). As an example, the core and services block 406 can be associated with a data management level (e.g., sensor, instrumentation, inventory, etc.). As an example, the equipment block 408 can be associated with a wellsite equipment level (e.g., wellsite subsystems, etc.).

As an example, the orchestration block 402 may receive information from a drilling workflow framework and/or one or more other sources, which may be remote from a wellsite.

In the example of FIG. 4, the orchestration block 402 includes a plan/replan block 422, an orchestrate/arbitrate block 424 and a local resource management block 426. In the example of FIG. 4, the integration block 404 includes an integrated execution block 444, which can include or be operatively coupled to blocks for various subsystems of a wellsite such as a drilling subsystem, a mud management subsystem (e.g., a hydraulics subsystem), a casing subsystem (e.g., casings and/or completions subsystem), and, for example, one or more other subsystems. In the example of FIG. 4, the core and services block 406 includes a data management and real-time services block 464 (e.g., real-time or near real-time services) and a rig and cloud security block 468 (e.g., as to provisioning and various type of security measures, etc.). In the example of FIG. 4, the equipment block 408 is shown as being capable of providing various types of information to the core and services block 406. For example, consider information from a rig surface sensor, a LWD/MWD sensor, a mud logging sensor, a rig control system, rig equipment, personnel, material, etc. In the example, of FIG. 4, a block 470 can provide for one or more of data visualization, automatic alarms, automatic reporting, etc. As an example, the block 470 may be operatively coupled to the core and services block 406 and/or one or more other blocks.

As mentioned, a portion of the system 400 can be remote from a wellsite. For example, to one side of a dashed line appear a remote operation command center block 492, a database block 493, a drilling workflow framework block 494, a SAP/ERP block 495 and a field services delivery block 496. Various blocks that may be remote can be operatively coupled to one or more blocks that may be local to a wellsite system. For example, a communication link 412 is illustrated in the example of FIG. 4 that can operatively couple the blocks 406 and 492 (e.g., as to monitoring, remote control, etc.), while another communication link 414 is illustrated in the example of FIG. 4 that can operatively couple the blocks 406 and 496 (e.g., as to equipment delivery, equipment services, etc.). Various other examples of possible communication links are also illustrated in the example of FIG. 4.

As an example, the system 400 of FIG. 4 may be a field management tool. As an example, the system 400 of FIG. 4 may include a drilling framework (see, e.g., the drilling framework 304). As an example, blocks in the system 400 of FIG. 4 that may be remote from a wellsite.

As an example, a wellbore can be drilled according to a drilling plan that is established prior to drilling. Such a drilling plan, which may be a well plan or a portion thereof, can set forth equipment, pressures, trajectories and/or other parameters that define drilling process for a wellsite. As an example, a drilling operation may then be performed according to the drilling plan (e.g., well plan). As an example, as information is gathered, a drilling operation may deviate from a drilling plan. Additionally, as drilling or other operations are performed, subsurface conditions may change. Specifically, as new information is collected, sensors may transmit data to one or more surface units. As an example, a surface unit may automatically use such data to update a drilling plan (e.g., locally and/or remotely).

As an example, the drilling workflow framework 494 can be or include a G&G system and a well planning system. As an example, a G&G system corresponds to hardware, software, firmware, or a combination thereof that provides support for geology and geophysics. In other words, a geologist who understands the reservoir may decide where to drill the well using the G&G system that creates a three-dimensional model of the subsurface formation and includes simulation tools. The G&G system may transfer a well trajectory and other information selected by the geologist to a well planning system. The well planning system corresponds to hardware, software, firmware, or a combination thereof that produces a well plan. In other words, the well plan may be a high-level drilling program for the well. The well planning system may also be referred to as a well plan generator.

In the example of FIG. 4, various blocks can be components that may correspond to one or more software modules, hardware infrastructure, firmware, equipment, or any combination thereof. Communication between the components may be local or remote, direct or indirect, via application programming interfaces, and procedure calls, or through one or more communication channels.

As an example, various blocks in the system 400 of FIG. 4 can correspond to levels of granularity in controlling operations of associated with equipment and/or personnel in an oilfield. As shown in FIG. 4, the system 400 can include the orchestration block 402 (e.g., for well plan execution), the integration block 404 (e.g., process manager collection), the core and services block 406, and the equipment block 408.

The orchestration block 402 may be referred to as a well plan execution system. For example, a well plan execution system corresponds to hardware, software, firmware or a combination thereof that performs an overall coordination of the well construction process, such as coordination of a drilling rig and the management of the rig and the rig equipment. A well plan execution system may be configured to obtain the general well plan from well planning system and transform the general well plan into a detailed well plan. The detailed well plan may include a specification of the activities involved in performing an action in the general well plan, the days and/or times to perform the activities, the individual resources performing the activities, and other information.

As an example, a well plan execution system may further include functionality to monitor an execution of a well plan to track progress and dynamically adjust the plan. Further, a well plan execution system may be configured to handle logistics and resources with respect to on and off the rig. As an example, a well plan execution system may include multiple sub-components, such as a detailer that is configured to detail the well planning system plan, a monitor that is configured to monitor the execution of the plan, a plan manager that is configured to perform dynamic plan management, and a logistics and resources manager to control the logistics and resources of the well. In one or more embodiments, a well plan execution system may be configured to coordinate between the different processes managed by a process manager collection (see, e.g., the integration block 404). In other words, a well plan execution system can communicate and manage resource sharing between processes in a process manager collection while operating at, for example, a higher level of granularity than process manager collection.

As to the integration block 404, as mentioned, it may be referred to as a process manager collection. In one or more embodiments, a process manager collection can include functionality to perform individual process management of individual domains of an oilfield, such as a rig. For example, when drilling a well, different activities may be performed. Each activity may be controlled by an individual process manager in the process manager collection. A process manager collection may include multiple process managers, whereby each process manager controls a different activity (e.g., activity related to the rig). In other words, each process manager may have a set of tasks defined for the process manager that is particular to the type of physics involved in the activity. For example, drilling a well may use drilling mud, which is fluid pumped into well in order to extract drill cuttings from the well. A drilling mud process manager may exist in a process manager collection that manages the mixing of the drilling mud, the composition, testing of the drilling mud properties, determining whether the pressure is accurate, and performing other such tasks. The drilling mud process manager may be separate from a process manager that controls movement of drill pipe from a well. Thus, a process manager collection may partition activities into several different domains and manages each of the domains individually. Amongst other possible process managers, a process manager collection may include, for example, a drilling process manager, a mud preparation and management process manager, a casing running process manager, a cementing process manager, a rig equipment process manager, and other process managers. Further, a process manager collection may provide direct control or advice regarding the components above. As an example, coordination between process managers in a process manager collection may be performed by a well plan execution system.

As to the core and services block 406 (e.g., CS block), it can include functionality to manage individual pieces of equipment and/or equipment subsystems. As an example, a CS block can include functionality to handle basic data structure of the oilfield, such as the rig, acquire metric data, produce reports, and manages resources of people and supplies. As an example, a CS block may include a data acquirer and aggregator, a rig state identifier, a real-time (RT) drill services (e.g., near real-time), a reporter, a cloud, and an inventory manager.

As an example, a data acquirer and aggregator can include functionality to interface with individual equipment components and sensor and acquire data. As an example, a data acquirer and aggregator may further include functionality to interface with sensors located at the oilfield.

As an example, a rig state identifier can includes functionality to obtain data from the data acquirer and aggregator and transform the data into state information. As an example, state information may include health and operability of a rig as well as information about a particular task being performed by equipment.

As an example, RT drill services can include functionality to transmit and present information to individuals. In particular, the RT drill services can include functionality to transmit information to individuals involved according to roles and, for example, device types of each individual (e.g., mobile, desktop, etc.). In one or more embodiments, information presented by RT drill services can be context specific, and may include a dynamic display of information so that a human user may view details about items of interest.

As an example, in one or more embodiments, a reporter can include functionality to generate reports. For example, reporting may be based on requests and/or automatic generation and may provide information about state of equipment and/or people.

As an example, a wellsite “cloud” framework can correspond to an information technology infrastructure locally at an oilfield, such as an individual rig in the oilfield. In such an example, the wellsite “cloud” framework may be an “Internet of Things” (IoT) framework. As an example, a wellsite “cloud” framework can be an edge of the cloud (e.g., a network of networks) or of a private network.

As an example, an inventory manager can be a block that includes functionality to manage materials, such as a list and amount of each resource on a rig.

In the example of FIG. 4, the equipment block 408 can correspond to various controllers, control unit, control equipment, etc. that may be operatively coupled to and/or embedded into physical equipment at a wellsite such as, for example, rig equipment. For example, the equipment block 408 may correspond to software and control systems for individual items on the rig. As an example, the equipment block 408 may provide for monitoring sensors from multiple subsystems of a drilling rig and provide control commands to multiple subsystem of the drilling rig, such that sensor data from multiple subsystems may be used to provide control commands to the different subsystems of the drilling rig and/or other devices, etc. For example, a system may collect temporally and depth aligned surface data and downhole data from a drilling rig and transmit the collected data to data acquirers and aggregators in core services, which can store the collected data for access onsite at a drilling rig or offsite via a computing resource environment.

As mentioned, the system 400 of FIG. 4 can be associated with a plan where, for example, the plan/replan block 422 can provide for planning and/or re-planning one or more operations, etc.

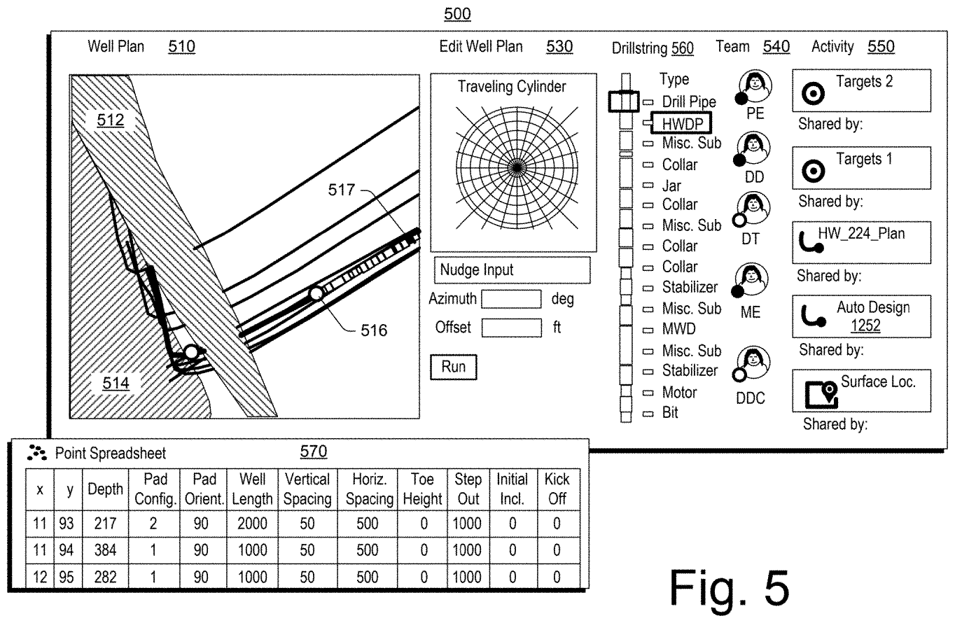

FIG. 5 shows an example of a graphical user interface (GUI) 500 that includes information associated with a well plan. Specifically, the GUI 500 includes a panel 510 where surfaces representations 512 and 514 are rendered along with well trajectories where a location 516 can represent a position of a drillstring 517 along a well trajectory. The GUI 500 may include one or more editing features such as an edit well plan set of features 530. The GUI 500 may include information as to individuals of a team 540 that are involved, have been involved and/or are to be involved with one or more operations. The GUI 500 may include information as to one or more activities 550. As shown in the example of FIG. 5, the GUI 500 can include a graphical control of a drillstring 560 where, for example, various portions of the drillstring 560 may be selected to expose one or more associated parameters (e.g., type of equipment, equipment specifications, operational history, etc.). FIG. 5 also shows a table 570 as a point spreadsheet that specifies information for a plurality of wells.

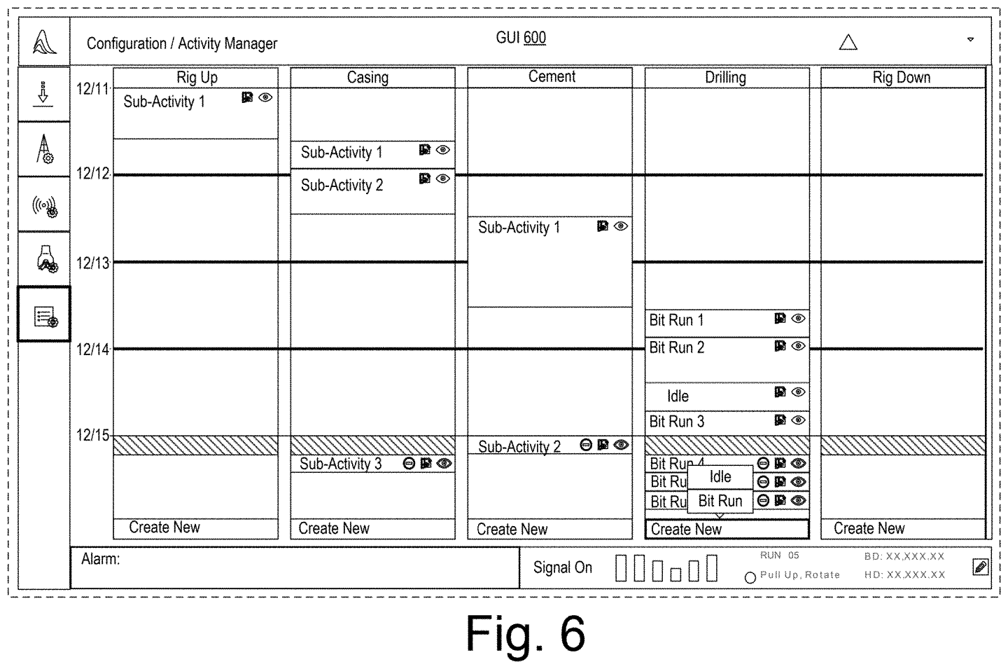

FIG. 6 shows an example of a graphical user interface (GUI) 600 that includes a calendar with dates for various operations that can be part of a plan. For example, the GUI 600 shows rig up, casing, cement, drilling and rig down operations that can occur over various periods of time. Such a GUI may be editable via selection of one or more graphical controls.

Various types of data associated with field operations can be 1-D series data. For example, consider data as to one or more of a drilling system, downhole states, formation attributes, and surface mechanics being measured as single or multi-channel time series data.

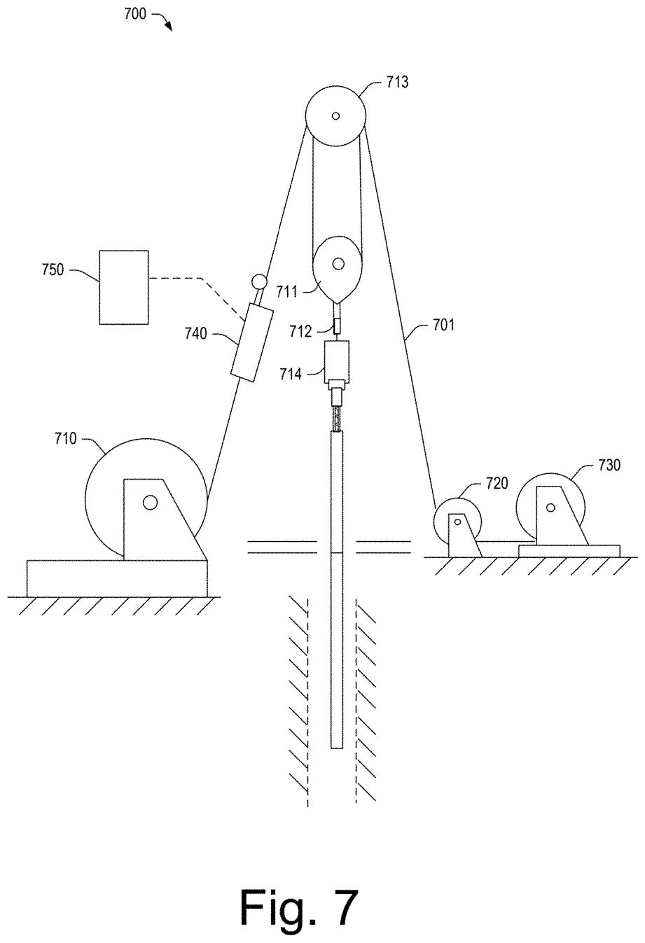

FIG. 7 shows an example of various components of a hoisting system 700, which includes a cable 701, drawworks 710, a traveling block 711, a hook 712, a crown block 713, a top drive 714, a cable deadline tiedown anchor 720, a cable supply reel 730, one or more sensors 740 and circuitry 750 operatively coupled to the one or more sensors 740. In the example of FIG. 7, the hoisting system 700 can include various sensors, which may include one or more of load sensors, displacement sensors, accelerometers, etc. As an example, the cable deadline tiedown anchor 720 may be fit with a load cell (e.g., a load sensor).

The hoisting system 700 may be part of a wellsite system (see, e.g., FIG. 1 and FIG. 2). In such a system, a measurement channel can be a block position measurement channel, referred to as BPOS, which provides measurements of a height of a traveling block, which may be defined about a deadpoint (e.g., zero point) and may have deviations from that deadpoint in positive and/or negative directions. For example, consider a traveling block that can move in a range of approximately −5 meters to +45 meters, for a total excursion of approximately 50 meters. As an example, a null point or deadpoint may be defined to make a scale positive, negative or both positive and negative. In such an example, a rig height can be greater than approximately 50 meters (e.g., a crown block can be set at a height from the ground or rig floor in excess of approximately 50 meters). While various examples are given for land-based field operations (e.g., fixed, truck-based, etc.), various methods can apply for marine-based operations (e.g., vessel-based rigs, platform rigs, etc.).

BPOS is a type of real-time channel that reflects surface mechanical properties of a rig. Another example of a channel is hook load, which can be referred to as HKLD. HKLD can be a 1-D series measurement of the load of a hook. As to a derivative, a first derivative can be a load velocity and a second derivative can be a load acceleration. Such data channels can be utilized to infer and monitor various operations and/or conditions. In some examples, a rig may be represented as being in one or more states, which may be referred to as rig states.

As to the HKLD channel, it can help to detect if a rig is “in slips”, while the BPOS channel can be a primary channel for depth tracking during drilling. For example, BPOS can be utilized to determine a measured depth in a geologic environment (e.g., a borehole being drilled, etc.). As to the condition or state “in slips”, HKLD is at a much lower value than in the condition or state “out of slips”.

The term slips refers to a device or assembly that can be used to grip a drillstring (e.g., drillcollar, drillpipe, etc.) in a relatively non-damaging manner and suspend it in a rotary table. Slips can include three or more steel wedges that are hinged together, forming a near circle around a drillpipe. On the drillpipe side (inside surface), the slips are fitted with replaceable, hardened tool steel teeth that embed slightly into the side of the pipe. The outsides of the slips are tapered to match the taper of the rotary table. After the rig crew places the slips around the drillpipe and in the rotary, a driller can control a rig to slowly lower the drillstring. As the teeth on the inside of the slips grip the pipe, the slips are pulled down. This downward force pulls the outer wedges down, providing a compressive force inward on the drillpipe and effectively locking components together. Then the rig crew can unscrew the upper portion of the drillstring (e.g., a kelly, saver sub, a joint or stand of pipe) while the lower part is suspended. After some other component is screwed onto the lower part of the drillstring, the driller raises the drillstring to unlock the gripping action of the slips, and a rig crew can remove the slips from the rotary.

A hook load sensor can be used to measure a weight of load on a drillstring and can be used to detect whether a drillstring is in-slips or out-of-slips. When the drillstring is in-slips, motion from the blocks or motion compensator do not have an effect on the depth of a drill bit at the end of the drillstring (e.g., it will tend to remain stationary). Where movement of a traveling block is via a drawworks encoder (DWE), which can be mounted on a shaft of the drawworks, acquired DWE information (e.g., BPOS) does not augment the recorded drill bit depth. When a drillstring is out-of-slips (e.g., drilling ahead), DWE information (e.g., BPOS) can augment the recorded bit depth. The difference in hook load weight (HKLD) between in-slips and out-of-slips tends to be distinguishable. As to marine operations, heave of a vessel can affect bit depth whether a drillstring is in-slips or out-of-slips. As an example, a vessel can include one or more heave sensors, which may sense data that can be recorded as 1-D series data.

As to marine operations, a vessel may experience various types of motion, such as, for example, one or more of heave, sway and surge. Heave is a linear vertical (up/down) motion, sway is linear lateral (side-to-side or port-starboard) motion, and surge is linear longitudinal (front/back or bow/stern) motion imparted by maritime conditions. As an example, a vessel can include one or more heave sensors, one or more sway sensors and/or one or more surge sensors, each of which may sense data that can be recorded as 1-D series data.

As an example, BPOS alone, or combined with one or more other channels, can be used to detect whether a rig is “on bottom” drilling or “tripping”, etc. An inferred state may be further consumed by one or more systems such as, for example, an automatic drilling control system, which may be a dynamic field operations system or a part thereof. In such an example, the conditions, operations, states, etc., as discerned from BPOS and/or other channel data may be predicates to making one or more drilling decisions, which may include one or more control decisions (e.g., of a controller that is operatively coupled to one or more pieces of field equipment, etc.).

A block can be a set of pulleys used to gain mechanical advantage in lifting or dragging heavy objects. There can be two blocks on a drilling rig, the crown block and the traveling block. Each can include several sheaves that are rigged with steel drilling cable or line such that the traveling block may be raised (or lowered) by reeling in (or out) a spool of drilling line on the drawworks. As such, block position can refer to the position of the traveling block, which can vary with respect to time. FIG. 1 shows the traveling block assembly 175, FIG. 2 shows the traveling block 211 and FIG. 7 shows the traveling block 711.

A hook can be high-capacity J-shaped equipment used to hang various equipment such as a swivel and kelly, elevator bails, or a topdrive. FIG. 7 shows the hook 712 as operatively coupled to a topdrive 714. As shown in FIG. 2, a hook can be attached to the bottom of the traveling block 211 (e.g., part of the traveling block assembly 175 of FIG. 1). A hook can provide a way to pick up heavy loads with a traveling block. The hook may be either locked (e.g., a normal condition) or free to rotate, so that it may be mated or decoupled with items positioned around the rig floor, etc.

Hook load can be the total force pulling down on a hook as carried by a traveling block. The total force includes the weight of the drillstring in air, the drill collars and ancillary equipment, reduced by forces that tend to reduce that weight. Some forces that might reduce the weight include friction along a bore wall (especially in deviated wells) and buoyant forces on a drillstring caused by its immersion in drilling fluid (e.g., and/or other fluid). If a blowout preventer (BOP) (e.g., or BOPs) is closed, pressure in a bore acting on cross-sectional area of a drillstring in the BOP can also exert an upward force.

A standpipe can be a rigid metal conduit that provides a high-pressure pathway for drilling fluid to travel approximately one-third of the way up the derrick, where it connects to a flexible high-pressure hose (e.g., kelly hose). A large rig may be fitted with more than one standpipe so that downtime is kept to a minimum if one standpipe demands repair. FIG. 2 shows the standpipe 208 as being a conduit for drilling fluid (e.g., drilling mud, etc.). Pressure of fluid within the standpipe 208 can be referred to as standpipe pressure.

As to surface torque, such a measurement can be provided by equipment at a rig site. As an example, one or more sensors can be utilized to measure surface torque, which may provide for direct and/or indirect measurement of surface torque associated with a drillstring. As an example, equipment can include a drill pipe torque measurement and controller system with one or more of analog frequency output and digital output. As an example, a torque sensor may be associated with a coupling that includes a resilient element operatively joining an input element and an output element where the resilient element allows the input and output elements to twist with respect to one another in response to torque being transmitted through the torque sensor where the twisting can be measured and used to determine the torque being transmitted. As an example, such a coupling can be located between a drive and drill pipe. As an example, torque may be determined via an inertia sensor or sensors. As an example, equipment at a rig site can include one or more sensors for measurement and/or determination of torque (e.g., in units of Nm, etc.).

As an example, equipment can include a real-time drilling service system that may provide data such as weight transfer information, torque transfer information, equivalent circulation density (ECD) information, downhole mechanical specific energy (DMSE) information, motion information (e.g., as to stall, stick-slip, etc.), bending information, vibrational amplitude information (e.g., axial, lateral and/or torsional), rate of penetration (ROP) information, pressure information, differential pressure information, flow information, etc. As an example, sensor information may include inclination, azimuth, total vertical depth, etc. As an example, a system may provide information as to whirl (e.g., backward whirl, etc.) and may optionally provide information such as one or more alerts (e.g., “severe backward whirl: stop and restart with lower surface RPM”, etc.).

As an example, a drillstring can include a tool or tools that include various sensors that can make various measurements. For example, consider the OPTIDRILL tool (Schlumberger Limited, Houston, Tex.), which includes strain gauges, accelerometers, magnetometer(s), gyroscope(s), etc. For example, such a tool can acquire weight on bit measurements (WOB) using a strain gauge (e.g., 10 second moving window with bandwidth of 200 Hz), torque measurements using a strain gauge (e.g., 10 second moving window with bandwidth of 200 Hz), bending moment using a strain gauge (e.g., 10 second moving window with bandwidth of 200 Hz), vibration using one or more accelerometers (e.g., 30 second RMS with bandwidth of 0.2 to 150 Hz), rotational speed using a magnetometer and a gyroscope (e.g., 30 moving window with bandwidth of 4 Hz), annular and internal pressures using one or more strain gauges (e.g., 1 second average with bandwidth of 200 Hz), annular and internal temperatures using one or more temperature sensors (1 second average with bandwidth of 10 Hz), and continuous inclination using an accelerometer (30 second average with bandwidth of 10 Hz).

As mentioned, channels of real time drilling operation data can be received and characterized using generated synthetic data, which may be generated based at least in part on one or more operational parameters associated with the real time drilling operation. Such real time drilling operation data can include surface data and/or downhole data. As mentioned, data availability may differ temporally (e.g., frequency, gaps, etc.) and/or otherwise (e.g., resolution, etc.). Such data may differ as to noise level and/or noise characteristics. While various types of sensors are mentioned, equipment may be utilized that may not include one or more types of downhole sensors. In such instances, a method may be utilized that can determine one or more downhole values.

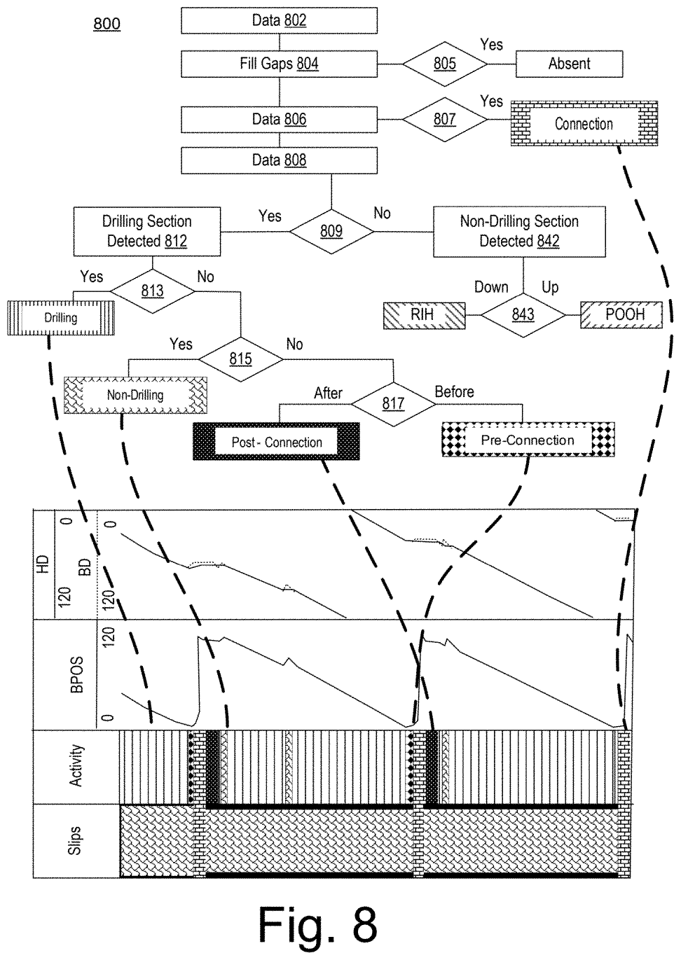

FIG. 8 shows an example of a method 800 that includes various blocks that can receive data, perform one or more analyses, perform one or more decisions, etc., to determine one or more states. In the example of FIG. 8, various examples of states are illustrated with respect to color. In FIG. 8, the example states include drilling, non-drilling, run-in-hole (RIH), pull-out-of-hole (POOH), pre-connection, connection, post-connection, and absent.

Drilling is drilling to increase the depth of a wellbore. Non-drilling activity can be determined to be occurring when no other activities are occurring (e.g., drilling, RIH, POOH, pre-connection, connection, post connection) and where the end of a current drill stand has not yet been reached. During non-drilling, the flow rate of fluid being pumped into a drillstring may increase and/or decrease, the rate of rotation of a drillstring may increase and/or decrease, a downhole tool (e.g., a drill bit) may move upwards and/or downwards, or a combination thereof. A non-drilling activity may be or include a time when a drill bit is idle (e.g., not drilling) and a slips assembly is not engaged with a drillstring.

Pre-connection can be where a downhole tool (e.g., a drill bit) has completed drilling operations for a current section of pipe, but the slips assembly has not begun to move (e.g., radially-inward) into engagement with the drillstring. During pre-connection, the flow rate of fluid being pumped into the drillstring may increase and/or decrease, the rate of rotation of the drillstring may increase and/or decrease, the downhole tool (e.g., the drill bit) may move upwards and/or downwards, or a combination thereof.

Connection can be where a slips assembly is engaged with, and supports, a drillstring (e.g., the drillstring is “in-slips”). When a connection is occurring, a segment (e.g., a pipe, a stand, etc.) may be added to the drillstring to increase the length of the drillstring, or a segment may be removed from the drillstring to reduce the length of the drillstring.

Post-connection can be where the drillstring is released by a slips assembly, and a downhole tool (e.g., the drill bit) are lowered to be on-bottom (e.g., bottom of hole or BOH). During post-connection, the flow rate of fluid being pumped into a drillstring may increase/and/or decrease, the rate of rotation of a drillstring may increase and/or decrease, a downhole tool (e.g., the drill bit) may move upwards and/or downwards, or a combination thereof.

As to an absent state, it can indicate a scenario where data are not being received (e.g., at least one of a plurality of inputs is missing).

As an example, a method can be utilized to determine a slips status. For example, slips status may include one or more of the following: In-slips where a slips assembly is engaged with, and supports, a drillstring (“in-slips”); out-of-slips where the slips assembly is not engaged with, and does not support, the drillstring; and absent where data are not received (e.g., at least one of the inputs is missing).

The method 800 of FIG. 8 can include various data acquisition or data reception blocks 802, 806, 808, etc., various decision block 805, 807, 809, 813, 815, 817, and 843, detection blocks 812 and 842 and state blocks. Measurements may include (1) a depth of a wellbore, (2) a depth of a drill bit, (3) a position of a travelling block, or a combination thereof. A set of measurements may or may not include weight on hook (e.g., HKLD), or weight on a drill bit (e.g., WOB). Each set of measurements may be captured/received a predetermined amount of time after a previous set of measurements is captured/received. A predetermined amount of time may be, for example, about three seconds; however, the predetermined amount of time may be shorter or longer.

A PCT publication WO 2017/221046 A1 of 28 Dec. 2017 is incorporated by reference herein and entitled “Automatic drilling activity detection” ('046 publication). The '046 publication describes a method of determining a drilling activity that includes receiving a set of measurements at different times. The set of measurements can include a depth of a wellbore, a depth of a drill bit, and a position of a travelling block. The method may also include identifying a connection by determining when the position of the travelling block changes but the depth of the drill bit does not change. The method may also include determining when the depth of the wellbore does not increase between two different connections. The method may also include determining a direction that the drill bit moves between the two connections.

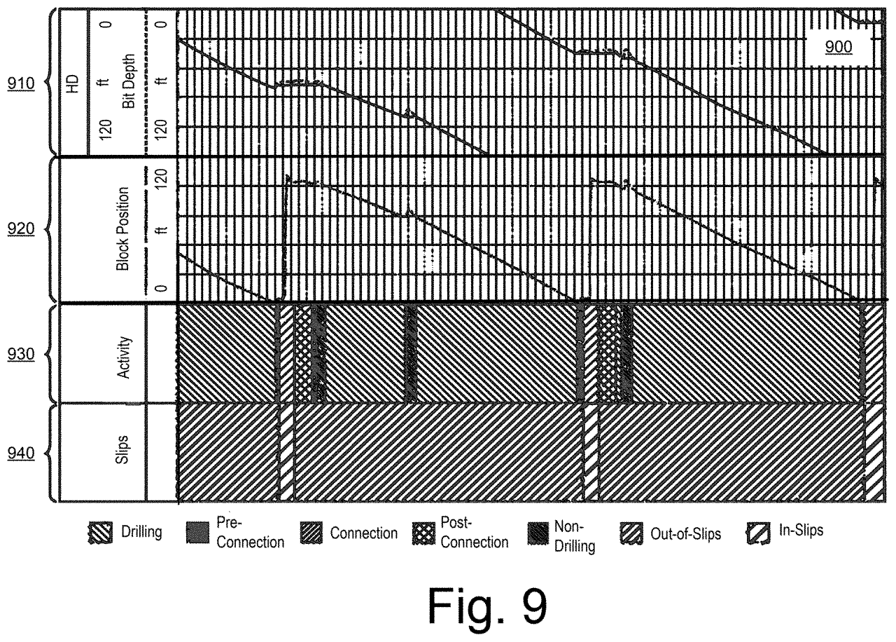

FIG. 9 shows an example of a graph 900 showing time intervals including drilling, pre-connection, connection, post-connection, and non-drilling activity, according to an embodiment. The time is shown on the X-axis and totals about 3 hours. A top quarter 910 of the graph 900 shows the depth of a wellbore versus time. The next quarter 920 of the graph 900 shows the position of a travelling block versus time. The next quarter 930 of the graph 900 shows time intervals where a downhole tool (e.g., a drill bit) is drilling, where a pre-connection occurs, where connection occurs, where post-connection occurs, and where non-drilling activity occurs. The bottom quarter 940 of the graph 900 shows the time intervals where the drillstring is engaged with, and supported by, the slips assembly (in-slips) and where the drillstring is not engaged with, or supported by, the slips assembly (out-of-slips). As may be seen, the travelling block moves upward during a connection and downward during drilling. In addition, the drillstring is in-slips when a connection is occurring and out-of-slips when a connection is not occurring.

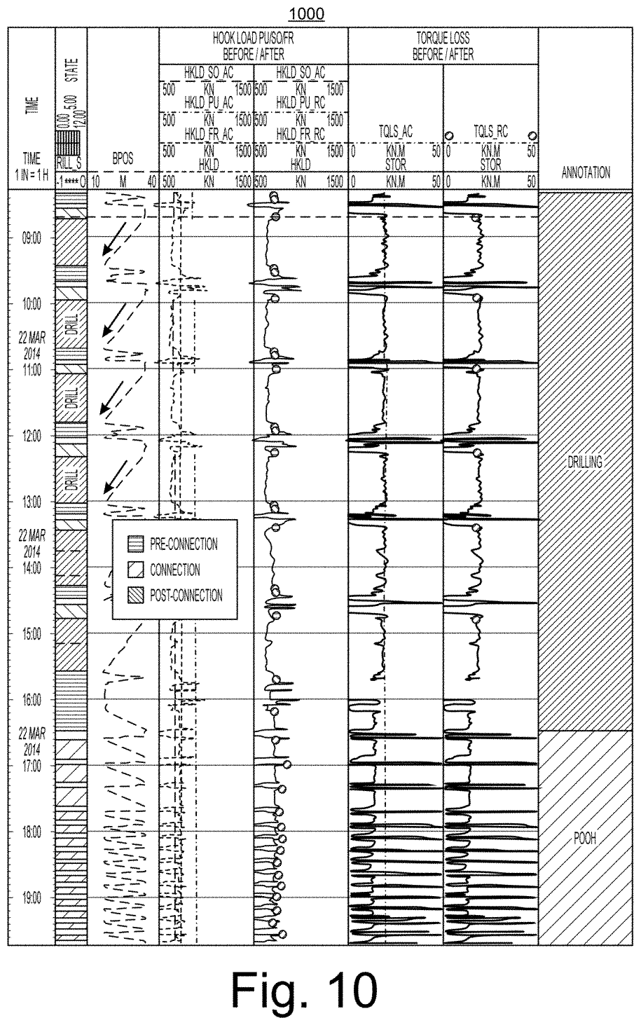

FIG. 10 shows an example of a graphical user interface (GUI) 1000 that includes various sets of data with respect to time. In the example of FIG. 10, the GUI 1000 includes a drill state track that may utilize a particular color scheme where green corresponds to drilling (deepening a wellbore), red corresponds to a pre-connection state, black corresponds to a post-connection state and gray corresponds to a connection state. As to time series data, BPOS, HKLD and STOR are shown with respect to time. Specifically, BPOS is shown with respect to distance (e.g., 10 meters to 40 meters, etc.), HKLD is shown with respect to kN (e.g., 500 kN to 1500 kN), and STOR is shown as torque loss in kN.m (e.g., 0 kN.m to 50 kN.m). In the example of FIG. 10, various values are labeled AC and various values are labeled RC. The values labeled RC are improved values in comparison to the values labeled AC. As an example, a method can include detecting pickup (PU)/slackoff (SO) weights and downhole weight on bit (DWOB) and torque (TQLS, downhole torque (DTOR), etc.) based on machine learning of surface sensors. Such a method can output values that are improved as to various operations, particularly where equipment may be without one or more types of downhole sensors. For example, consider a scenario where operations occur without a downhole torque sensor. In such an example, a method can implement a trained machine model to determine one or more downhole torque values.

As an example, a method can include an interface for receiving the following inputs: DRILL_STATE, drill state [unitless]; BPOS, block position [m]; RPM, rotations per minute [c/min]; HKLD, hook load [kN]; and STOR, surface torque [kN.m]. Such a method can utilize such inputs to output the following outputs: HKLD_SO, hook load—slack off [kN], block is going down; HKLD_PU, hook load—pick up [kN], block is going up; HKLD_FR, hook load—free rotate [kN]; DWOB, downhole weight on bit [kN]; TQLS, torque—loss [kN.m]; DTOR, torque—downhole [kN.m], DTOR=STOR−TQLS.

Referring again to the GUI 1000 of FIG. 10, various inputs and outputs are shown. For example, inputs include DRILL_STATE, BPOS, HKLD, and STOR and outputs include HKLD_SO, HKLD_PU, HKLD_FR, and TQLS, which may be coded (e.g., color, shading, hatching, etc.).

During a drilling process, information associated with connections between drilling stands can be utilized. Historically, drilling parameters at connection were taken at a rig site with inconsistencies due to crew changes. To reduce the impact of human factors and select measurement points in a more systematic way various algorithms were developed; however, such algorithms had limits due to inconsistencies in practices of a driller and/or due to different process applied by one drilling company to another.

As an example, a system can include one or more processors, memory and instructions that can instruct the system to operate in a robust manner to retrieve off bottom measurements such as off bottom measurements for load, torque and pressure. For example, consider an algorithm of a mudlogging system or an algorithm for the Perform Tool Kit (PTK) with autocalibration (Schlumberger Limited, Houston, Tex.). Such an algorithm may operate to output values that can be utilized to determine hook load at connection for pickup (PU) and/or slackoff (SO) and also downhole drilling parameters for WOB, torque at bit (TAB) and pressure at bit (PAB). Computed downhole drilling parameters can be used when downhole measurements are not taken or not available. Such computed values can be useful, for example, for land rig operations where PU and SO values may be a first indicator of stuck pipe during drilling and/or tripping operations.

In the context of monitoring and drilling data analysis in real time, computations for such values can be used for display of a broomstick model against actual measurement values, and for on bottom drilling efficiency analysis.

Drilling analysis software implemented as a computational framework can be confronted with real time surface data of poor quality in a vendor neutral context. Data can be of relatively low frequency data (e.g., consider 0.1 Hz sample rate) and inconsistent drilling practices at connection time can make unavailable some types of computations that can impact confidence in such software itself.

As mentioned with respect to the example GUI 1000, a method can provide for determinations of various phenomena associated with drilling operations. For example, determinations may be made for torque losses and pickup (PU)/slackoff (SO)/free rotate (FR) weights on data (e.g., vendor free data, etc.) even in instances with poor quality. Such a method may operate in an automated manner. Such a method may provide for estimating one or more operation friction factors. As an example, a method can include determining one or more values that are germane to sticking. As an example, a method can include determining values that indicate a risk (e.g., a probability of stuck pipe). As an example, a method can be implemented as part of a control system that can operate to reduce risk of stuck pipe and/or reduce incidents of pipe sticking. As an example, a method can provide for detection of stuck pipe. As an example, a method can be implemented as part of a stuck pipe detection workflow. In such an example, the workflow may reduce occurrence of stuck pipe and/or detect stuck pipe.

As an example, a method can provide for detecting torque losses and/or one or more of pickup (PU), slackoff (SO) and free rotate (FR) weights in time data series. For example, such a method can utilize a trained machine model and may include training a machine model. As an example, machine learning techniques can replace manual entry of one or more interpretation parameters. As an example, an approach can select a number of channels where the selected channels allow for reduction in user error (e.g., error minimization, etc.) and/or data quality issues. As an example, a method can, for each individual output, involve filtering data points with one or more criteria where such criteria can include one or more criteria based on physics of a process. In such a method, where applied to stands of drilling operations, a final point for each individual stand can be taken statistically, for example, as a median of points. Such an approach can act to reduce impact(s) of noise in data from one or more surface sensors.

As an example, a stand can be two or three single joints of drillpipe or drill collars that remain screwed together during a tripping operation. Various medium- to deep-capacity drilling rigs can handle three-joint stands, called “trebles” or “triples”. Some smaller rigs have capacity for two-joint stands, called “doubles”. As an example, an operation can involve standing drillpipe or drill collars back upright in a derrick and placing them into fingerboards to keep them orderly. Such an approach tends to be a relatively efficient way to remove drillstring from a well when changing a drill bit or making adjustments to a bottomhole assembly (BHA). As an example, an approach can involve unscrewing threaded connections. As an example, in some instances a “stand” may be a single uncoupled segment of a drillstring. While placing upright is mentioned, in some instances, other orientations may be utilized. For example, in an operation that involves unscrewing threaded connection, sections of pipe may be placed in a horizontal position.

While threads are mentioned, various types of equipment may be connected via nonthreaded unions or joints. A connection may be a threaded union or joint or a nonthreaded union or joint that connects two tubular components. Connecting can be an operation of adding a segment, for example, adding a joint or a stand of drillpipe to a top of the drillstring (e.g., “making a connection”). The opposite operation can be utilized for removing a segment (e.g., disconnecting, etc.).

As to surface sensor measurements, during an operation, movement may be less consistent for about connection/disconnection operations. For example, when tripping, movement can slow (e.g., decelerate) and then quicken (e.g., accelerate). Between times of acceleration and deceleration, movement may be more consistent. Where movement is more consistent, surface sensor data may be of a higher signal to noise ratio (SNR) when compared to instances where movement is less consistent (e.g., deceleration and/or acceleration). As an example, a method can include processing sensor data to effectively select data points (e.g., samples) that are within a period of time (e.g., or periods of time) where movement is more consistent. While such an approach can reduce the number of data points utilized, the data points that are utilized can be of lesser noise (e.g., higher SNR, etc.). As an example, a method can involve detecting a connection time or connection times and selecting a window of time series data that is at a time delta from the connection time or connection times. For example, consider time series data that spans a period of time t-total from a connection 1 to a connection 2 where a window is selected that is less than t-total and that does not include data points in a period of time t-1 after the connection 1 and does not include data points in a period of time t-2 before the connection 2. Such an approach may select the window based on percent, number of data points (e.g., given a sampling rate), using a velocity based criterion (e.g., average velocity, etc.), using a total time based criterion, using an acceleration criterion, using a deceleration criterion, etc.

As an example, consider a method that utilizes a statistical approach for weights and torques detection based on a previous stand experience.

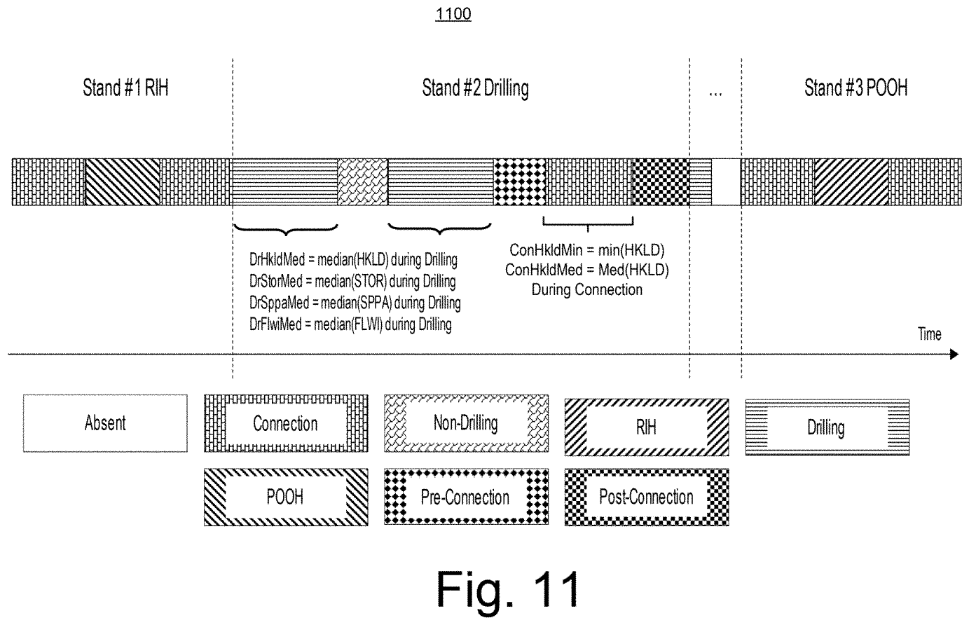

FIG. 11 shows an example of a graphic 1100 of a timeline with various states associated with operations where there can be associated time series data. The graphic 1100 is organized from left to right in terms of a sequence of operations that includes RIH, drilling and POOH. For example, consider tripping in a drillstring, drilling using the drillstring and tripping out the drillstring (e.g., for drill bit replacement, BHA modification, etc.). The various operations can involve connecting stands or disconnecting stands as well as periods of acceleration and/or deceleration of the drillstring.

In the example of FIG. 11, time series data can include surface torque time series data (STOR) and hook load time series data (HKLD). Again, FIG. 10 shows some examples of such types of data. As an example, a method can include filtering using a median, which may be a median of a weight, a torque, etc.

As indicated in the graphic 1100, a method can include splitting stand types into categories such as the three categories: RIH, Drilling, and POOH. During drilling intervals of the stand, the method may include computing a median high value of surface torque (DrStorMed). As an example, such a computed value can be utilized as a threshold for torque loss detection, which may be accompanied by an assumption that it will not result in negative downhole torque in the next stand. As shown in the graphic 1100, during a connection interval of the drilling stand, the method can include computing a minimum hook load value (ConHkldMin) and/or a median hook load value (ConHkldMed). As an example, such a computed value can be utilized in filtering (e.g., to define a filter) for computing one or more weights such as, for example, pickup (PU) weight and/or slackoff (SO) weight.

As an example, a method can proceed as in the graphic 1100 of FIG. 11 where after thresholds have been identified, the method can proceed to detecting.

In the example of FIG. 11, a statistical approach and/or a probabilistic approach can be utilized for one or more of weight, torque and pressure detections based on previous stand experience. As mentioned, a method can include splitting stand types into three categories: RIH, Drilling, POOH. In such an example, during various intervals of a stand or stands, a method can include computing various statistical values that may be related to one or more conditions. For example, consider torque, hook load, pressure, flow, etc.

In the example of FIG. 11, various examples of median values are shown that can include, for example, one or more of median hook load during drilling (DrHkldMed), median surface torque during drilling (DrStorMed), median stand pipe pressure (e.g., absolute) during drilling (DrSppaMed) and median flow during drilling (DrFlwiMed). As an example, one or more of such values may be identified and utilized as one or more threshold values.

As an example, during a connection interval of a drilling stand, a method can include computing a threshold value where the threshold value may be used as a filter, for example, in a filter model, to compute one or more other values (e.g., weights such as pickup, slackoff, free rotate, torques, pressures, flowrates, etc.). In such an example, the filter or filter model may include one or more other types of parameters that may be, for example, determined via learning from data in one or more databases, etc.

As shown in FIG. 11, time series data can include surface torque time series data (STOR), hook load time series data (HKLD), standpipe time series data (SPPA), and flow time series data (FLWI) (e.g., mud flow rate in, etc.).

As an example, during a connection (e.g., a connection interval), a method can include computing a median hook load value (ConHkldMed), which may be utilized as a filter to compute a pickup weight and/or a slackoff weight.

As an example, after one or more of DrStorMed, DrHkldMed, ConHkldMed, DrSppaMed, and DrFlwiMed threshold values have been identified, a method can continue with one or more detection processes, which can include filtering using one or more filter models, which may be machine models that can include one or more parameter values that may be learned, for example, using offset well data, etc. For example, a threshold value can be considered a dynamic parameter while one or more other parameters may be determined via learning that uses offset well data, etc.

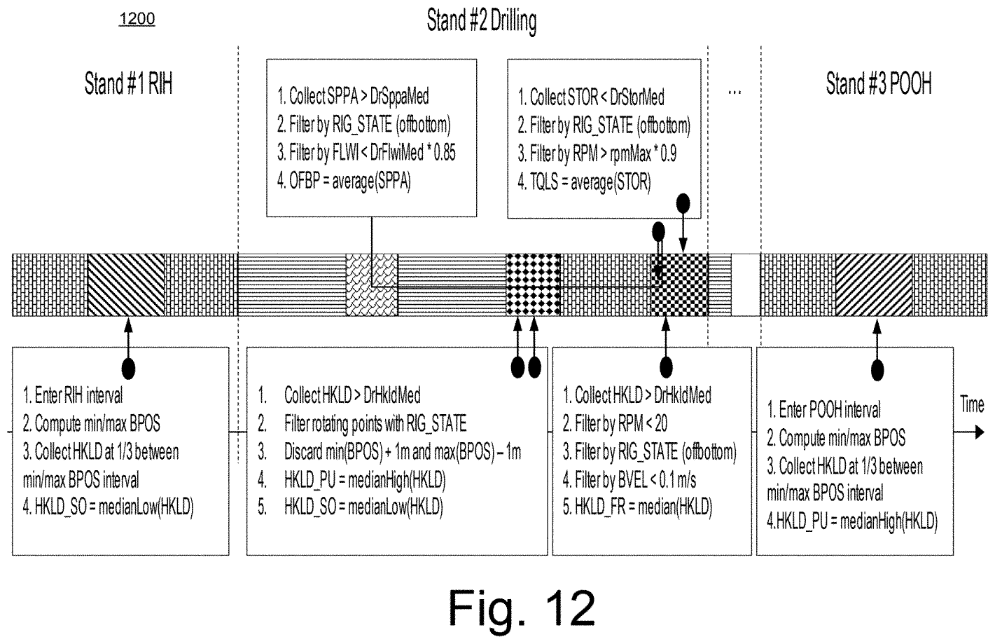

FIG. 12 shows an example of a GUI 1200 that includes a timeline with various states associated with operations where there can be associated time series data. The GUI 1200 shows some examples of processes that can be detection processes, for example, that can operate using one or more threshold values. As shown in the example of FIG. 12, the GUI 1200 can include various portions for three stands, including RIH, drilling and POOH. The GUI 1200 illustrates an approach to detection for TLQS, HKLD_FR, HKLD_SO, HKLD_PU, and OFBP (off-bottom pressure).

As an example, a method can include determining a weight value HKLD_FR in after connection (e.g., post-connection) as follows:
A. Collect data points during “After Connection” (e.g., post-connection);
B. Discard negative and missing HKLD points;
C. Discard points with RPM<20 c/min;
D. Discard points when bit is on bottom (RIG_STATE=0 or 1);
E. Discard points with block velocity >0.1 m/s;
F. Discard points with HKLD<DrHkldMed; and
G. Determine the final HKLD_FR result value to be taken as low median of the rest of points where it can be assumed safe to take the median to see an exact point picked, as HKLD does not tend to have much noise during this period.

As an example, a method can include determining a torque value TQLS in after connection (e.g., post-connection) as follows:
A. Collect valid STOR data points during “After Connection”;
B. Discard negative and missing STOR points;
C. Discard points when bit is on bottom (RIG_STATE=0 or 1);
D. Discard points with RPM<20 c/min or RPM<0.9*max(RPM);
E. Discard points with STOR>DrStorMed; and
F. Determine the final TQLS result value to be taken as the average of the rest of points where it can be assumed safer to take an average instead of median, as quite often there can be a substantial amount of STOR noise present during After Connection.

As an example, a method can include performing various computations in pre-connection as follows:
A. To compute HKLD_PU and HKLD_SO during drilling phase, collect points from pre-connection interval into two collections—one of pickup and one of slackoff (e.g., different directions of drillstring movement in a bore);
B. For both, first apply HKLD<ConHkldMed*1.1 filter;
C. For both discard rotating points based on RIG_STATE input;
D. For Pickup collection take points where BPOS increases, filtered by min(BPOS)+1 m<BPOS<max(BPOS)−1 m, and final HKLD_PU is taken as high median of the collection; and
E. For Slackoff collection take points where BPOS decreases, filtered by min(BPOS)+1<BPOS<max(BPOS)−1, and final HKLD_SO is taken as low median of the collection; noting that such an approach may tend to be more efficient than computing and comparing block velocity from block position.

As an example, a method can include performing various computations for RIH and/or POOH as follows:
A. During RIH and POOH phases Pre-Connection and Post-Connection are not defined because no Drilling occurs;
B. During analysis, compute min(BPOS) and max(BPOS), points taken at the interval of ⅓ between min(BPOS) and max(BPOS);
C. HKLD_SO during RIH is taken as low median of points; and
D. HKLD_PU during POOH is taken as high median of points.

As an example, a method can include performing various computations as to off-bottom pressure (OFBP) and/or differential pressure (DPRES), which may, for example, relate to operation of a downhole motor that can be driven at least in part by flow of fluid (e.g., a mud-motor, etc.) to turn a drill bit. For example, consider a method that can provide for determining off-bottom pressure (OFBP) and/or differential pressure (DPRES) via the following actions:
A. Learn SPPA (Standpipe Pressure) points during the previous drill stand (e.g., pre-connection), compute DrSppaMed=median(SPPA);
B. Learn FLWI (Mud flow rate in) points during the previous drill stand (e.g., pre-connection), compute DrFlwiMed=median(FLWI);
C. During the next post-connection (e.g., after connection), take the SPPA/FLWI samples;
D. Remove points with SPPA>DrSppaMed;
E. Remove onbottom points by taking Rig State=off-bottom;
F. Remove points with FLWI<0.85*DrFlwiMed;
G. Compute reference OFBP=average(SPPA) of the points left; and
H. Compute DPRES=SPPA−OFBP for the points of the next drill. stand.

In various examples, one or more parameters may be determined using one or more learning techniques, which may be machine model-based learning techniques. As an example, data from offset wells may be analyzed. In such an example, various parameter values may be tested to determine suitable parameter values for one or more methods. For example, consider various numeric values given above relating to RPM, block velocity, flow rate, etc., which may be part of one or more filtering processes. One or more of such numeric values may be determined using offset well data where, for example, the numeric values may be determined through use of a machine model that can be trained using the offset well data to arrive at the numeric values. Such an approach may aim to increase accuracy and/or applicability (e.g., robustness, etc.) of one or more of the techniques described with respect to the GUI 1200 of FIG. 12. For example, a set of parameter values may be determined for a particular type of formation, particular type of bottom hole assembly, particular type of drilling fluid, etc. As an example, one or more parameter values may be updated, which may be via a background process that can operate on one or more of offset well data, target well data, etc.

As an example, a method can include performing various computations as to off-bottom pressure (OFBP) and/or differential pressure (DPRES), which may, for example, relate to operation of a downhole motor that can be driven at least in part by flow of fluid (e.g., a mud-motor, etc.) to turn a drill bit. For example, consider a method that can provide for determining off-bottom pressure (OFBP) and/or differential pressure (DPRES) via the following actions:
A. Learn SPPA (Standpipe Pressure) points during the previous drill stand (e.g., pre-connection), compute DrSppaMed=median(SPPA);
B. Learn FLWI (Mud flow rate in) points during the previous drill stand (e.g., pre-connection), compute DrFlwiMed=median(FLWI);
C. During the next post-connection (e.g., after connection), take the SPPA/FLWI samples;
D. Remove points with SPPA>DrSppaMed;
E. Remove onbottom points by taking Rig State=off-bottom;
F. Remove points with FLWI<0.85*DrFlwiMed;
G. Compute reference OFBP=average(SPPA) of the points left; and
H. Compute DPRES=SPPA−OFBP for the points of the next drill. stand.

Referring again to the GUI 1200 of FIG. 12, some examples of parameter values may include “20 c/min” (e.g., RPM<20 c/min), “0.1 m/s” (e.g., block velocity >0.1 m/s), “20 c/min” or “0.9” (e.g., RPM<20 c/min or RPM<0.9*max(RPM)), “1.1” (e.g., HKLD<ConHkldMed*1.1), “0.85” (e.g, FLWI<0.85*DrFlwiMed), etc. Such values may be represented as parameters using a moniker such as “param” (e.g., param1, param2, param3, param4, etc.). As explained, a threshold can be another type of parameter that can be dynamic, which may be represented using a moniker such as “thres” (e.g., thres1, thres2, thres3, etc.).

As explained, various equations, techniques, etc., can be utilized for detecting one or more of TLQS, HKLD_FR, and HKLD_SO. As explained, one or more thresholds can be utilized in a method, for example, to collect particular HKLD time series data (e.g., filtering of HKLD time series data) and to collect particular STOR time series data (e.g., filtering of STOR time series data). As an example, a filter can be a low pass filter, a high pass filter, a band pass filter or another type of filter.

As shown, the graphic 1200 includes the partitions (e.g., phases) as in the graphic 1100 of FIG. 11. As an example, the graphic 1100 and/or the graphic 1200 may be rendered as a graphical user interface to a display. In such an example, one or more graphical controls may be utilized to interrogate one or more of the states, underlying data, computational parameters, etc.

To compute TQLS, a method can receive valid STOR data points during post-connection, where those STOR data point values are less than DrStorMed (e.g., or less than or equal to). As an example, a final TQLS result value can be taken as a low median of the filtered data points. As an example, a method can include using a certain point after connection (e.g., post-connection state) where it is possible to get a torque value (TQLS) that can be subtracted from the surface torque (STOR), as measured using a sensor, to estimate a downhole torque (DTOR) that is less than the surface torque (e.g., DTOR=STOR−TQLS). Referring again to FIG. 10, the track for TQLS_RC indicates a point that corresponds to a post-connection state in the state track. Such a point can be utilized to determine DTOR, which is an estimated real downhole torque. As mentioned, such a value can be useful with respect to stuck pipe detection, reduced risk of stuck pipe, control to address an indication of sticking, etc. As mentioned, the value of TQLS_RC is improved compared to the value of TQLS_AC; thus, DTOR can be improved and, corresponding, friction, sticking, etc. As indicated, without rotation of a drillstring, torque is zero (see, e.g., where STOR drops to zero).

To compute HKLD_FR, a method can receive data points during post-connection with valid HKLD and RPM. The method can then filter the data points via an equation RPM<0.7×max(RPM), which can be a filter model (e.g., a machine model filter). As an example, a final HKLD_FR result value can be taken as a low median of the filtered data points.

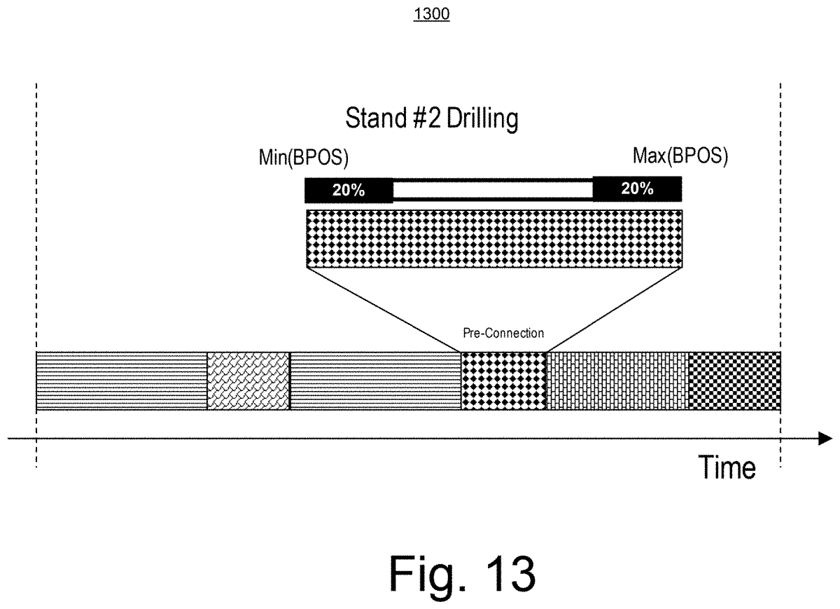

To compute HKLD_PU and HKLD_SO during the drilling phase, a method can receive points from the pre-connection interval for two collections, one for pickup (PU) and another for slackoff (SO). For both collections, a method can first apply a HKLD<ConHkldMin filter. Then collections can be filtered by a RPM>1 c/min condition. Then for the pickup (PU) collection, a method can take data points where BPOS increases, filtered by 1.2×min(BPOS)<BPOS<0.8×max(BPOS), and a final HKLD_PU can be taken as a high median of the collection. For the slackoff (SO) collection, a method can take points where BPOS decreases, filtered by 1.2×min(BPOS)<BPOS<0.8×max(BPOS), and a final HKLD_SO can be taken as a low median of the collection. An approach may, statistically, be more efficient than computing and comparing block velocity from block position (see, e.g., FIG. 13).

During RIH and POOH phases, pre-connection and post-connection are not defined because no drilling occurs. As an example, HKLD_SO during RIH may be taken as min(HKLD) when max(BPOS)−2 m<BPOS<max(BPOS). And, HKLD_PU during POOH can be taken as max(HKLD) when min(BPOS)<BPOS<min(BPOS)+2 m; noting that percentages may be utilized alternatively or additionally to distances.

Learning may occur in drilling where one or more filters can be applied to identify particular times (see, e.g., times indicated by various points in FIG. 10). As indicated, various phases can be accompanied by various rules, which can be model based rules (e.g., machine model based rules, etc.).

As explained, an approach may utilize filters that are “floating” such that minimum and maximum can be determined on a stand by stand basis. Such filters can be real-time, adaptive filters. Such an approach can allow for less “hard coding” of parameters and provide for a more robust approach to determination of downhole values. In various examples, various statistical metrics can be utilized (e.g., min, max, median, etc.). As to “hard coding”, RPM>1 and BPOS>0 may be utilized for filtering where “1” and “0” are hard coded. Such an approach can help to assure a certain amount of rotation and that BPOS are defined as being positive; noting that another approach may optionally utilize a negative or positive and negative scale for BPOS.

FIG. 13 shows an example of a graphic 1300 that illustrates a technique for PU and SO points detection based on block position (BPOS). As mentioned, various operations can involve one or more periods of inconsistent motion and one or more periods of relatively consistent motion. Such periods may be associated with high noise and low noise, respectively. For example, inconsistent motion may be associated with a first level of signal to noise and consistent motion may be associated with a second level of signal to noise where the second level is higher than the first level. Such noise may be a result of sensor surface construction, sampling, and/or one or more other factors.

In the example of FIG. 13, a pre-connection state is shown during the drilling phase where the pre-connection state spans a time between a minimum BPOS value and a maximum BPOS value, which may be understood, for example, with respect to one or more of the BPOS tracks of the graphics of FIG. 8, FIG. 9 or FIG. 10. For example, consider the graphic of FIG. 8 where pre-connection states are identified in black by the decision block 817 of the method 800. The pre-connection states are identified in the activity track of the graphic of FIG. 8 as being temporally prior to corresponding connection states. As indicated, a post-connection state can follow and, thereafter, a drilling state (e.g., noting that a non-drilling state may occur). After some amount of drilling, another pre-connection state may occur. As indicated in the method 800 of FIG. 8, the decision block 843 can be utilized to classify RIH and/or POOH. In the graphic of FIG. 8, the BPOS can be seen to vary. As indicated in FIG. 13, it can vary from a minimum value to a maximum value with respect to time. As explained, a window may be utilized for data points, which may act to filter data points in time series data. In the example of FIG. 13, the window is a 60 percent window of a total time between a start time of the pre-connection state and an end time of the pre-connection state where data points in the first 20 percent and data points in the last 20 percent time periods are not utilized. Such data points may be of higher noise when compared to the data points of the 60 percent window. While the approach illustrated in FIG. 13 operates on a number of data points that is less than the total number of data points available for the pre-connection state, the data points selected (e.g., by filtering, etc.), provide for improved computations.

As explained, a method can be utilized to compute one or more downhole values where, for example, one or more corresponding sensors may not be available for measuring such downhole values.

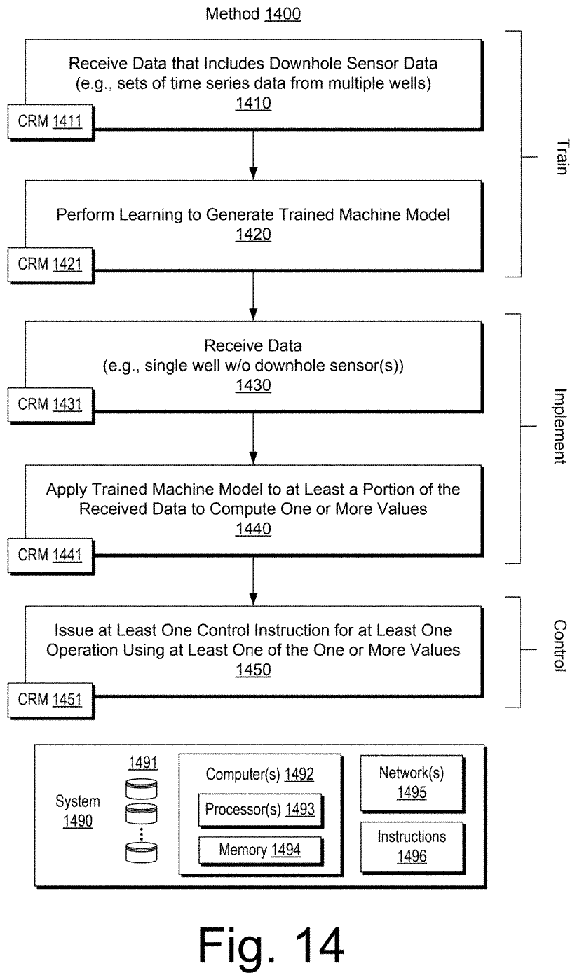

FIG. 14 shows an example of a method 1400 that includes a reception block 1410 for receiving time series data that includes downhole sensor data where the time series data may be from a number of wells (e.g., consider ten or more wells); a performance block 1420 for performing learning to generate a trained machine model; a reception block 1430 for receiving time series data of operations for a single well, which may or may not include one or more downhole sensors; an application block 1440 for applying the trained machine model to at least a portion of the received data of the reception block 1430 to compute one or more values; and an issuance block 1450 for issuing at least one control instruction for at least one operation using at least one of the one or more values. FIG. 14 also shows an example of a system 1490 that may be utilized to implement one or more portions of the method 1400.

As shown, the method 1400 can include various portions such as a train portion, an implement portion and a control portion. As to training, consider accessing time series data for tens of wells (e.g., 50 wells, 100 wells, etc.) where the time series data include data from downhole sensors. For example, for purposes of training, various data sets may be accessed for wells that were drilled using drillstrings with one or more downhole sensors. In such an example, training can train a machine model to reproduce downhole sensor based values using input values (e.g., via matching input-based output to actual downhole sensor based values). Such training can be referred to as machine learning that can generate a trained machine model. As an example, such machine learning may provide for output of one or more parameter values that may be suitable for utilization in one or more filter models, which may be considered machine models.

As explained, such a trained machine model can be utilized in a method that can compute downhole values that are not based on downhole sensor measurements. As an example, a trained machine model can include adaptive features. For example, a trained machine model can be adaptable using time series data, which can include real-time data. A machine model can be utilized to determine one or more parameter values that may, for example, be part of a filtering model that performs one or more filtering tasks as to time series data where the filtering model can include one or more threshold values. As an example, one or more of the methods described with respect to the GUI 1200 of FIG. 12 may be implemented using a monolithic machine model or a number of machine models that provide for threshold identification, filtering of data, etc. Such a model or models may be operatively coupled to one or more databases and/or real-time data sources.

As an example, a trained machine model can operate as one or more filters that can be applied to time series data, for example, on a drill stand by drill stand basis. As an example, a method can include a decision tree structure that involves applying one or more filters to determine points that can be utilized as being representative of a particular aspect of an operation or operations with respect to a drill stand.

As an example, a filter may be a “smart” filter as derived through training. For example, a trained machine model can be a filter model that is adaptable using input. As an example, a method may be implemented in a suitable programming language such as the PYTHON language as instructions stored in a storage device operatively coupled to a processor where such instructions are executable by the processor.

As an example, as to implementation, during operations, time series data can be acquired for a segment of a drillstring (e.g., a stand, etc.) where a particular portion of that time series data (e.g., selected samples) can be utilized as input to determine (e.g., identify) one or more thresholds for a subsequent segment of the drillstring, for example, to compute pickup (PU) and slackoff (SO) points.

As mentioned, inputs can include (i) drill state (e.g., per a method such as the method 800 of FIG. 8), (ii) BPOS, (iii) RPM, (iv) HKLD, and (v) STOR and outputs can include (i) HKLD_SO (block is going down), (ii) HKLD_PU (block is going up), (iii) HKLD_FR (free rotate), (iv) DWOB (a downhole value), (v) TQLS, and (vi) DTOR, which is downhole (e.g., DTOR=STOR−TQLS). In this example, the number of inputs can be selected in a manner that is limited, which can help to limit the amount and/or types of noise that may be present and/or otherwise impact output. As mentioned, torque values can be utilized in one or more friction calculations. Friction can be wellbore friction that occurs during rotation of a drillstring in a wellbore. As an example, a friction factor may be calculated with respect to a drillstring and a wellbore. As an example, inputs may include SPPA and/or FLWI, which may be alternative and/or additionally to one or more other inputs.

As to BPOS, it may be within a range that can be specified in meters (e.g., 0 meters to 40 meters) or feet. Depending on equipment at a site, sample rate for BPOS may differ. As an example, sample rate as to BPOS with respect to time may be 1 second, 3 second, 5 second, 10 second, etc. As an example, a robust system may be configured to handle a variety of different sample rates, which may be specific to types of equipment, entities performing drilling, etc. Such time series data can include noise. As an example, to handle noise, a method can utilize raw time series data for BPOS and select data points (e.g., samples) therein for purposes of computations. Such a method can involve filtering to select such data points. While BPOS is mentioned, such an approach can be applied to HKLD and STOR, which may include noise, outliers, etc., that are not seen in BPOS. For example, HKLD and/or STOR may include spikes (e.g. short transients with relatively extreme values). As an example, a method may be utilized in a scenario where one or more downhole sensors are included. For example, depending on transmission of downhole sensor data to a surface location, an estimate may be available prior to receipt of an actual downhole sensor value. As an example, in some scenarios, downhole sensor data may be stored in equipment such that the data is accessible after tripping out the equipment. In such an example, a comparison may be made between the actual data and the estimated values.

As explained, a machine model can be a filter (or filters) that can operate on input, which can be time series data associated with a segment of a drillstring (e.g., a stand, etc.). Such an approach can be utilized to determine one or more threshold values that can be utilized for a subsequent stand.

As an example, a method can automatically detect torque losses during drilling, weights for pickup (PU), slackoff (SO) and free rotate (FR) operations and/or one or more pressures. Such a method can operate on inputs that may be limited to drill state, block position, rotary speed, hook load, and surface torque and/or may optionally include standpipe pressure and/or flow rate.

As explained, a method can include implementing machine learning to identify proper filters for hook load and surface torque by looking at previous connection and previous drilling intervals (e.g., phases). Such an approach can reduce manual user intervention. For example, such an approach can automatically extract thresholds from time series data.

As an example, a method can operate in a manner that improves upon an approach that utilizes a hook load threshold that determines whether a drillstring is in-slips or not. For example, a method may operate in a manner that is more robust to noise in time series data such as noise in HKLD.

As an example, a method can utilize a trained machine model, can utilize a limited number of inputs, and can utilize a statistical approach and/or a probabilistic approach to data points (e.g., samples). Such a method can be robust to noise and applicable to a variety of types of equipment, which can provide the basic types of surface sensors.

As indicated in the method 1400 of FIG. 14, a training phase can occur to generate a trained machine model. For example, consider using time series data for 50 wells data to train with data from real downhole sensors. As indicated, an implementation phase can utilize a trained machine model. As an example, a method can include looking at previous drilling stand and sampling for thresholds for a next drilling stand. As an example, a method may be implemented locally and/or remotely. As an example, a computational framework such as, for example, the TECHLOG framework, may include features for implementation of one or more portions of a method such as the method 1400 of FIG. 14. As an example, a method can be part of a workflow (or workflows), which may be a torque and drag workflow, a tripping load workflow, a stuck pipe workflow, a mud-motor workflow, etc.

FIG. 14 also shows various computer-readable media (CRM) blocks 1411, 1421, 1431, 1441, and 1451. Such blocks can include instructions that are executable by one or more processors, which can be one or more processors of a computational framework, a system, a computer, etc. A computer-readable medium can be a computer-readable storage medium that is not a signal, not a carrier wave and that is non-transitory. For example, a computer-readable medium can be a physical memory component that can store information in a digital format.

In the example of FIG. 14, a system 1490 includes one or more information storage devices 1491, one or more computers 1492, one or more networks 1495 and instructions 1496. As to the one or more computers 1492, each computer may include one or more processors (e.g., or processing cores) 1493 and memory 1494 for storing the instructions 1496, for example, executable by at least one of the one or more processors. As an example, a computer may include one or more network interfaces (e.g., wired or wireless), one or more graphics cards, a display interface (e.g., wired or wireless), etc. The system 1490 can be specially configured to perform one or more portions of the method 1400 of FIG. 14.

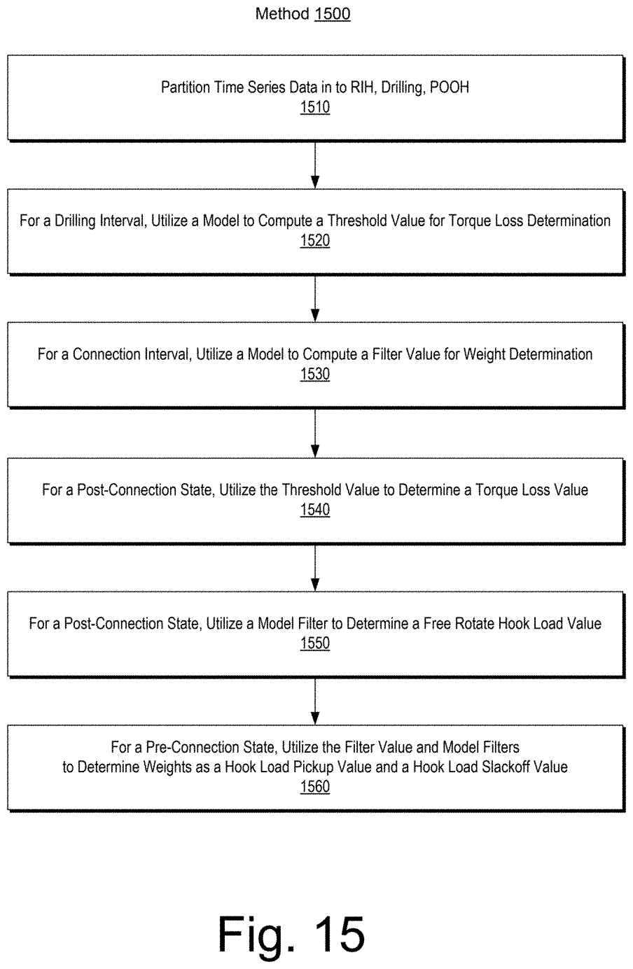

FIG. 15 shows an example of a method 1500 that includes a partition block 1510 for partitioning time series data into RIH, Drilling and POOH partitions; a computation block 1520 for computing a threshold value for torque loss determination using a model where data of a drilling interval are utilized; a computation block 1530 for computing a filter value for weight determination using a model where data of a connection interval are utilized; a determination block 1540 for determining a torque loss value using the threshold value and data of a post-connection state; a determination block 1550 for determining a free rotate hook load value (e.g., a weight) utilizing a model filter and data of the post-connection state; and a determination block 1560 for determining weights using the filter value and model filters and data of a pre-connection state where the weights include one or more of a hook load pickup value and a hook load slackoff value. In the example of FIG. 15, the method 1500 includes an adaptive learning phase and a detection phase where detection provides for determinations as to values, which can include a torque loss value that can be utilized for determining a downhole torque value. A downhole torque value can be utilized, for example, in one or more workflows, which may include a control workflow that aims to reduce incidents of stuck pipe, etc. As an example, the method 1500 may include one or more blocks as to pressure such as off-bottom pressure and/or differential pressure.

As an example, a trained machine model can be based on time series data that includes downhole sensor data. Such a trained model can be adaptable in its implementation in that various parameter values can be determined as appropriate, which can be parameters values for filters, which may be threshold values and/or filter values. Given such parameter values, a method can utilize the trained model, as adapted, for detecting data points that can be statistically processed to determine values such as, for example, torque values, weight values and/or pressure values.

The method 1500 can be implemented using a statistical approach for weights, torques and/or pressure detection based on stand experience. As indicated, a method can split stand types into partitions (e.g., RIH, Drilling, and POOH). As mentioned, during drilling intervals of a drilling stand, a method can compute a statistical value such as a median high value of surface torque (DrStorMed), which can be used as threshold for torque loss detection. As mentioned, during a connection interval of a drilling stand, a method can compute a minimum hook load value, which may be used as a filter value to compute one or more weights. Such actions can be part of an adaptation process where a model is utilized to “learn” parameter values of the model for purposes of detection. For example, consider learning parameter values of DrStorMed and/or ConHkldMin (e.g., connection hook load minimum) and/or ConHkldMed (e.g., connection hook load median) and/or DrHkldMed (e.g., drilling hook load median) and then utilizing one or more for parameter values for detection. Other values may include DrSppaMed and/or DrFlwiMed, etc. As an example, to compute TQLS, a method can collect valid STOR data points during a post-connection state (e.g., those STOR<DrStorMed). In such an approach, a final TQLS value can be taken as low median of points. As to determination of HKLD_FR, a method can collect data points during a post-connection state with valid HKLD and RPM. In such an approach, points can be filtered using a model filter (e.g., RPM<0.7×max(RPM), where “0.7” may be an appropriate parameter value). A final HKLD_FR result value can be taken statistically as low median of points. As to determinations of HKLD_PU and HKLD_SO values during a drilling phase, a method can collect points from a pre-connection state and categorize these as two sets, one of pickup and the other of slackoff. For both, as an example, a method can first apply HKLD<ConHkldMin filter (e.g., using the filter value of the adaptive portion). Then collections can be filtered by a model filter (e.g., RPM>1 c/min condition, where “1” may be an appropriate parameter value). Then for the pickup set, the method can take data points where BPOS increases, filtered by a model filter (e.g., 1.2×min(BPOS)<BPOS<0.8×max(BPOS), where “1.2” and “0.8” may be appropriate parameter values), and a final HKLD_PU can be determined statistically, for example, taken as a high median of the set. Similarly, for the slackoff set, the method can take data points where BPOS decreases, filtered by a model filter (e.g., 1.2×min(BPOS)<BPOS<0.8×max(BPOS)), and final HKLD_SO can be determined statistically, for example, taken as a low median of the set.

As to the RIH and POOH phases, as an example, pre-connection and post-connection states may not be defined because no drilling occurs. In such instances, HKLD_SO during RIH can be determined statistically as min(HKLD) when max(BPOS)−2 m<BPOS<max(BPOS), where “2 m” may be an appropriate parameter value, noting again that a percentage or percentages may be utilized. And, HKLD_PU during POOH can be determined statistically as max(HKLD) when min(BPOS)<BPOS<min(BPOS)+2 m, where “2 m” may be an appropriate parameter value; noting again, one or more parameter values and/or types of parameters may be utilized (e.g., distance, percentage, etc.).

As explained with respect to FIG. 11, a method can include, for example, after one or more of various thresholds (e.g., one or more of DrStorMed, DrHkldMed, ConHkldMed, DrSppaMed, DrFlwiMed, etc.) have been identified, continuing with one or more detection processes.

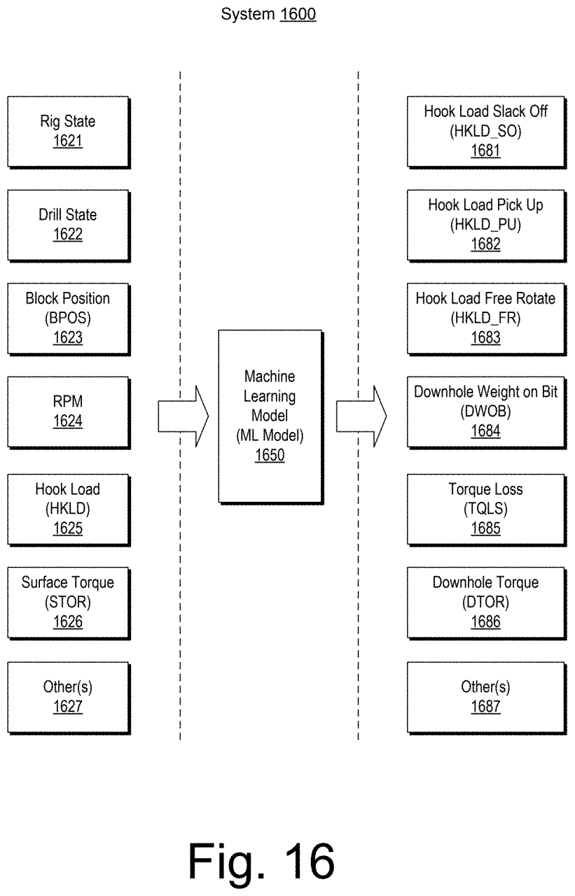

FIG. 16 shows an example of a system 1600 that includes various example inputs 1621 to 1627 for a machine learning model (ML model) 1650 and various example outputs 1681 to 1687 that can be generated using the ML model 1650 as a trained ML model. As shown, the inputs can include rig state 1621, drill state 1622, block position (BPOS) 1623, RPM 1624, hook load (HKLD) 1625, surface torque (STOR) 1626 and one or more other inputs 1627 (e.g., consider one or more pressures (SPPA, etc.), flow rates (FLWI, etc.), etc. As shown, the outputs can include hook load slack off (HKLD_SO) 1681, hook load pick up (HKLD_PU) 1682, hook load free rotate (HKLD_FR) 1683, downhole weight on bit (DWOB) 1684, torque loss (TQLS) 1685, downhole torque (DTOR) and one or more other outputs 1687 (e.g., consider one or more pressures (OFBP, DPRES, etc.)).

As an example, the system 1600 may be utilized in a method such as, for example, the method 1400 of FIG. 14, which can include various portions such as train, implement and control. As an example, the system 1600 may utilize one or more features of the system 1490, which may be local, distributed, remote, local and remote, etc. As an example, the system 1600 may be utilized with one or more of the aspects explained with respect to the GUIs 1100, 1200 and 1300 of FIGS. 11, 12 and 13. As an example, a system such as the system 1600 may be utilized to determine, directly and/or indirectly, one or more values that can be utilized in one or more methods.

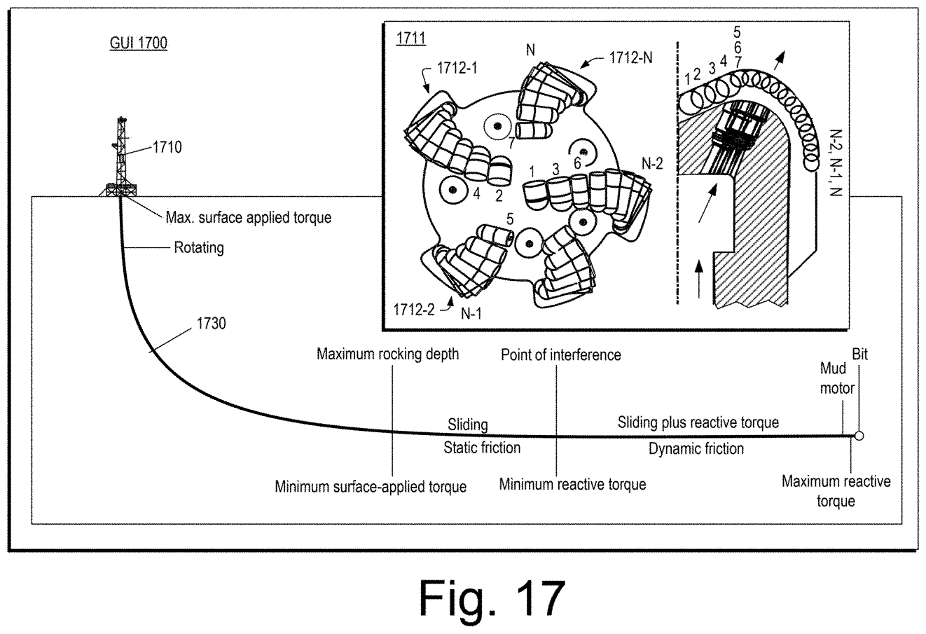

FIG. 17 shows an example of a graphical user interface 1700 that includes a graphic of a system 1710, graphics of an example of a drill bit (or bit) 1711, and a graphic of a trajectory 1730 where the system 1710 can perform directional drilling to drill a borehole according to the trajectory 1730. As shown, the trajectory 1730 includes a substantially vertical section, a dogleg and a substantially lateral section (e.g., a substantially horizontal section). The system 1710 can be operated in various operational modes, which can include, for example, rotary drilling and sliding. In the example of FIG. 17, arrows illustrate flow of drilling fluid (e.g., mud) through openings of the drill bit 1711 (e.g., for lubrication, for carrying cuttings to surface, etc.).

In the example of FIG. 17, longitudinal drag along the drillstring can be reduced from the surface down to a maximum rocking depth, at which friction and imposed torque are in balance. As an example, a drilling operation can include manipulating surface torque oscillations such that the maximum rock depth may be moved deep enough to produce a substantial reduction in drag. As an example, reactive torque from a bit can create vibrations that propagate back uphole, breaking friction and longitudinal drag across a bottom section of a drillstring up to a point of interference, where the torque is balanced by static friction. As shown in the example of FIG. 17, an intermediate zone may remain relatively unaffected by surface rocking torque or by reactive torque. In the example of FIG. 17, a drilling operation can include monitoring torque, WOB and ROP while sliding. As an example, such a drilling operation may aim to minimize length of the intermediate zone and thus reduces longitudinal drag.

A drilling operation in the sliding mode that involves manual adjustments to change and/or maintain a toolface orientation can be challenging. As an example, a drilling operation in the sliding mode can depend on an ability to transfer weight to a bit without stalling a mud motor and an ability to reduce longitudinal drag sufficiently to achieve and maintain a desired toolface angle. As an example, a drilling operation in the sliding mode can aim to achieve an acceptable ROP while taking into account one or more of various other factors (e.g., equipment capabilities, equipment condition, tripping, etc.).

In a drilling operation, as an example, amount of surface torque (e.g., STOR) supplied by a top drive can largely dictate how far downhole rocking motion can be transmitted. As an example, a relationship between torque and rocking depth can be modeled using a torque and drag framework (e.g., T&D framework). As an example, a system may include one or more T&D features.

As an example, a system may utilize inputs from surface hook load and standpipe pressure as well as downhole MWD toolface angle. In such an example, the system may automatically determine the amount of surface torque that is appropriate to transfer weight downhole to a bit, which may allow an operation to not come off-bottom to make a toolface adjustment, which can results in a more efficient drilling operation and reduced wear on downhole equipment. Such a system may be referred to as an automation assisted system.

As to the example bit 1711, it can include various cutting structures (e.g., cutters) that can be numbered from 1 to N and represented in a cross-sectional view, which is a view where cutter density and associated spatial information is illustrated by rotating the placement of the cutting structures onto a single radial plane. The bit 1711 may be, for example, a polycrystalline diamond compact (PDC) bit, which may be a fixed-head bit that rotates as one piece and that does not include separately moving parts.

As shown in FIG. 17, a bit can include blades 1712-1, 1712-2, . . . 1712-N, which may, for example, include primary blades and secondary blades. As an example, blades can part of a bit body and hence integral thereto. As shown, a blade can include a blade top for mounting a plurality of cutting structures (e.g., as numbered from 1 to N). As an example, a cutting structure can include a cutting face where the cutting structure is mounted in a pocket formed in a blade top. Cutting structures can be arranged adjacent one another in a radially extending row proximal the leading edge of a blade. As an example, a cutting face can have an outermost cutting tip that can be furthest from the blade top to which the cutting structure is mounted. As shown in FIG. 17, a bit body can include various passages that can allow for drilling fluid to flow between and both clean and cool the blades 1712-1, 1712-2, . . . , 1712-N during drilling. As an example, a bit can be defined by a bit centerline and a bit face where blades extend radially along the bit face. As shown in FIG. 17, each of the blades 1712-1, 1712-2, . . . , 1712-N can extend a distance outwardly such that channels are defined between adjacent blades. Each blade includes a blade top, which may be defined by a blade height parameter. As mentioned, cutting structures can be mounted to blades where drilling is to utilize the cutting structures to “cut” rock. As an example, a cutting structure can extend outwardly beyond a blade top to which it is mounted. Cutting structures (e.g., cutting elements) can be, for example, PDC cutting structures such that a bit can be referred to as a PDC bit. Forming PDC into useful shapes for cutting structures can involve placing diamond grit, together with its substrate, in a pressure vessel and then sintering at high heat and pressure. As an example, a bit body may be considered to be a carrier for cutting structures.

As an example, a bit may be a matrix body bit (MBB) or a steel body bit (SBB). A matrix can be hard yet somewhat brittle composite material that can include tungsten carbide grains metallurgically bonded with a softer, tougher, metallic binder. A matrix can be desirable as a bit material as its hardness can provide resistance to abrasion and erosion. A matrix bit may be capable of withstanding relatively high compressive loads, but, compared with steel, may have a relatively low resistance to impact loading.

As a matrix can be relatively heterogeneous, because it is a composite material, and, because of the size and placement of particles of tungsten carbide, a matrix can vary (e.g., by both design and circumstances) such that its physical properties may be less predictable than steel.

Matrix body bits can be manufactured by a mold process. For example, tungsten carbide and binder materials can be arranged into a mold that is then placed in a furnace for a certain period of the time. The mold can then be cooled down and released to remove the unfinished matrix bit.

As to a steel body, it can be capable of withstanding high impact loads, but can be relatively soft and, without protective features, would tend to fail quickly by abrasion and erosion. Quality steels tend to be homogeneous with structural limits that tend to be predictable. A steel body may be manufactured by machining steel bars per design.

Design characteristics and manufacturing processes for different bit types are, in respect to body construction, different, because of the nature of the materials from which they are made. The lower impact toughness of matrix limits some matrix-bit features, such as blade height. Conversely, steel is ductile, tough, and capable of withstanding greater impact loads. This makes it possible for steel body PDC bits to be relatively larger than matrix bits and to incorporate greater height into features such as blades.

Matrix body PDC bits tend to be suitable for environments in which body erosion is likely to cause a bit to fail. For diamond-impregnated bits, matrix-body construction can be used. The strength and ductility of steel give steel bit bodies high resistance to impact loading. Steel bodies tend to be stronger than matrix bodies. Because of steel material capabilities, complex bit profiles and hydraulic designs can be possible to construct on a multi-axis, computer-numerically-controlled milling machine. A steel bit may be amenable to being rebuilt a number of times where worn or damaged cutters can be replaced, which can be beneficial for operators in low-cost drilling environments.

Cutting structures or cutters of a bit may be expected to endure throughout the life of a bit. To perform suitably, cutters can receive both structural support and efficient orientation from bit body features. Cutter orientation can be such that cutters are loaded by to a large extent (e.g., primarily) by compressive forces during operation. To prevent loss (e.g., detachment from a body), cutters can be retained, for example, by braze material that has adequate structural capabilities and has been properly deposited during manufacturing.

Cutters can be appropriately placed on a bit face (e.g., mounted on blades) in an effort to ensure a desired amount of bottom hole coverage (e.g., complete bottom hole coverage). The term “cutter density” refers in part to the number of cutters used in a particular bit design. For example, PDC bit cutter density can be a function of profile shape and length and of cutter size, type, and quantity. If there is a redundancy of cutters, the redundancy can generally increase from the center of the bit to the outer radii because of increasing demands for work as radial distance from the bit centerline increases. Cutters nearer to the gauge travel farther and faster and remove more rock than cutters near the centerline. As shown in FIG. 17, cutter density can be illustrated by rotating each cutter's placement onto a single radial plane. Such an illustration may be referred to as a planar representation of cutter density, which is shown to increase with radial position.

Reducing the number of cutters on a bit face tends to yield the following results: depth of cut (DOC) increases; ROP increases; torque increases; and bit life is shortened; whereas, increasing cutter density tends to yield: a decrease in ROP; a decrease in cutting structure cleaning efficiency; and an increase in bit life.

In the example of FIG. 17, cutter density may be increased in the outward radial direction from the bit centerline for the bit depicted where a planar cutter strike pattern inscribes an image of a bit profile.

As mentioned, a system may provide information pertaining to mechanical specific energy (MSE), which can be or can include downhole mechanical specific energy (DMSE).

MSE can be a measure of drilling efficiency. For example, MSE can represent energy to remove a unit volume of rock. As an example, for optimum drilling efficiency, a system may aim to minimize MSE and to maximize ROP. To control MSE, various techniques may be utilized, which can include adjusting one or more control parameters, etc. For example, a driller and/or a system may control WOB, torque, ROP and drill bit RPM in an effort to control MSE.

Rock working can involve breakage of fragments out of a face of a solid wall of rock. Rock working can involve forcing a tool into a rock surface, which may be characterized by a surface hardness. As a rock working process breaks rather than cuts solid rock into small fragments of assorted sizes, it may be regarded as a crushing process. As an example, a crushing process can be characterized using one or more energy/volume relationships. As an example, specific energy may be defined as the energy to excavate a unit volume of rock, which may be taken as an index of the mechanical efficiency of a rock working process. In various drilling processes, a minimum value may roughly correlate with the crushing strength of the medium drilled in, for rotary, percussive-rotary and roller-bit drilling.

As an example, equations for MSE may be as follows:

$$M S E = \frac{Total Energy Input}{Volume Removed} \\ MSE = \frac{Vertical Energy Input}{Volume Removed} + \frac{Rotational Energy Input}{Volume Removed} \\ MSE = \frac{WOB}{A} + \frac{2 π * R P M * TOR}{A * ROP}$$

where A is the cross section area of drilling and where MSE may have units of psi, ft-lb*ft³, etc.

As an example, a bit efficiency value may be determined using a minimum MSE divided by an obtained MSE. As an example, MSE and ROP can be inversely related for a given rig power. In various drilling operations, rock broken into pieces smaller than sufficient for evacuation can result in more energy expenditure while rock broken into pieces too large for evacuation can demand expenditure of energy in further braking (e.g., into smaller pieces).

As an example, drilling, depending on parameters, may be characterized according to depth of cut (DOC) where, for example, a small depth of cut may be associated with grinding and high friction forces that can result in a high MSE and a low ROP and, for example, where an increased DOC may transition from scraping and grinding to fracture and breakage of rock. For example, a higher DOC can cause chipping and breakage of material in larger pieces with less reduction to smaller pieces via regrinding, which can result in a lower MSE due to more efficient volume removal.

While MSE may be a parameter utilized in control, as indicated, the foregoing example MSE equation includes WOB and RPM. As an example, a control process may utilize one or more of WOB and RPM, optionally in addition to one or more other parameters. As an example, a control process may include monitoring MSE, which may be utilized for one or more purposes (e.g., control, diagnosis, etc.).

As an example, a well may be an extended reach well (ERW) that is to be drilled via extended-reach drilling (ERD). For example, an ERW may be drilled using directional drilling for a drilled horizontal reach (HR) attained at total depth (TD) exceeding a true vertical depth (TVD) by a factor greater than or equal to two. ERD can be challenging for directional drilling and demand specialized planning to execute well construction.

ERD may be defined, for example, to include deep wells with horizontal distance-to-depth, or H:V, ratios less than two. As an example, an ERD database can classify wells, with increasing degree of well construction complexity, into low-, medium-, extended- and very extended-reach wells. Construction complexity can depend on various factors, for example, including water depth (for offshore wells), rig capability, geologic constraints and overall TVD. For example, a vertical well with TVD greater than 7,620 m (25,000 ft) may be considered to be an extended-reach well. Also, depending on conditions, drilling a well in deep water or through salt may be classified as ERD even if the well's horizontal extent is not more than twice its TVD. As an example, ERD may be utilized to drill from a position that may be more advantageous than another position that may be vertically above a target. For example, consider drilling from an onshore site to reach a target that is vertically below a body of water. Drilling from the onshore site may be more desirable in various instances than drilling from an offshore site (e.g., a platform, etc.).

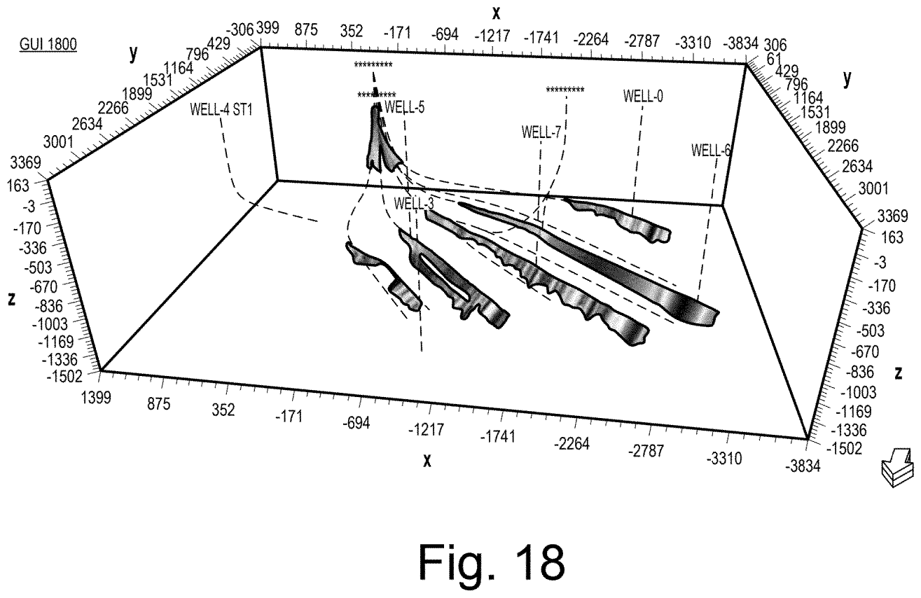

FIG. 18 shows an example GUI 1800 that includes graphical representations for a geologic environment that includes 7 exploration wells and 6 development wells completed by 9 sidetracks. As an example, a system such as the system 1600 may be utilized for one or more types of operations in such an environment. For example, consider using the system 1600 for drilling one or more sections of a well or wells. In such an example, various conditions may exist, occur, etc., for example, consider a 12.25 inch section (e.g., approximately 31.8 cm), where conditions for a pack-off event are observed.

As an example, with respect to sections, consider a 17.5 inch section (e.g., approximately 44.5 cm) that is to achieve an inclination of 50 degrees for a number of wells, while a 12.25 inch section (e.g., approximately 31.8 cm) is to be landed to 90 degrees for a number of the wells. As an example, an 8.5 inch section (e.g., approximately 21.6 cm) may be drilled substantially horizontally (e.g., a lateral section, etc.). As an example, a system may assist with drilling of one or more sections that are subject to one or more hole cleaning concerns. For example, consider identification of sensitive inclinations for hole-cleaning, which may be between approximately 30 degrees and approximately 70 degrees.

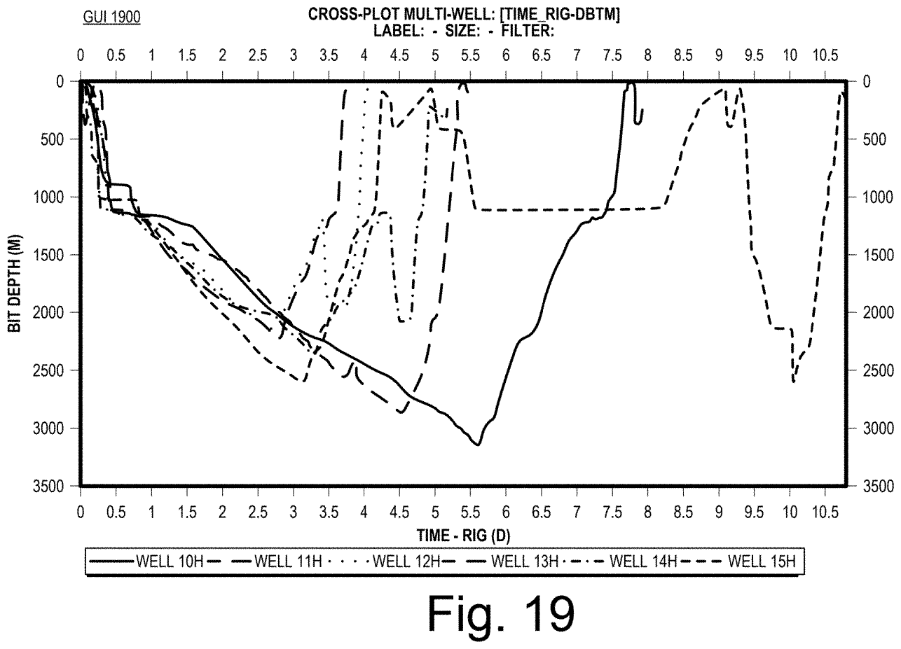

FIG. 19 shows an example GUI 1900 of bit depth as measured depth versus time in days for drilling of six wells. The GUI 1900 provides data for understanding of the performance for each well, specifically, the daily progress of the 12.25 inch section for the wells. As can be seen in the GUI 1900, the best performance was achieved during drilling well 15H, which reached to 2,600 m, while wells 11H and 14H faced intervals of lower performance. During well 14H, at around 2,000 m, it took nearly 12 h to drill two stands (each point represents roughly one stand). Regarding the performance of the well 11H, the ROP was lower between 1,400 m and 1,600 m but did not drop abruptly as it did in well 14H.

As explained, MSE can be a parameter that can be utilized to characterize drilling such as drilling efficiency. In particular, MSE can be a good indicator of drilling efficiency. While various equations are presented above for MSE, consider the following equation for MSE as another example:

MSE=Input Power/Output ROP

The MSE concept tends to be more appropriate in a vertical section when computed with surface data and tends to be less reliable with surface data in a highly deviated well, where it is recommended to use downhole parameters to discard losses of energy against the wellbore. As such, a system such as the system 1600 can be utilized for various outputs as shown in FIG. 16, which can be outputs for various downhole parameters. As an example, a method can include estimating various downhole parameters where a downhole MSE (DMSE) may be computed. For example, consider the following example equation for DMSE:

DMSE=480TOR×TRPM/(ROP×D²)+4DWOB/(πD²)

where:

DMSE: Downhole mechanical specific energy in MPa

TRPM: Total rotation per minute in c/min

ROP: Rate of penetration in m/h

DWOB: Downhole weight on bit in kN

DTOR: Downhole torque in kN.m

D: Bit diameter in m

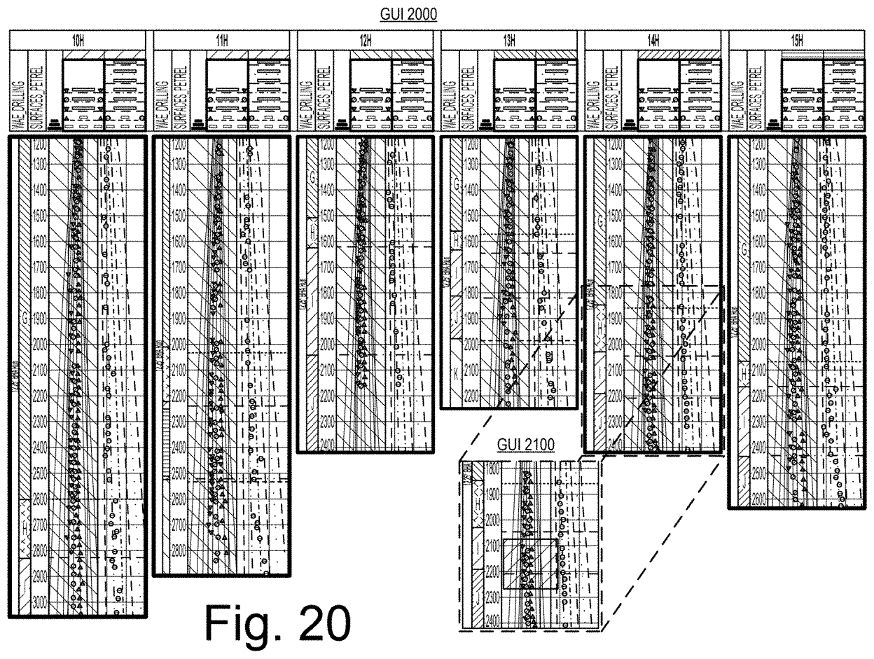

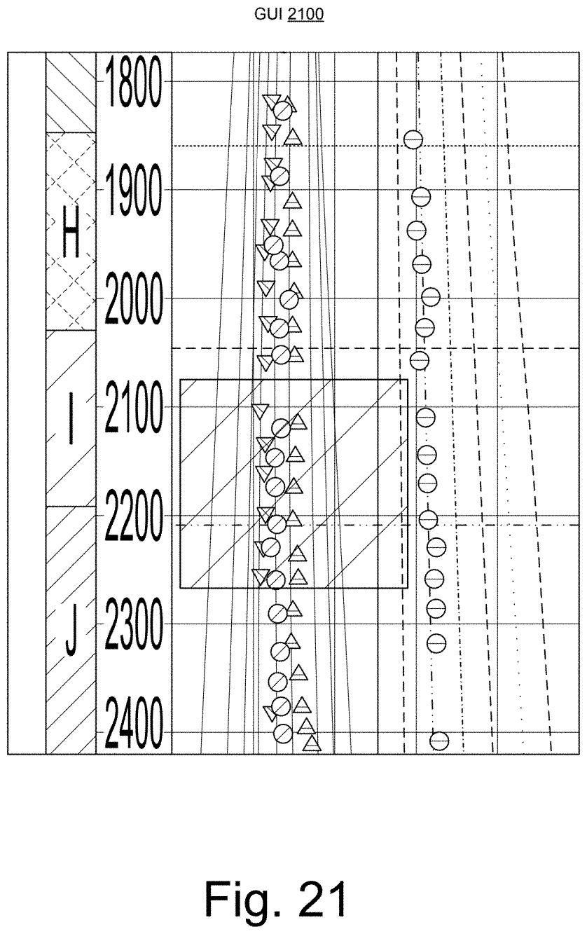

FIG. 20 and FIG. 21 show an example GUI 2000 for various outputs for the six wells where comparisons may be made for the pickup and slackoff weights taken during connections using a broomstick model along with an enlarged portion GUI 2100. As an example, a system may generate a GUI that includes multi-well broomsticks with pickup and slackoff points taken automatically. As an example, a system such as the system 1600 of FIG. 16 may be utilized to generate outputs for one or more wells, for one or more sections of one or more wells, etc.

In the example GUI 2000, for well 14H, it appears that there is a slight increase in friction factor during the depths when cavings were observed and a further increase just before pulling out of hole (POOH). During a trip out, an overpull of 30 kkgf was recorded, leading to a wiper trip in to better clean the hole and avoid stuck pipe. As explained, stuck pipe can cause various issues, expenditures of resources, delays (e.g., non-productive time (NPT)), etc. As indicated, it took approximately 200 h to complete the 12.25 inch section with a wiper trip representing approximately 8 percent (e.g., 16 h) of the time spent on this phase.

A provisional patent application to Gutarov et al., Adaptive Torque Loss Determination, U.S. Provisional Patent Application Ser. No. 63/093,022, filed 16 Oct. 2020, and an associated U.S. Patent Publication US 2022/0120176 A1 are incorporated by reference herein.

The example GUI 2000 can render broomstick model plots with respect to depth (e.g., measured depth, etc.). Where a borehole is vertical, plotting with respect to depth can provide for some insight as the direction of the acceleration of gravity is vertical. Thus, an operator may understand how gravity impacts friction with respect to a drillstring, a BHA, a bit, drilling fluid (e.g., mud), etc. Further, pickup (PU) and slackoff (SO) are with respect to gravity downhole, not just at surface. However, where a borehole is deviated, it may be more difficult to relate a broomstick model plot with respect to depth to gravity related phenomena and/or other phenomena.

As an example, GUI can render one or more broomstick model plots with respect to time (e.g., horizontally, vertically, etc.). In such an example, a broomstick model plot can be utilized to ascertain one or more friction factors with respect to time. As an example, a GUI or GUIs can include one or more broomstick model plots with respect to time and a data quality control plot, which may provide for assessment of factors (e.g., weights, etc.), optionally with respect to time. As an example, a broomstick plot or broomstick model plot (e.g., a plot of model results, etc.), may be a full broomstick plot, a half broomstick plot or another portion of a broomstick plot. For example, where PU and SO are concerned, they can correspond to different directions such that a full broomstick plot may be generated; noting that a half broomstick plot for PU and/or a half broomstick plot for SO may be generated. As to TQLS, where the torque is in a particular rotational direction (e.g., a rotational direction of a bit for drilling), a broomstick plot may be a half broomstick plot; noting that torque may be acquired in two rotational directions (e.g., clockwise and counterclockwise), which may provide for rendering a plot in a full broomstick manner.

A broomstick model plot with respect to time may provide an operator with an ability to understand better dynamics when compared to broomstick model plot with respect to depth.

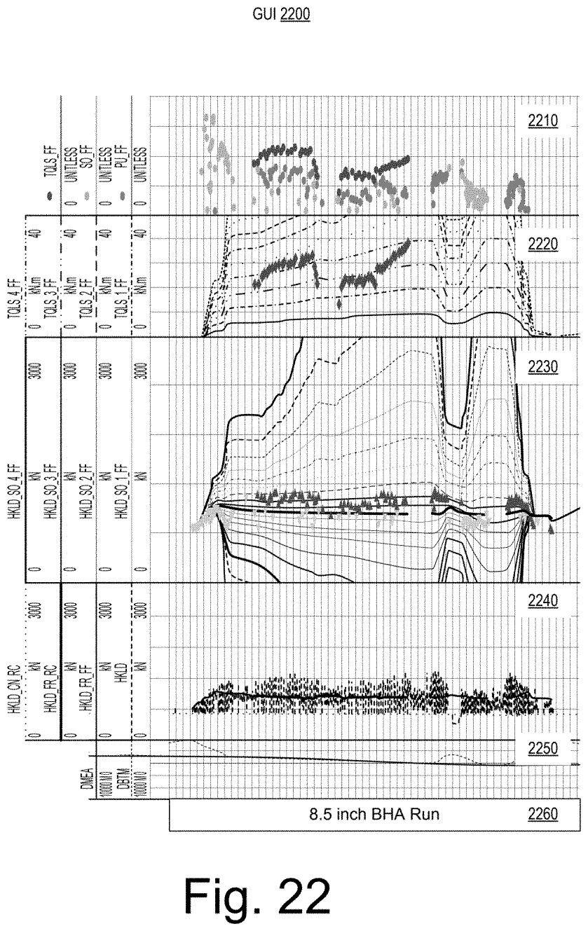

FIG. 22 shows an example GUI 2200 with various tracks 2210, 2220, 2230, 2240, 2250 and 2260 with respect to time. In the example GUI 2200, the track 2210 shows friction factors that can be derived using one or more models and sensor data. In particular, the track 2210 shows a torque loss (TQLS) friction factor (FF), a slackoff (SO) friction factor (FF), and a pickup (PU) friction factor (FF), which may be color coded or otherwise coded. The track 2210 provides an operator and/or a controller with an ability to assess one or more trends as to one or more of the friction factors.

In the example of FIG. 22, the track 2260 indicates that the information in the GUI 2200 pertains to an 8.5 inch BHA run, which may be for a particular section of a multiple section borehole. The track 2260 can also include state indicators, for example, in one or more rows above the 8.5 inch BHA run row. In the example of FIG. 22, the 8.5 inch BHA run can be expected to take an amount of time to drill the 8.5 inch section. In such an example, the amount of time can depend on the rate of penetration (ROP), which can vary, for example, depending on one or more factors. In various instances, friction can be a factor that impacts ROP.

In the example of FIG. 22, the points in the track 2210 can be derived with respect to information in the track 2220 and the track 2230. In the track 2220, broomstick lines (e.g., half a broomstick) are plotted for torque. In the track 2230, broomstick lines are plotted where some lines are above a baseline (e.g., see a zero friction model result) and where some lines are below the baseline. More specifically, the tracks 2220 and 2230 show lines for model-based friction factors within a range from 0 to 1, and specifically for friction factors of 0.1, 0.2, 0.3, 0.4, 0.5, 0.6, 0.7, 0.8 and 0.9. In the track 2230, the lines generally above the baseline are model values for movement of a drillstring in one direction in a borehole (e.g., pickup (PU), pulling out of hole (POOH)) and the lines generally below the baseline are model values for movement of the drillstring in an opposite direction in the borehole (slackoff (SO), running in hole (RIH)). When running in hole, the weight is decreased compared to pulling out of hole. The data points in the track 2230 are sensor-based hook load values (HKLD), where the position of a data point can be compared to one or more model values to determine a fraction factor, which, in turn, can be rendered in the track 2210. In the track 2230, the greater the absolute value of the friction factor, in general, the greater the deviation from the zero friction model result, which may be represented as a line.

As an example, values and/or ranges for friction factors for modeling can be spaced evenly, unevenly, etc. For example, consider more closely spaced values near an alarm such that accuracy may be increased when approaching an alarm (e.g., to provide for operating closer to an alarm limit, etc.).

Below, some examples of inputs and outputs are shown in the listing below where the inputs can be model inputs with appropriate values, ranges, etc., as to friction factors.

Example Inputs and Outputs

### Example Inputs:

1. Bit Depth, [m]

2. HKLD_SO, [N]—Hook load Slack Off, block is going down

3. HKLD_PU, [N]—Hook load Pick Up, block is going up

4. HKLD_CN, [N]—Hook load during Connection or Block weight

5. HKLD_FR, [N]—Hook load free rotate

6. TQLS [N.m]—Torque Loss

7. BHA—Bottom Hole Assembly elements

8. Fluid mud weight

9. Trajectory survey (MD, INCL, AZIM)

10. Well Activities or BHA runs

### Example Channel Group Outputs:

1. Friction factors
a. PU_FF, [0-100%]—Friction Factor during Pick Up
b. SO_FF, [0-100%]—Friction Factor during Slack Off
c. TQLS_FF, [0-100%]—Friction Factor during string rotation

2. HKLD_FR_FF, [N]—Hook Load Free Rotate model with friction 0

3. HKLD_QC_FF, [0-100%]=abs(HKLD_FR−HKLD_FR_FF)*2/(abs(HKLD_FR)+abs(HKLD_FR_FF)), indicates the match between the model and free rotate references

4. Modelled Pick up weights
a. HKLD_PU 1_FF, [N]—Hook Load Pick Up model with friction 0.1
b. HKLD_PU 2_FF, [N]—Hook Load Pick Up model with friction 0.2
c. HKLD_PU 3_FF, [N]—Hook Load Pick Up model with friction 0.3
d. HKLD_PU 4_FF, [N]—Hook Load Pick Up model with friction 0.4
e. HKLD_PU 5_FF, [N]—Hook Load Pick Up model with friction 0.5
f. HKLD_PU 6_FF, [N]—Hook Load Pick Up model with friction 0.6
g. HKLD_PU_7_FF, [N]—Hook Load Pick Up model with friction 0.7
h. HKLD_PU 8_FF, [N]—Hook Load Pick Up model with friction 0.8
i. HKLD_PU 9_FF, [N]—Hook Load Pick Up model with friction 0.9

5. Modelled Slack off weights
a. HKLD_SO_1_FF, [N]—Hook Load Slack Off model with friction 0.1
b. HKLD_SO_2_FF, [N]—Hook Load Slack Off model with friction 0.2
c. HKLD_SO_3_FF, [N]—Hook Load Slack Off model with friction 0.3
d. HKLD_SO_4_FF, [N]—Hook Load Slack Off model with friction 0.4
e. HKLD_SO_5_FF, [N]—Hook Load Slack Off model with friction 0.5
f. HKLD_SO_6_FF, [N]—Hook Load Slack Off model with friction 0.6
g. HKLD_SO_7_FF, [N]—Hook Load Slack Off model with friction 0.7
h. HKLD_SO_8_FF, [N]—Hook Load Slack Off model with friction 0.8
i. HKLD_SO_9_FF, [N]—Hook Load Slack Off model with friction 0.9

6. Modelled Torque loss values
a. TQLS_1_FF, [N.m]—Torque model with friction 0.1
b. TQLS_2_FF, [N.m]—Torque model with friction 0.2
c. TQLS_3_FF, [N.m]—Torque model with friction 0.3
d. TQLS_4_FF, [N.m]—Torque model with friction 0.4
e. TQLS_5_FF, [N.m]—Torque model with friction 0.5
f. TQLS_6_FF, [N.m]—Torque model with friction 0.6
g. TQLS_7_FF, [N.m]—Torque model with friction 0.7
h. TQLS_8_FF, [N.m]—Torque model with friction 0.8
i. TQLS_9_FF, [N.m]—Torque model with friction 0.9

As an example, a method can include determining hook load values using acquired data, optionally in real-time, and can include determining hook load values for various friction factors, optionally in real-time. In such an example, the determinations may be made using a common computational framework and/or using separate computational frameworks. As an example, sensor-based values may be provided independent of model-based values.

In the example GUI 2200, the tracks 2210, 2220 and 2230 can be utilized in combination for purposes of control, risk assessment, etc. In the track 2220 and/or the track 2230, an operator and/or a controller may assess sensor-based values as overlaid on model-based values for a variety of friction factors. Where an operator and/or a controller desires a friction factor value for a sensor-based value, an interpolation may be performed using the model-based values where the result may be plotted in track 2210.

An operator and/or a controller may aim to keep a friction factor within a particular range or outside of a particular limit (e.g., 0.1 and 0.5) where a value outside of the particular range and/or outside of a particular limit occurs, risk of an issue such as sticking may increase due to increased friction. For example, a range of values may define a safe zone for operations.

In the tracks 2220 and 2230, the different friction factor model-based values for hook load may be rendered in one or more manners. For example, while lines are shown, consider shading, zones, envelopes, etc. As an example, one or more rendering techniques may be utilized to help an operator visualize operational conditions, particularly with respect to friction. As to model-based values, a model can be a pickup (PO) model, a slackoff (SO) model, a torque loss (TQLS) model, etc. For example, the track 2230 shows PU model and SO model results while the track 2220 shows TQLS model results. The tracks 2220 and 2230 can be utilized in combination with acquired data to determine the friction factors in real-time that are shown in the track 2210. As an example, PU and SO may be broken out into separate tracks (e.g., as half broomstick plots).

As to model-based values, a model can take various inputs such as, for example, BHA specifications and mud-weight. Such inputs may be automatically received or retrieved by a framework (e.g., from another framework, a database, etc.) and/or may be manually entered.

As an example, a method can include determining one or more friction factors responsive to acquisition of data. Such a method can be more expeditious than an approach that continuously executes a complex model. For example, consider the track 2230 where actual data points are indicated by triangles (e.g., similarly in the track 2220). In such an approach, the actual data points may correspond to individual stands, for example, one data point per stand. As shown, the data points correspond to loads where each load can be compared to the model values for the various different friction factor values to thereby determine a friction factor value that can then be rendered to the track 2210. While a per stand basis can be implemented, one or more other bases may be utilized (e.g., lesser and/or greater).

In various instances, drilling operations may proceed according to operating procedures (e.g., standard operating procedures (SOPs)). Such procedures may specify aspects as to pickup (PU) and slackoff (SO). For example, consider PU and SO in pre-connection just before connection. In such an example, there may or may not be conditions such as rotation and/or no rotation during one or more operations. As to torque loss (TQLS), it may be specified for determination based on sensor data just after connection. For example, consider acquiring torque data after commencing rotation. Various procedures (e.g., SOPs, etc.) can provide for acquisition of data concerning PU, SO and TQLS. As explained, the track 2110 shows friction factor values that correspond to TQLS (TQLS_FF), SO (SO_FF) and PU (PU_FF). As an example, TQLS data can be acquired at the commencement of drilling of a stand (e.g., commencing rotation) and PU data and SO data can be acquired at completion of drilling a stand.

Friction factors can include one or more of movement friction factors and rotation frictions factors. Such friction factors can be directional, such as movement in an out of hole direction, movement in an in hole direction, rotation clockwise and rotation counter-clockwise. As explained, gravity and hole direction can impact friction, for example, consider a horizontal well versus a vertical well.

As an example, a controller, an operator, etc., may generate control logic that can be based on one or more friction factors.

In various instances, one or more block related factors may be taken into account. As explained, a block can be a set of pulleys used to gain mechanical advantage in lifting or dragging heavy objects. As an example, a rig can include two blocks: the crown block and the traveling block. In such an example, each block can include sheaves that are rigged with drilling cable or line such that the traveling block may be raised (or lowered) by reeling in (or out) a spool of drilling line on the drawworks. A block weight may be utilized that may, for example, include mass of a kelly. As an example, a method can include detecting the hook load connection at each stand (e.g., automatically and/or manually).

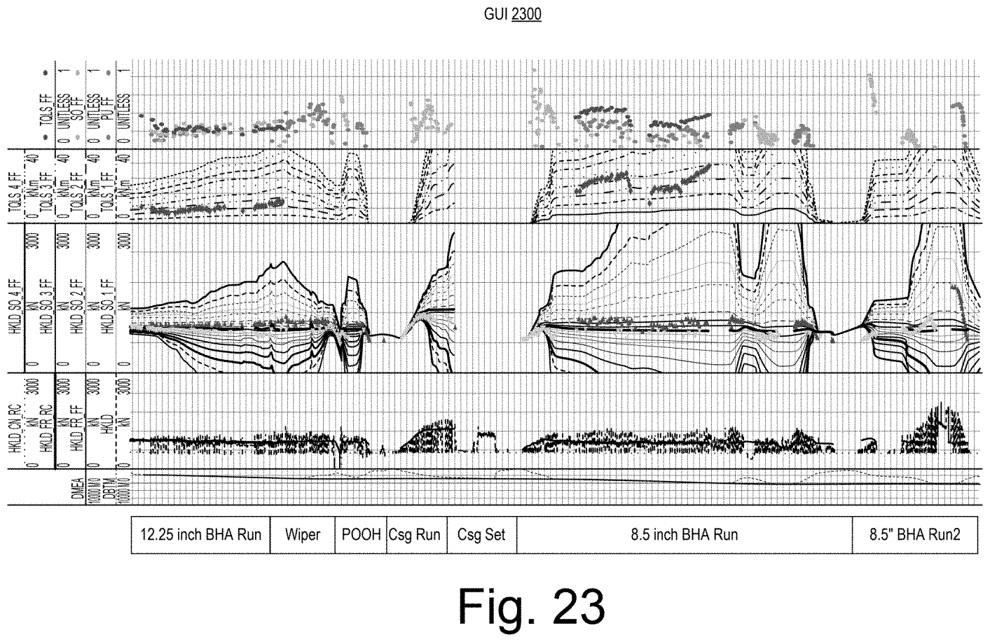

FIG. 23 shows an example GUI 2300 that includes the 8.5 inch BHA run along with other operations that occur over a time period of days (e.g., 3 May to 17 May). As shown, the operations can include multiple BHA runs, wiper runs, casing runs, casing settings, etc. The 12.25 inch section of the borehole includes a 12.25 inch BHA run, a 12.25 inch BHA wiper run and a 12.25 inch pull out of hole (POOH). In the load track, data are shown that can be utilized to generate friction factor values for the friction factor track. As shown, friction factor values can be generated for various types of operations (e.g., BHA runs, wiper runs, casing runs, etc.). In such an approach, one or more of such operations may be controlled utilizing one or more of the friction factors.

In the GUI 2300, the shapes of the load track can be indicative of various conditions, states, etc. For example, consider bit depth where load may be expected to decrease as the bit depth decreases and vice versa. As shown in the GUI 2300, the load track shows envelopes that expand and contract in time corresponding to operational conditions. As the GUI 2300 is shown with respect to time, aspects of rates and/or accelerations may be determined, estimated, etc., in various tracks.

As an example, a method can include generating error or uncertainty bounds. For example, at shallower depths, model loads for a family of friction factors may be relatively close together (see, e.g., start of each BHA run), which may increase error and/or uncertainty of friction factor determinations. In a broomstick plot with respect to depth, the shallower depths may be quite apparent. As an example, a GUI can include one or more graphical controls for selecting a view or views as to how one or more broomstick plots are rendered (e.g., with respect to time, with respect to depth, etc.).

As shown in FIGS. 22 and 23, when rendered with respect to time, some amount of symmetry and/or asymmetry may be observed with respect to time that can indicate direction of movement, operational conditions, etc. As explained, the various torques and/or loads for different friction factors as in the tracks 2220 and 2230 can be real-time using torque and drag framework computations for load determinations, which are with respect to time (e.g., consider the PERFORM TOOL KIT (PTK) framework, etc.).

As an example, the GUI 2200 and/or the GUI 2300 may provide for rendering and/or setting one or more alarms. For example, consider one or more friction factor based alarms. In such an example, if a friction factor exceeds a certain value (an alarm value), then an alarm notification may be issued. As an example, a GUI can include a graphical control for creating, adjusting, deleting, etc., one or more alarms. For example, consider an alarm line or curve that can be dragged and dropped to appropriate values, whether in the track 2210, the track 2220 and/or the track 2230. In the track 2210 the values may be for friction factors while in the track 2230 the values may be for loads that are, for example, positioned with respect to the friction factor based model loads while in the track 2120 the values may be for torques that are, for example, positioned with respect to friction factor based torques.

Referring again to the GUIs 2000 and 2100 of FIG. 20 and FIG. 21, which show broomstick plots with respect to depth, where free rotate (FR) data are substantially vertical between the PU and SO data. In such an example, for appropriate calibration (e.g., positioning or centering of FR data), block weight adjustments can be made. In the example of the GUI 2000, a manual approach can be utilized where an operator iteratively enters block weight estimates until the broomstick plot appears appropriately calibrated.

As an example, a method can automate broomstick plot calibration and/or provide one or more indicators of error. Such an approach may be applied to plots of loads with respect to time and/or depth. Referring again to the GUI 2200 of FIG. 22, the track 2240 shows various hook load values.

The track 2240 can be a quality control track. As mentioned, the block weight can be adjusted manually to calibrate a FR hook load for a broomstick plot with respect to depth (see, e.g., FIG. 20). Such a calibration may aim to position FR values with respect to block weight. In the approach explained with respect to the GUI 2200 of FIG. 22, the track 2240 includes a model determined FR weight, which can be expected to match actual sensor based weight. In the track 2240, the values are sensor data in real-time while other values are the actual FR sensor data. As a quality control, the model determined FR values can be compared to the actual FR values to determine if the model generated data are adequately following the sensor data (e.g., reality). In the time track 2240, the quality can be readily controlled with respect to time, for example, as operations progress. As an example, a GUI can provide for rendering of one or more quality control metrics as to model FR weight and actual FR weight. For example, consider a track that shows a difference between model FR weight and actual FR weight. In such an example, one or more alarms, limits, etc., may be set and utilized for issuance of notifications, model adjustments, check of one or more sensors, etc. For example, where a difference becomes large, it may be due to a model and/or a sensor. In such an example, friction factor values as in the track 2210 may be of greater uncertainty and/or erroneous. As an example, an alarm may be a combined alarm that depends on data quality and/or friction factor.

In comparison to the broomstick with respect to depth approach to visually estimate friction factor as in the GUI 2000 of FIG. 20, the track 2210 in the GUI 2200 of FIG. 22 provides values for friction factor with respect to time where each of the values can be based on acquired data, for example, stand-by-stand. In a stand-by-stand approach, a framework can self-equilibrate stand-by-stand. In comparison, the broomstick with respect to depth can depend on one or more constants for parameters that are defined per BHA activity (e.g., drilling run, wiper run, etc.). If the parameters are not, in reality, constant, then errors may arise for the broomstick with respect to depth approach as in the FIG. 20.

As an example, a method can provide for automatic detection of one or more weights such that, for example, an operator does not have to enter a block weight, for example, as a neutral weight when going into connection. As an example, a method can provide for automatic detection of block weight.

As explained, the example GUI 2200 shows the track 2210 with friction factors, which can be derived using one or more models (see, e.g., tracks 2220 and 2230). In particular, the track 2210 shows a torque loss (TQLS) friction factor (FF), a slackoff (SO) friction factor (FF), and a pickup (PU) friction factor (FF), which may be color coded or otherwise coded. The track 2210 provides an operator and/or a controller to assess one or more trends as to one or more of the friction factors.

As an example, a method can provide for determinations of various phenomena associated with drilling operations where such determinations can be made for torque loss (TQLS) and pickup (PU)/slackoff (SO)/free rotate (FR) weights. As explained, such a method may provide for estimating one or more operation friction factors. In particular, a method can provide for detecting torque losses and/or one or more of pickup (PU), slackoff (SO) and free rotate (FR) weights in time data series.

As explained, time domain and/or depth domain may be utilized to render various data, which can include various friction factors. As explained, a computational framework can assess friction factors, optionally in combination with other data, to determine whether control action is warranted. As an example, a method can include automatically triggering an action, which may be a notification, a control action, etc., using one or more friction factors. As an example, a GUI can include one or more action tracks that may be for one or more notifications (e.g., alarms, etc.) and/or other actions (e.g., suggested control action, etc.).

As explained, various tracks can be rendered to a display as part of a GUI. As an example, consider a GUI that includes one or more hook load related tracks and one or more torque related tracks. As an example, a GUI can include multiple hook load tracks, which can be considered weight or mass related tracks. As an example, weight related tracks can be rendered for drilling, POOH and RIH operations. In a torque track or tracks, data can indicate one or more types of issues such as, for example, differential sticking. As an example, a time-based broomstick can be transformed into a depth-based broomstick by depth gating a model and actual values. As an example, broomsticks with respect to time and/or with respect to depth may be generated and rendered.

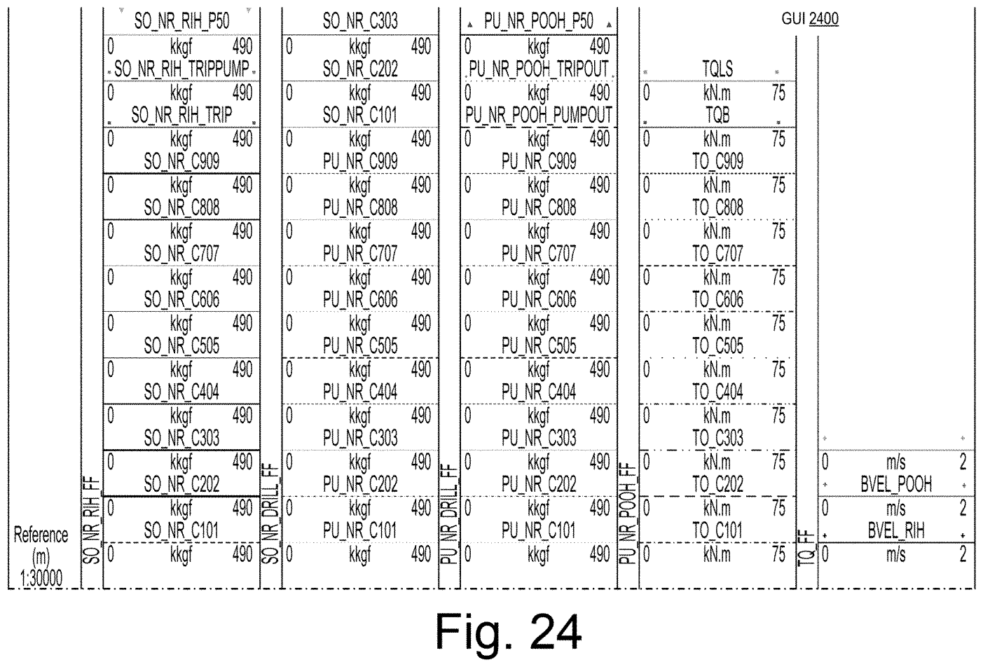

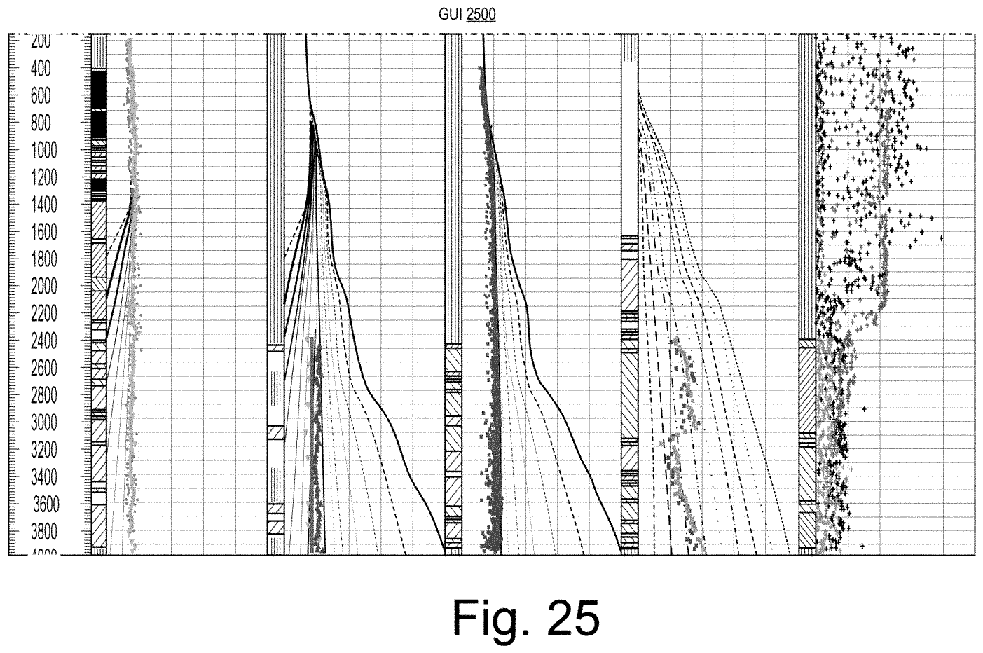

FIGS. 24 and 25 show example portions of a GUI with GUI portions 2400 and 2500, which may be rendered together to a display and where the GUI portion 2400 indicates various parameters and where the GUI portion 2500 indicates various values, indicators, etc.

As shown in FIG. 24 and FIG. 25, the GUI portions 2400 and 2500 includes weight related tracks for friction factors (FF): slackoff (SO) run in hole (RIH) friction factor (FF); slackoff (SO) drilling friction factor (FF); pickup (PU) drilling friction factor (FF); and pickup (PU) pull out of hole (POOH) friction factor (FF). Specifically, the four aforementioned tracks can be notification tracks that pertain to conditions, which can include one or more types of alarms, control actions to be taken, etc. The friction factor (FF) tracks are adjacent to weight tracks where the weight tracks include units of kkgf. Specifically, the GUI portions 2400 and 2500 include three weight tracks as associated with running in hole (RIH), drilling and pulling out of hole (POOH). Additionally, a torque track (units kN.m) with torque friction factor (FF), which can provide for notifications (e.g., torque FF triggered notifications), and a block velocity (BVEL) track (units m/s) are included where the block velocity (BVEL) track includes pull out of hole (POOH) and run in hole (RIH) data.

In the example GUI portions 2400 and 2500, the various weight related tracks are for no rotation (NR). For example, data can be acquired during various operations (e.g., RIH, drilling, POOH, etc.) where a drillstring is not rotating. Where a drillstring is not rotated, it can be more difficult to run in hole (RIH) and pull out of hole (POOH). As an example, data can be acquired with drillstring rotation. In such an example, a broomstick plot can become narrower as friction can be lessened during rotation when moving a drillstring in or out of a borehole. In such an example, various tracks, notifications, etc., may be generated and optionally rendered to a display in the form of one or more GUIs. As an example, a computational framework can provide for selecting data for rotation and/or no rotation (NR) to process for purposes of determining friction factors, issuing notifications, automatically taking control action, etc. As an example, a computational framework can provide for mixed friction factors where a combination of rotating data and non-rotating data are utilized.

As an example, a friction factor indicator can be associated with a track such as, for example, a weight related track or a torque related track. In the example GUI portion 2500 of FIG. 25, indicators can be color coded, for example, using a spectrum from red to green or another convention. In the example of FIG. 25, the torque FF indicators can be mainly green and, for example, light green and dark green. An operator may interpret the torque track by looking at the light grey markers (torque loss, TQLS) to determine where they fall with respect to strands of the broomstick (e.g., lines of the broomstick plot). In such an approach, an operator may determine that the markers fall between 0.1 and 0.2 where an indicator track shows light green while if markers fall between 0.2 and 0.3, then the indicator track may show dark green.

In the drilling track, a friction factor is computed for slackoff (SO) and another friction factor is computed for pickup (PU). As an example, a computational framework can acquire four different measurements to compute five different friction factors: SO, NR, RIH FF; SO, NR, DRILL FF; PU, NR, DRILL FF; PU, NR, POOH FF; and torque FF. As explained, for drilling two friction factors can be determined, which can be rendered in a time domain and/or in a depth domain.

During field operations, a state can change from RIH, where bit depth increases while hole depth remains constant, to drilling, where bit depth and hole depth increase together, as an indicator that drilling is occurring to lengthen a borehole. During RIH, weight can be measured as stands of drill pipe are added, where uphole movement does not occur. During POOH, weight can be measured as stands of drill pipe are removed, where downhole movement does not occur. During drilling, in the process of adding a stand of drill pipe, the drill bit is pulled off the bottom of the hole by raising the drillstring outwardly and once the stand of drill pipe is added, the drill bit is lowered by moving the drillstring inwardly. Thus, during drilling, as each stand of drill pipe is added (e.g., or a single length of drill pipe), an upward movement occurs followed by a downward movement. Such movements tend to be relatively small and less than a discrete length of a piece of drill pipe. As weight (e.g., hook load) can be measured (e.g., without rotation or with rotation), friction factors can be computed, for example, one for an upward movement and another for a downward movement. As to rotation, friction factors may be computed for clockwise rotation and/or counter-clockwise rotation. As an example, various friction factors may be computed, which may include one or more mixed friction factors (e.g., a combination of up, down, clockwise, counter-clockwise, etc.). As an example, weights may be measured and friction factors computed each time additional drill pipe is added to a drillstring or less frequently, for example, at multiples of three (e.g., once for every three stands, etc.); noting that friction factor computations may be more precise when weights are measured more often.

As an example, RIH points may be rendered in blue as indicative of movement downwardly and POOH points may be rendered in red as indicative of movement upwardly where drilling can include a combination of points rendered in blue and red. As an example, each point can be for a stand of drill pipe. As an example, a RIH operation and/or POOH operation may provide for weight measurements may be acquired more frequently than once per stand of drill pipe.

As an example, where sticking or indications of sticking exist, one or more tracks for hydraulics may be rendered. In such an approach, a root cause for sticking or an indication of sticking may be discerned from a GUI rendered to a display.

As an example, a depth domain track or tracks can be rendered with one or more channels that may provide for understanding as to friction factor changes. For example, block velocity during drilling, RIH and/or POOH and/or for inclination and/or dogleg severity from a trajectory. As to block velocity, it may provide for an indication of hydraulic effects as fluid (e.g., mud) can surround a drillstring in an annular region between the drillstring and a borehole wall and/or a cased wall. As to inclination and/or dogleg severity, these can be indicators of how a drillstring is oriented with respect to gravity, which may provide for additional information to assess weight related aspects of field operations, including friction aspects that may present risks as to sticking. In various instances, dogleg severity can be a metric that can impact risk of sticking. For example, with a more sever dogleg, there can be an increased risk of sticking. As an example, a computational framework can increase measurement and computation frequency for friction factors depending on one or more conditions, which may include commencing a dogleg, which may consider dogleg severity.

As an example, a computational framework may generate a number of friction factors, which may range from one to three to more than three (e.g., consider five or more). In such an approach, the friction factors can be associated with particular field operations and/or particular directions of movement.

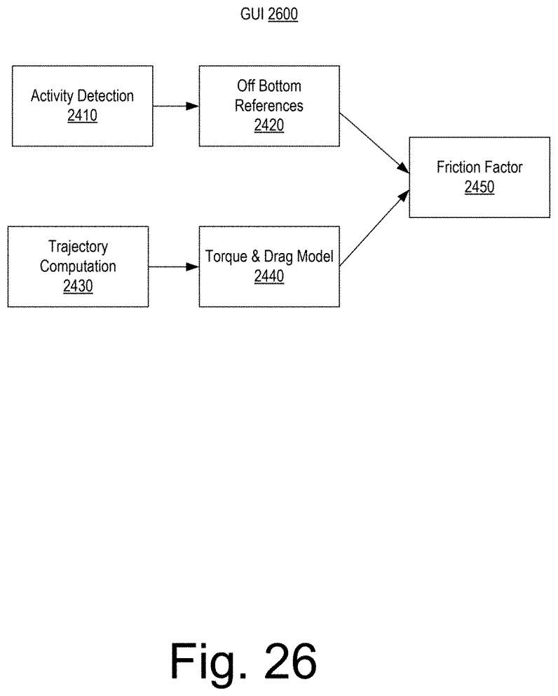

FIG. 26 shows an example of a GUI 2600 that can be utilized to arrange various framework components, which may include one or more of an activity detection component 2610, an off-bottom references component 2620, a trajectory computation component 2630, a torque and drag (T&D) model component 2640 and a friction factor component 2650.

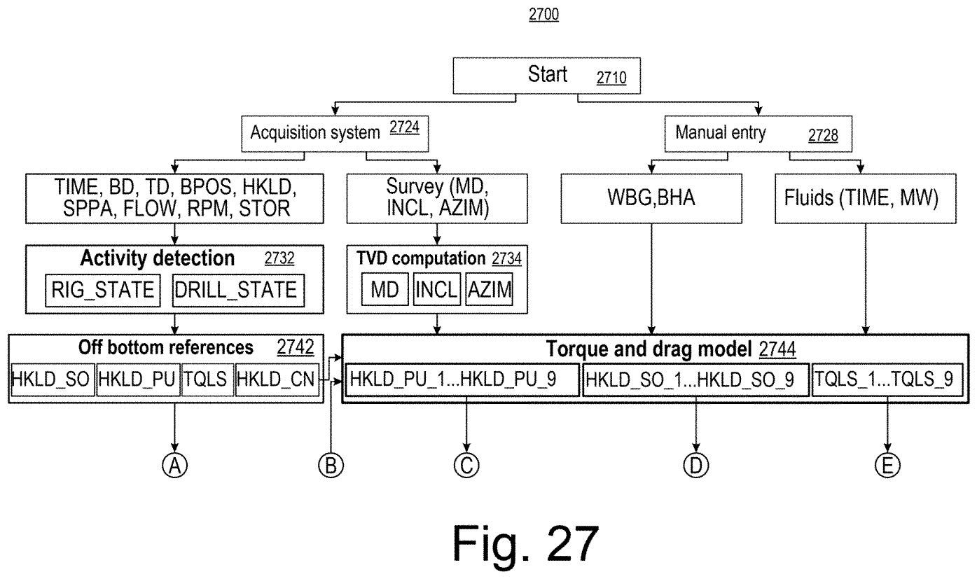

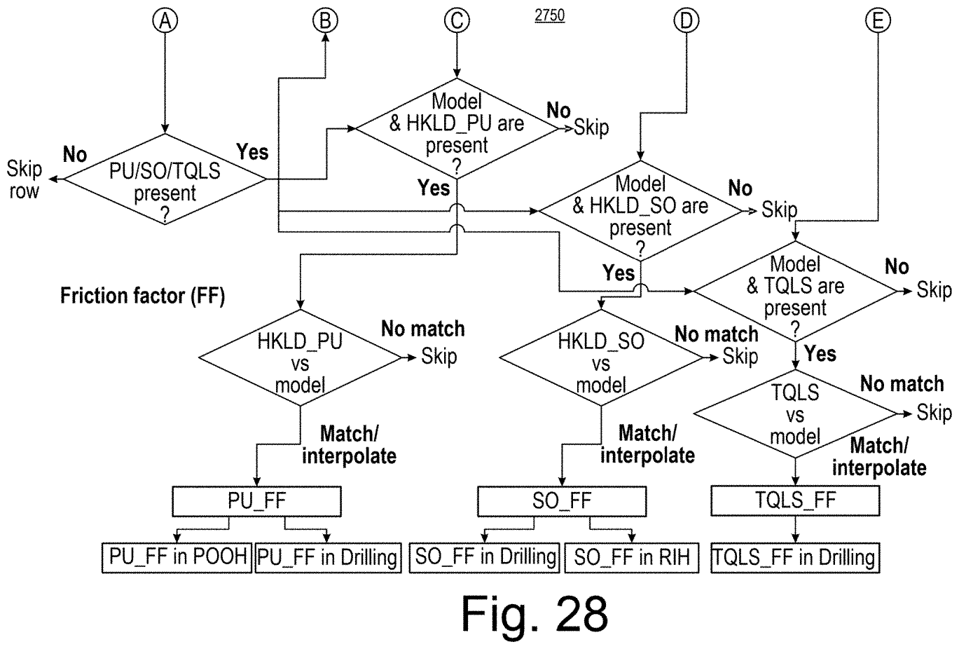

FIG. 27 and FIG. 28 show an example of a method 2700 that includes various blocks that can correspond to actions, for example, one or more actions that may be performed by one or more of the components 2610, 2620, 2630, 2640 and 2650 in the GUI 2600 of FIG. 26.

As shown in the example of FIG. 27, the method 2700 can include a start block 2710 for starting the method 2700 where data acquisition system block 2724 and an entry block 2728 follow. The entry block 2728 can provide for entry and/or retrieval of information such as wellbore geometry (WBG), BHA specifications, fluid specifications, etc., which can be provided to a torque and drag model block 2744. The data acquisition system block 2724 can provide for acquisition of various data, which may include surface data and downhole data. For example, downhole survey data may include measured depth, inclination and azimuth (e.g., per sensors of a BHA, etc.). Such data may be fed to a TVD computation block 2734, for example, to adjust downhole values to a set of total vertical depth model values suitable for utilization by the torque and drag model block 2744. As shown, various types of acquired data can be provided to an activity detection block 2732 that may determine states such as, for example, rig state and drill state. Such states may be utilized by an off-bottom references block 2742, which may generate values such as HKLD_SO, HKLD_PU, TQLS and HKLD_CN (e.g., for calibration, etc.). Output from the block 2742 may be fed to the torque and drag model block 2744 and to a friction factor determination block 2750, as shown in FIG. 28. As shown, the torque and drag model block 2744 can also output to the friction factor determination block 2750, for example, consider output of model values for HKLD_PU (0 to n), HKLD_SO (0 to n), and TQLS (0 to n). While each of the examples includes an index “n” for number of different friction factors, the indexes may differ.

FIG. 28 shows an example of a friction factor block 2750 that includes various decision blocks that can implement decision logic. Such decision logic may provide for output of friction factor values on a desired basis, which may provide for conservation of computational resources, improved real-time performance, etc. As mentioned, the friction factor determinations can be performed responsive to data.

As shown in the friction factor block 2750 of FIG. 28, a decision block decides if data are present for PU, SO and TQLS. As shown, a “no” decision results in a skip (e.g., skip row) while a “yes” decision calls for additional actions and/or decisions, which can include triggering the torque and drag model block 2744. In such an approach, the T&D model block 2744 may be activated responsive to a decision from the aforementioned decision block of the friction factor block 2750. Output of the friction factor block 2750 can be rendered to a GUI such as, for example, the track 2210 of the GUI 2200 of FIG. 22. As an example, output of the T&D model block 2744 may be output to a GUI such as, for example, consider the tracks 2220 and 2230 of the GUI 2200 of FIG. 22; noting that a time domain and/or a depth domain may be utilized for rendering of output.

In the example friction factor block 2750 of FIG. 28, friction factors for pickup (PU_FF), slackoff (SO_FF) and torque loss (TQLS_FF) can be computed, where the pickup (PU) can be further computed for one or more of POOH (PU_FF in POOH) and for drilling (PU_FF in drilling) and where slackoff (SO) can be further computed for one or more of drilling (SO_FF in drilling) and RIH (SO_FF in RIH). As explained, computations may be performed, for example, with rotation, without rotation, clockwise rotation, counter-clockwise rotation, etc. Thus, the number of friction factors of a friction factor block can be more than five.

As explained, a framework can implement a method that can automatically compute a broomstick model in a time domain and/or a broomstick model in a depth domain. As explained with respect to the GUI 2600 of FIG. 26 and the method 2700 of FIG. 27 and FIG. 28, such a framework can utilize one or more components, which may be represented as blocks (e.g., consider a reference connection component for drilling interpretations). As an example, a framework can provide for estimation of friction factors when a string goes up, down or is rotating (e.g., clockwise and/or counter-clockwise). In various examples, a framework can provide for automatic detection of block weight, consideration of fluid changes and modification of the tool behavior within a bore.

As explained, a GUI can include a friction factor track that may replace and/or supplement a broomstick with respect to depth track where an operator may readily determine friction factor values, trends, etc., using the friction factor track. Such a friction factor track can be with respect to time and, for example, optionally with respect to depth, where values may appear with respect to time responsive to acquisition of appropriate data during operations. Such a track can represent a considerable improvement over a classic depth broomstick display that demands expertise of a drilling engineer to interpret the broomstick analysis leading to low reactivity or interpretation errors.

As an example, a friction factor track can be a real-time track that can account for changes in one or more rig parameters and/or one or more conditions such as block weight, mud weight or string conditions. A classic depth broomstick display requires the expertise of a drilling engineer to interpret the broomstick analysis, which can lead to low reactivity or interpretation errors.

As an example, the method 2700 of FIG. 27 and FIG. 28 may be automated, including optionally automated for data entry per the block 2728. The method 2700 may provide for automated friction factor determinations with respect to time responsive to data acquisition, where broomstick model generation can occur and where broomstick model results may be rendered to a GUI or not (e.g., characterized with respect to time and/or depth). For example, a GUI and/or alarm system may utilize friction factor determinations with respect to time without consideration of and/or rendering of inherent model results (e.g., T&D model results).

As explained, inputs and output may be defined as channels. During operations, live, real-time channels can provide input and, in turn, live, real-time channels can provide output. As explained, some trajectory and/or contextual information may be retrieved and/or manually entered.

As explained with respect to the method 2700 of FIG. 27 and FIG. 28, rig activity can be automatically detected (e.g., in a state-based approach, etc.) to identify connections. As explained, data pertaining to block weight, pickup (PU), free rotate (FR) and slackoff (SO) loads may be automatically acquired. As explained, one or more hook load models and torque models can be computed for an individual connection (e.g., coupling or decoupling of drill pipe of a drillstring), which can be followed by a comparison between model and references taken at the connections for one or more of PU, SO and TQLS to estimate one or more friction factor values.

In various examples, a framework can provide for utilization of multiple friction factor models (e.g., string up, string down and string rotate, optionally clockwise and counter-clockwise). A framework may utilize various different measurement points (e.g., hook load and torque). As an example, a framework may account for depth where, for example, one or more shallow depth limits may be set as increased uncertainty in friction may exist for shallow depths.

As an example, a framework can provide for detection of torque losses and pickup/slackoff/free rotate weights in time data series. As explained, various types of equipment/operational state determinations may be made using one or more techniques, which can include machine learning model based techniques. As explained, a framework may be operable to determine friction factors using a relatively low number of channels, which may help to reduce complexity, more readily identify issues (e.g., data/sensor quality, etc.).

As an example, data processing may be implemented by a framework such that, for example, data points can be filtered according to one or more criteria, which may be based on physics of a process. Where a stand-by-stand approach is implemented, a final point for each stand may be taken using one or more statistical techniques (e.g., consider a median of points). Such an approach can help to address possible noise in one or more surface sensor readings.

As an example, a framework can implement a method that can include determining a block weight value and connection references during a connection. For example, consider a framework that provides for:
1. Single computation process for a complete well (e.g., rather than running T&D/broomstick analysis by BHA run);
2. An ability to monitor assembly cleaning for borehole condition based on single phase on multiple BHA at global well scale (e.g., consider phases and BHAs on one screen combined as in the GUI 2300 of FIG. 23).
3. An ability to, at the beginning of a workflow, examine a difference between reference free rotate Hook load (HKLD_FR) and a modeled free rotate weight (HKLD_FR_FF), which may provide a quality flag that can help users to determine if the model is appropriately calibrated within the context information (WBG, BHA, fluids) (e.g., consider an indicator that does not impact friction factor computation yet provides for a measure of confidence level).
4. An ability to automatically output one or more of multiple different friction factors, which may be utilized for one or more types of interpretations, analyses, etc.
5. An ability to automate HKLD_CN during connection (e.g., to alleviate demand for manual adjustment of a block weight parameter, for example, consider: a hook load median value when drill state is “connection” and off bottom references for PU, SO and TQLS to get HKLD_PU (e.g., without rotation), HKLD_SO (e.g., without rotation) and TQLS. As an example, a method may generate HKLD_PU and HKLD_SO models with rotation and, for example, compare against actual rotational points, which may provide value for wells where there are more rotational points.
6. An ability to realize a performance gain due to an on-demand computation (e.g. responsive to data acquisition for one or more of PU, SO and TQLS data points).
7. An ability to handle mud weight changes dynamically at each point.
8. An ability to consider a floating casing case in dynamic manner.
9. An ability to handle changes in a BHA, for example, as for a change in tool diameter.

As an example, a framework can include a T&D model engine that can compute a number of models (e.g., model results) for one or more of PU, SO and TQLS. For example, consider a parameter “n” that defines a number of friction factor values to consider. In various examples, n=9 where 9 models are computed for PU (e.g., movement in a first direction), 9 models are computed for SO (e.g., movement in a second direction) and 9 models are computed for TQLS (e.g., rotation). As explained, computations can be triggered when reference points are present in order to optimize algorithm performance, for example, giving a single value by string elements. Each model may be computed at each reference based on the block weight, mud weight and BHA conditions.

As an example, a framework can include dynamic adjustment to one or more friction factor values, ranges, etc., for a model. For example, consider an approach that aims to refine a model based on one or more readings. In such an example, a framework may learn a general operational range and then discretize within that operational range to provide a number of friction factor values to utilize in modeling. Such an approach may include a zero reference value and/or a sufficient number of values at and/or near a limit (e.g., consider an alarm limit). Such an approach may provide for more accurate determinations as to friction factors using a set of model-based results. As explained, where changes may occur dynamically, a framework may respond with dynamic adjustments to friction factor values for modeling; noting that such dynamically adjusted friction factor values for modeling can be a time increment or time increments (e.g., or stand-by-stand, etc.) basis behind real-time. As an example, a statistical approach may be utilized, for example, consider deviations about a mean where the mean is determined using a forgetting factor (e.g., based on time, a number of stands, etc.). As explained, nine values may be utilized that are equally spaced. In a dynamic approach, such values may be adjusted in their spacing as operations progress in time, which may provide for more accurate estimates (e.g., interpolations) of friction factors based model results and on sensor data.

As explained with respect to the logic of the friction factor block 2750 of FIG. 28, PU, SO and TQLS values can be compared to values of corresponding sets of models. In such an example, if a value is higher than the highest value, it can be discarded, otherwise the logic calls for determining an appropriate corresponding model or models (e.g., between two models). Where a value does not fall on a model value (e.g., within some limit), then interpolation may be utilized to determine an estimated value (e.g., between friction factor of 0.2 and friction factor of 0.3, etc.). As explained, a friction factor value may be estimated based on an interpolation made according to nearest 2 models covering the value. As an example, interpolation information may be utilized to dynamically adjust model friction factor values (e.g., range adjustment, spacing adjustment, etc.).

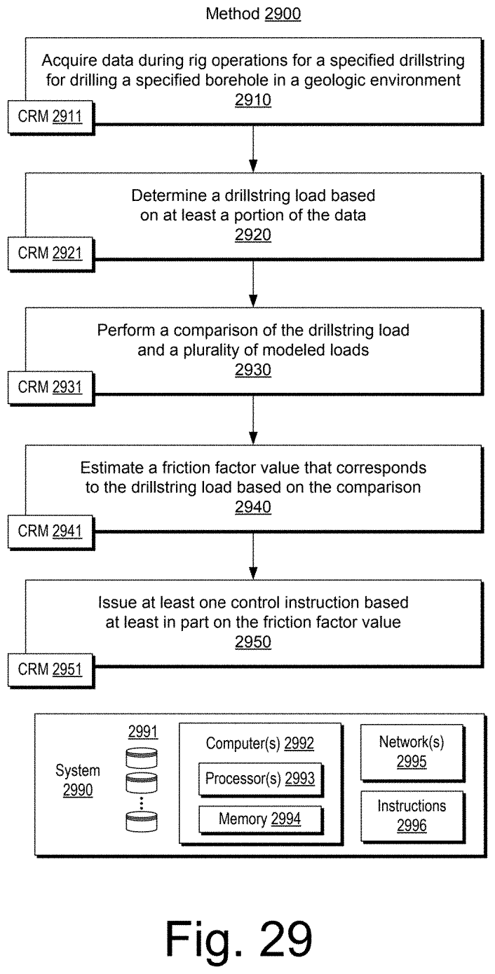

FIG. 29 shows an example of a method 2900 that includes an acquisition block 2910 for acquiring data during rig operations for a specified drillstring for drilling a specified borehole in a geologic environment, where the data include downhole survey data; a determination block 2920 for determining a drillstring load based on at least a portion of the data; a comparison block 2930 for comparing the drillstring load to a plurality of modeled loads, where the plurality of modeled loads depend on the specified drillstring, the specified borehole, and at least a portion of the survey data and correspond to a plurality of different friction factor values; and an estimation block 2940 for, based on the comparing, estimating a friction factor value that corresponds to the drillstring load. As shown, the method 2900 can include an issuance block 2950 for issuing at least one control instruction based at least in part on the friction factor value.

FIG. 29 also shows various computer-readable media (CRM) blocks 2911, 2921, 2931, 2941, and 2951. Such blocks can include instructions that are executable by one or more processors, which can be one or more processors of a computational framework, a system, a computer, etc. A computer-readable medium can be a computer-readable storage medium that is not a signal, not a carrier wave and that is non-transitory. For example, a computer-readable medium can be a physical memory component that can store information in a digital format.

In the example of FIG. 29, a system 2990 includes one or more information storage devices 2991, one or more computers 2992, one or more networks 2995 and instructions 2996. As to the one or more computers 2992, each computer may include one or more processors (e.g., or processing cores) 2993 and memory 2994 for storing the instructions 2996, for example, executable by at least one of the one or more processors. As an example, a computer may include one or more network interfaces (e.g., wired or wireless), one or more graphics cards, a display interface (e.g., wired or wireless), etc. The system 2990 can be specially configured to perform one or more portions of the method 2900 of FIG. 29.

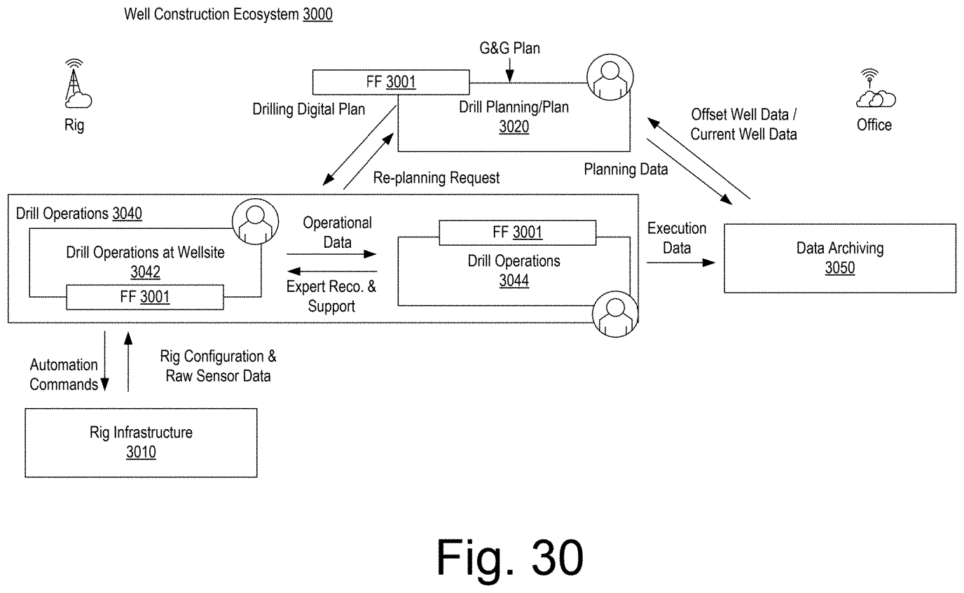

FIG. 30 shows an example of a system 3000 that can be a well construction ecosystem. As shown, the system 3000 can include one or more instances of the friction factor framework (FF) 3001 and can include a rig infrastructure 3010 and a drill plan component 3020 that can generation or otherwise transmit information associated with a plan to be executed utilizing the rig infrastructure 3010, for example, via a drilling operations layer 3040, which includes a wellsite component 3042 and an offsite component 3044. As shown, data acquired and/or generated by the drilling operations layer 3040 can be transmitted to a data archiving component 3050, which may be utilized, for example, for purposes of planning one or more operations (e.g., per the drilling plan component 3020).

In the example of FIG. 30, the FF 3001 may be implemented in at least in part at the offsite component 3044 and/or may be implemented at least in part at the wellsite component 3042 (e.g., at a rigsite). As explained, a GUI or GUIs can include one or more plots that can provide for rendering of friction factor values with respect to time and, for example, load model results with respect to time, optionally for a plurality of model friction factor values. As explained, the FF 3001 may issue signals such as, for example, control and/or alarm signals. In the example of FIG. 30, a signal may be issued by the offsite component 3044 to the wellsite component 3042, which can issue one or more signals to the rig infrastructure 3010 (e.g., rig equipment). As an example, a signal may pertain to one or more operations and associated risk or risks that depend on friction, which may be a directional friction. As an example, the system 3000 of FIG. 30 may include one or more features of the system 400 of FIG. 4. As an example, the method 2700 of FIG. 27 and FIG. 28 and/or the method 2900 of FIG. 29 may be implemented at least in part using a system or systems (e.g., one or more features of the system 400, the system 1600, the system 2900, etc.).

As an example, a computational framework may be implemented within or in a manner operatively coupled to the DELFI cognitive exploration and production (E&P) environment (Schlumberger, Houston, Tex.), which is a secure, cognitive, cloud-based collaborative environment that integrates data and workflows with digital technologies, such as artificial intelligence and machine learning. As an example, such an environment can provide for operations that involve one or more frameworks. The DELFI environment may be referred to as the DELFI framework, which may be a framework of frameworks. As an example, the DELFI framework can include various other frameworks, which can include, for example, one or more types of models (e.g., simulation models, etc.).

As an example, a system such as the system 1600 of FIG. 16 may be utilized in one or more planning, execution, etc., phases, which may occur through use of a framework such as the DELFI framework. For example, consider simulating drilling where surface measurements are generated that can be utilized as inputs to the system 1600 to determine one or more performance aspects of the system 1600 prior to drilling using the system 1600. In such an example, a simulation may help to decide how to utilize the system 1600, for example, which section or sections may be suitable for use of the system 1600 for one or more purposes.

As an example, a workflow may progress to a geology and geophysics (“G&G”) service provider, which may generate a well trajectory, which may involve execution of one or more G&G software packages. Examples of such software packages include the PETREL framework. As an example, a system or systems may utilize a framework such as the DELFI framework. Such a framework may operatively couple various other frameworks to provide for a multi-framework workspace.

As explained, one or more machine learning techniques may be implemented by a framework, a system, etc. For example, the system 1600 includes ML model block 1650 that can utilize one or more machine learning techniques. As an example, a method can include implementing machine learning for determining one or more aspects of a model such as a load model. For example, consider implementing machine learning to determine a number of friction factor values, a range of friction factor values, etc., which may be dynamic utilized during operations to provide for making friction factor estimations. As explained, a PU model may differ from a SO model as to number, range, etc., of friction factor values. Further, a TQLS model may differ as well. As an example, a ML model or ML models based approach may provide for optimizing model runs (e.g., for one or more of PU, SO and TQLS models) for purposes of friction factor estimations. Such an approach may call for dynamically running a model or models for a “smart” set of friction factor values that can optionally reduce computational demand and/or expedite generation of load results. As explained, an approach may include three models with nine friction factor values evenly spaced, for a total of 27 model runs. A dynamically optimized approach may reduce the number of model runs for one or more of the models while providing for suitable friction factor estimations.

As to types of machine learning models, consider one or more of a support vector machine (SVM) model, a k-nearest neighbors (KNN) model, an ensemble classifier model, a neural network (NN) model, etc. As an example, a machine learning model can be a deep learning model (e.g., deep Boltzmann machine, deep belief network, convolutional neural network, stacked auto-encoder, etc.), an ensemble model (e.g., random forest, gradient boosting machine, bootstrapped aggregation, AdaBoost, stacked generalization, gradient boosted regression tree, etc.), a neural network model (e.g., radial basis function network, perceptron, back-propagation, Hopfield network, etc.), a regularization model (e.g., ridge regression, least absolute shrinkage and selection operator, elastic net, least angle regression), a rule system model (e.g., cubist, one rule, zero rule, repeated incremental pruning to produce error reduction), a regression model (e.g., linear regression, ordinary least squares regression, stepwise regression, multivariate adaptive regression splines, locally estimated scatterplot smoothing, logistic regression, etc.), a Bayesian model (e.g., naïve Bayes, average on-dependence estimators, Bayesian belief network, Gaussian naïve Bayes, multinomial naïve Bayes, Bayesian network), a decision tree model (e.g., classification and regression tree, iterative dichotomiser 3, C4.5, C5.0, chi-squared automatic interaction detection, decision stump, conditional decision tree, M5), a dimensionality reduction model (e.g., principal component analysis, partial least squares regression, Sammon mapping, multidimensional scaling, projection pursuit, principal component regression, partial least squares discriminant analysis, mixture discriminant analysis, quadratic discriminant analysis, regularized discriminant analysis, flexible discriminant analysis, linear discriminant analysis, etc.), an instance model (e.g., k-nearest neighbor, learning vector quantization, self-organizing map, locally weighted learning, etc.), a clustering model (e.g., k-means, k-medians, expectation maximization, hierarchical clustering, etc.), etc.

As an example, a machine model, which may be a machine learning model (ML model), may be built using a computational framework with a library, a toolbox, etc., such as, for example, those of the MATLAB framework (MathWorks, Inc., Natick, Mass.). The MATLAB framework includes a toolbox that provides supervised and unsupervised machine learning algorithms, including support vector machines (SVMs), boosted and bagged decision trees, k-nearest neighbor (KNN), k-means, k-medoids, hierarchical clustering, Gaussian mixture models, and hidden Markov models. Another MATLAB framework toolbox is the Deep Learning Toolbox (DLT), which provides a framework for designing and implementing deep neural networks with algorithms, pretrained models, and apps. The DLT provides convolutional neural networks (ConvNets, CNNs) and long short-term memory (LSTM) networks to perform classification and regression on image, time-series, and text data. The DLT includes features to build network architectures such as generative adversarial networks (GANs) and Siamese networks using custom training loops, shared weights, and automatic differentiation. The DLT provides for model exchange various other frameworks.

As an example, the TENSORFLOW framework (Google LLC, Mountain View, Calif.) may be implemented, which is an open source software library for dataflow programming that includes a symbolic math library, which can be implemented for machine learning applications that can include neural networks. As an example, the CAFFE framework may be implemented, which is a DL framework developed by Berkeley AI Research (BAIR) (University of California, Berkeley, Calif.). As another example, consider the SCIKIT platform (e.g., scikit-learn), which utilizes the PYTHON programming language. As an example, a framework such as the APOLLO AI framework may be utilized (APOLLO.AI GmbH, Germany). As an example, a framework such as the PYTORCH framework may be utilized (Facebook AI Research Lab (FAIR), Facebook, Inc., Menlo Park, Calif.).

As an example, a training method can include various actions that can operate on a dataset to train a ML model. As an example, a dataset can be split into training data and test data where test data can provide for evaluation. A method can include cross-validation of parameters and best parameters, which can be provided for model training.

The TENSORFLOW framework can run on multiple CPUs and GPUs (with optional CUDA (NVIDIA Corp., Santa Clara, Calif.) and SYCL (The Khronos Group Inc., Beaverton, Oreg.) extensions for general-purpose computing on graphics processing units (GPUs)). TENSORFLOW is available on 64-bit LINUX, MACOS (Apple Inc., Cupertino, Calif.), WINDOWS (Microsoft Corp., Redmond, Wash.), and mobile computing platforms including ANDROID (Google LLC, Mountain View, Calif.) and IOS (Apple Inc.) operating system based platforms.

TENSORFLOW computations can be expressed as stateful dataflow graphs; noting that the name TENSORFLOW derives from the operations that such neural networks perform on multidimensional data arrays. Such arrays can be referred to as “tensors”.

As an example, a method can include acquiring data during rig operations for a specified drillstring for drilling a specified borehole in a geologic environment, where the data include downhole survey data; determining a drillstring load based on at least a portion of the data; comparing the drillstring load to a plurality of modeled loads, where the plurality of modeled loads depend on the specified drillstring, the specified borehole, and at least a portion of the survey data and correspond to a plurality of different friction factor values; and, based on the comparing, estimating a friction factor value that corresponds to the drillstring load. In such an example, the method can include issuing a signal such as a control signal, an alarm, etc., based at least in part on the friction factor. For example, consider a control signal and/or an alarm signal that aims to reduce a risk of getting stuck, damaging a borehole (e.g., borehole wall), damaging a drillstring, damaging rig equipment, etc. As to control signal, consider issuance of a control signal to rig equipment (see, e.g., FIGS. 1, 2, 7, etc.). As an example, a system such as the system 400 of FIG. 4 may be utilized to implement one or more methods. As explained, a method may include dynamic adjustment to a model or a plurality of models, which may, for example, improve accuracy of friction factor value estimation.

As an example, a drillstring load can be a directional load. For example, consider a pickup (PU) direction load or a slackoff (SO) direction load. As an example, a load may be referenced with respect to a measured depth, a coordinate system, gravity, etc. As an example, a drillstring load can be a rotational load. For example, consider a load associated with rotation of a drillstring in a clockwise direction or a counter-clockwise direction. A drillstring may be moved in one or more axial directions (e.g., in and out or up and down) with respect to an axis of a borehole, which may be curved and/or straight. As an example, a borehole may be characterized by a trajectory, which may include a dogleg (see, e.g., FIG. 2).

As an example, a drillstring load can corresponds to a stand of a drillstring. For example, consider utilizing a framework that can determine a state of an operation and, for that state, acquire data and/or retrieve data that is indicative of a load for that state.

As an example, a method can include repeating acquiring, determining, comparing and estimating on a stand-by-stand basis for stands of a drillstring. In such an example, the method may be performed during one or more types of operations (e.g., BHA run, wiper run, etc.).

As an example, a method can include detecting an activity state based on at least a portion of data. For example, consider detecting an activity state that can be one of a pickup (PU) state and a slackoff (SO) state. As an example, a method can include detecting a commencement of rotation state as an activity state.

As an example, a method can include rendering a friction factor value to a display where, for example, the rendering renders the friction factor value to a plot with respect to time and/or with respect to depth. In such an example, the rendering can render the friction factor value to a graphical user interface on a display, for example, via issuance of appropriate data, commands, etc. Such a display may be on-site or off-site and viewable by an operator on-site or a remote operator off-site. As an example, a track of friction factor values with respect to time and/or with respect to depth can provide for trend assessment and/or one or more other types of time-based and/or depth-based assessments. For example, consider a rate of change in friction factor values with respect to time and/or with respect to depth. As an example, a rate of change may be utilized for issuing one or more signals (e.g., control, alarm, etc.) and/or in combination with a friction factor value (e.g., that may be approaching an alarm limit, etc.).

As an example, a method can include rendering a friction factor value to a display with respect to time and/or with respect to depth. In such an example, a broomstick pattern may be rendered where a friction factor value can be rendered with respect to the broomstick pattern, for example, to discern where the friction factor value lies with respect to strands of the broomstick pattern, which may represent contours that may change with respect to depth and/or with respect to time.

As an example, a method can include estimating at least two friction factor values for at least two different friction factors. As an example, a method can include estimating at least three friction factor values for at least three different friction factors. As an example, a method can include estimating a drilling pickup friction factor value and estimating a drilling slackoff friction factor value. In such an example, the friction factor values can correspond to different axial directions of movement of a drillstring in a borehole. As explained, values may be determined using data acquired during a connection or during a disconnection. As explained, during drilling connections are made to add drill pipe, which may be in the form of a stand (e.g., three sections of drill pipe). During a connection process for drilling, a drillstring may be lifted to take a drill bit off the bottom of a hole and then the drillstring may be lowered to allow the drill bit to encounter the bottom of the hole. As such, data may be acquired and utilized to determine two different friction factors (e.g., an upward factor and a downward friction factor). As explained, friction factors can correspond to rotation or no rotation where, for rotation, a friction factor may be for a clockwise rotation or for a counter-clockwise rotation.

As an example, various rotating up, rotating down, etc., types of friction factors may be determined using data acquired during various movements of a drillstring. In such an example, one or more thresholds, differentials, slopes, trends, etc., may be utilized for issuance of one or more notifications, one or more control signals, etc., to improve one or more field operations that involve moving a drillstring in a borehole.

As an example, a method can include rendering a plurality of modeled loads to a display (e.g., via one or more GUIs, etc.). In such an example, the rendering can render the plurality of modeled loads to one or more plots with respect to time. Such plots can include one or more broomstick plots (e.g., full broomstick, half broomstick, etc.). As explained, spread of a broomstick plot can depend on one or more factors, which may be measurable in real-time, adjustable based on results and/or data, dependent on direction or directions of movement of a drillstring, etc.

As an example, a method can include determining a model-based free rotate load. In such an example, the method can include acquiring data that includes a sensed free rotate load. As an example, a method can include rendering a representation of a model-based free rotate load and a sensed free rotate load to a display (e.g., via one or more GUIs) and/or comparing a model-based free rotate load and a sensed free rotate load and issuing an alarm based at least in part on the comparing. As an example, a comparison may be utilized as a quality control approach as to modeling and/or sensing. For example, a sensor issue or sensor data transmission issue may be indicated by a deviation between a model-based free rotate load and a sensed free rotate load. In such an example, a signal may be issued that calls for resetting and/or otherwise addressing the issue. As explained, for example, with respect to the system 400 of FIG. 4, the system 3000 of FIG. 30, etc., one or more types of transmission technologies may be utilized where a part of a system may be local and a part of a system may be remote. Where satellite technology is utilized (e.g., for rigsites remote from infrastructure), transmissions issues may arise from time-to-time (e.g., based on weather, time of day, sun activity, etc.).

As an example, a method can include determining drillstring loads based on at least a portion of data, where the drillstring loads include a pickup (PU) load and a slackoff (SO) load, and where the method includes rendering a plurality of the pickup (PU) loads and the slackoff (SO) loads with respect to time.

As an example, a system can include a processor; memory accessible by the processor; processor-executable instructions stored in the memory and executable to instruct the system to: acquire data during rig operations for a specified drillstring for drilling a specified borehole in a geologic environment, where the data include downhole survey data; determine a drillstring load based on at least a portion of the data; perform a comparison of the drillstring load and a plurality of modeled loads, where the plurality of modeled loads depend on the specified drillstring, the specified borehole, and at least a portion of the survey data and correspond to a plurality of different friction factor values; and, based on the comparison, estimate a friction factor value that corresponds to the drillstring load.

As an example, one or more computer-readable storage media can include processor-executable instructions to instruct a computing system to: acquire data during rig operations for a specified drillstring for drilling a specified borehole in a geologic environment, where the data include downhole survey data; determine a drillstring load based on at least a portion of the data; perform a comparison of the drillstring load and a plurality of modeled loads, where the plurality of modeled loads depend on the specified drillstring, the specified borehole, and at least a portion of the survey data and correspond to a plurality of different friction factor values; and, based on the comparison, estimate a friction factor value that corresponds to the drillstring load.

As an example, a method may be implemented in part using computer-readable media (CRM), for example, as a module, a block, etc. that include information such as instructions suitable for execution by one or more processors (or processor cores) to instruct a computing device or system to perform one or more actions. As an example, a single medium may be configured with instructions to allow for, at least in part, performance of various actions of a method. As an example, a computer-readable medium (CRM) may be a computer-readable storage medium (e.g., a non-transitory medium) that is not a carrier wave. As an example, a computer-program product can include instructions suitable for execution by one or more processors (or processor cores) where the instructions can be executed to implement at least a portion of a method or methods.

According to an embodiment, one or more computer-readable media may include computer-executable instructions to instruct a computing system to output information for controlling a process. For example, such instructions may provide for output to sensing process, an injection process, drilling process, an extraction process, an extrusion process, a pumping process, a heating process, etc.

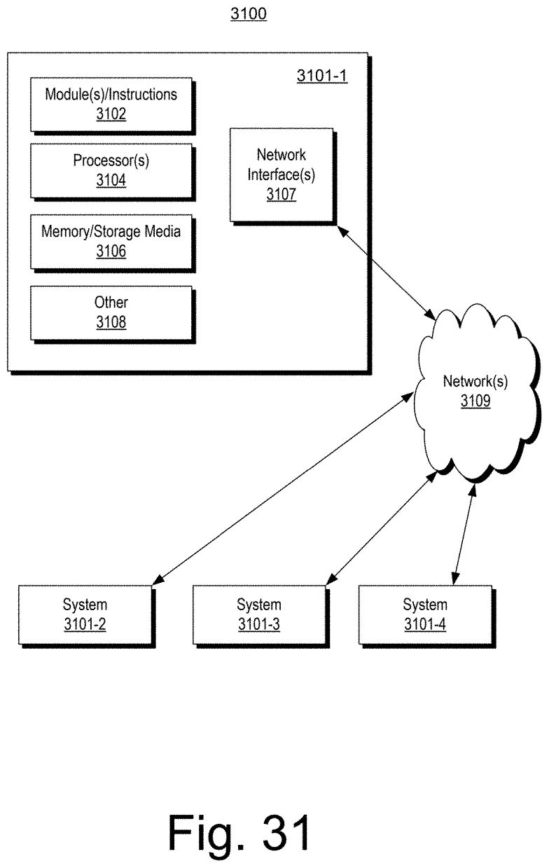

In some embodiments, a method or methods may be executed by a computing system. FIG. 31 shows an example of a system 3100 that can include one or more computing systems 3101-1, 3101-2, 3101-3 and 3101-4, which may be operatively coupled via one or more networks 3109, which may include wired and/or wireless networks.

As an example, a system can include an individual computer system or an arrangement of distributed computer systems. In the example of FIG. 31, the computer system 3101-1 can include one or more modules 3102, which may be or include processor-executable instructions, for example, executable to perform various tasks (e.g., receiving information, requesting information, processing information, simulation, outputting information, etc.).

As an example, a module may be executed independently, or in coordination with, one or more processors 3104, which is (or are) operatively coupled to one or more storage media 3106 (e.g., via wire, wirelessly, etc.). As an example, one or more of the one or more processors 3104 can be operatively coupled to at least one of one or more network interface 3107. In such an example, the computer system 3101-1 can transmit and/or receive information, for example, via the one or more networks 3109 (e.g., consider one or more of the Internet, a private network, a cellular network, a satellite network, etc.). As shown, one or more other components 3108 can be included in the computer system 3101-1.

As an example, the computer system 3101-1 may receive from and/or transmit information to one or more other devices, which may be or include, for example, one or more of the computer systems 3101-2, etc. A device may be located in a physical location that differs from that of the computer system 3101-1. As an example, a location may be, for example, a processing facility location, a data center location (e.g., server farm, etc.), a rig location, a wellsite location, a downhole location, etc.

As an example, a processor may be or include a microprocessor, microcontroller, processor module or subsystem, programmable integrated circuit, programmable gate array, or another control or computing device.

As an example, the storage media 3106 may be implemented as one or more computer-readable or machine-readable storage media. As an example, storage may be distributed within and/or across multiple internal and/or external enclosures of a computing system and/or additional computing systems.

As an example, a storage medium or storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices.

As an example, a storage medium or media may be located in a machine running machine-readable instructions, or located at a remote site from which machine-readable instructions may be downloaded over a network for execution.

As an example, various components of a system such as, for example, a computer system, may be implemented in hardware, software, or a combination of both hardware and software (e.g., including firmware), including one or more signal processing and/or application specific integrated circuits.

As an example, a system may include a processing apparatus that may be or include a general purpose processors or application specific chips (e.g., or chipsets), such as ASICs, FPGAs, PLDs, or other appropriate devices.

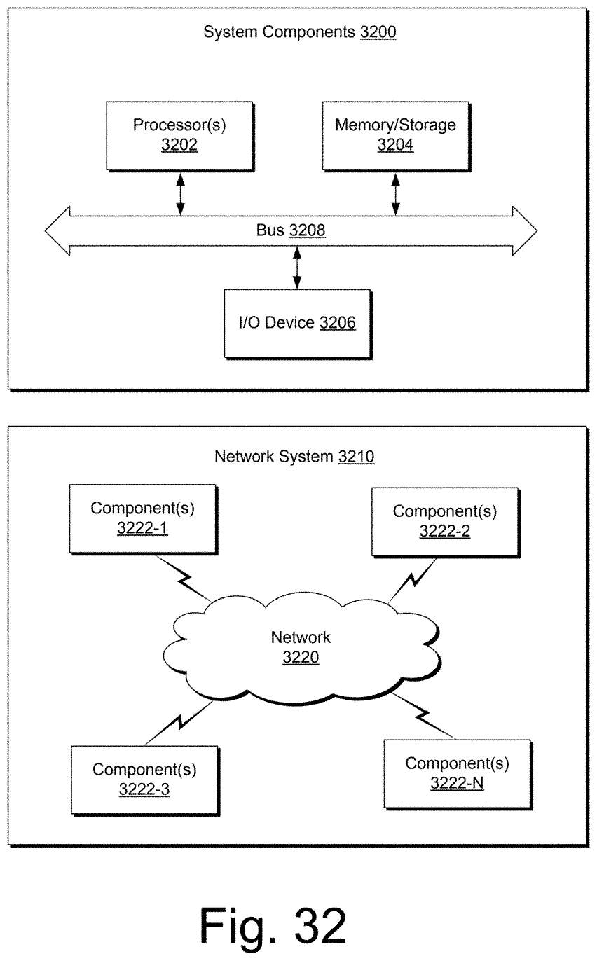

FIG. 32 shows components of a computing system 3200 and a networked system 3210 with a network 3220. The system 3200 includes one or more processors 3202, memory and/or storage components 3204, one or more input and/or output devices 3206 and a bus 3208. According to an embodiment, instructions may be stored in one or more computer-readable media (e.g., memory/storage components 3204). Such instructions may be read by one or more processors (e.g., the processor(s) 3202) via a communication bus (e.g., the bus 3208), which may be wired or wireless. The one or more processors may execute such instructions to implement (wholly or in part) one or more attributes (e.g., as part of a method). A user may view output from and interact with a process via an I/O device (e.g., the device 3206). According to an embodiment, a computer-readable medium may be a storage component such as a physical memory storage device, for example, a chip, a chip on a package, a memory card, etc.

According to an embodiment, components may be distributed, such as in the network system 3210. The network system 3210 includes components 3222-1, 3222-2, 3222-3, . . . 3222-N. For example, the components 3222-1 may include the processor(s) 3202 while the component(s) 3222-3 may include memory accessible by the processor(s) 3202. Further, the component(s) 3222-2 may include an I/O device for display and optionally interaction with a method. The network may be or include the Internet, an intranet, a cellular network, a satellite network, etc.

As an example, a device may be a mobile device that includes one or more network interfaces for communication of information. For example, a mobile device may include a wireless network interface (e.g., operable via IEEE 802.11, ETSI GSM, BLUETOOTH, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

As an example, information may be input from a display (e.g., consider a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that can be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

Although only a few examples have been described in detail above, those skilled in the art will readily appreciate that many modifications are possible in the examples. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
acquiring data during rig operations for a specified drillstring for drilling a specified borehole in a geologic environment, wherein the data comprise downhole survey data;
determining a drillstring load based on at least a portion of the data;
comparing the drillstring load to a plurality of modeled loads, wherein the plurality of modeled loads depend on the specified drillstring, the specified borehole, and at least a portion of the survey data and correspond to a plurality of different friction factor values; and
based on the comparing, estimating a friction factor value that corresponds to the drillstring load.

2. The method of claim 1, wherein the drillstring load comprises a directional load.

3. The method of claim 2, wherein the directional load comprises a pickup direction load.

4. The method of claim 2, wherein the directional load comprises a slackoff direction load.

5. The method of claim 1, wherein the drillstring load comprises a rotational load.

6. The method of claim 1, wherein the drillstring load corresponds to a stand of the drillstring.

7. The method of claim 1, comprising repeating the acquiring, determining, comparing and estimating on a stand-by-stand basis for stands of the drillstring.

8. The method of claim 1, comprising detecting an activity state based on at least a portion of the data.

9. The method of claim 8, wherein the activity state comprises a pickup state or a slackoff state.

10. The method of claim 1, comprising rendering the friction factor value to a display with respect to time.

11. The method of claim 1, comprising rendering the friction factor value to a display with respect to depth.

12. The method of claim 1, comprising estimating at least three friction factor values for at least three different friction factors.

13. The method of claim 1, comprising estimating a drilling pickup friction factor value and estimating a drilling slackoff friction factor value.

14. The method of claim 1, comprising determining a model-based free rotate load.

15. The method of claim 14, wherein the data comprises a sensed free rotate load.

16. The method of claim 15, comprising rendering a representation of the model-based free rotate load and the sensed free rotate load to a display.

17. The method of claim 15, comprising comparing the model-based free rotate load and the sensed free rotate load and issuing an alarm based at least in part on the comparing.

18. The method of claim 1, comprising determining drillstring loads based on at least a portion of the data, wherein the drillstring loads comprise a pickup load and a slackoff load, and comprising rendering a plurality of the pickup loads and the slackoff loads with respect to time and/or with respect to depth.

19. A system comprising:
a processor;
memory accessible by the processor;
processor-executable instructions stored in the memory and executable to instruct the system to:
acquire data during rig operations for a specified drillstring for drilling a specified borehole in a geologic environment, wherein the data comprise downhole survey data;
determine a drillstring load based on at least a portion of the data;
perform a comparison of the drillstring load and a plurality of modeled loads, wherein the plurality of modeled loads depend on the specified drillstring, the specified borehole, and at least a portion of the survey data and correspond to a plurality of different friction factor values; and
based on the comparison, estimate a friction factor value that corresponds to the drillstring load.

20. One or more computer-readable storage media comprising processor-executable instructions to instruct a computing system to:
acquire data during rig operations for a specified drillstring for drilling a specified borehole in a geologic environment, wherein the data comprise downhole survey data;
determine a drillstring load based on at least a portion of the data;
perform a comparison of the drillstring load and a plurality of modeled loads, wherein the plurality of modeled loads depend on the specified drillstring, the specified borehole, and at least a portion of the survey data and correspond to a plurality of different friction factor values; and
based on the comparison, estimate a friction factor value that corresponds to the drillstring load.
